(19) United States
(12) Patent Application Publication
(10) Pub. No.: US 2016/0126478 A1
(43) Pub. Date: May 5, 2016

(54) EMISSIVE COMPOUNDS FOR LIGHT EMITTING DEVICES

(71) Applicants: Shijun Zheng, San Diego, CA (US); Adam Basiago, Temecula, CA (US); Nitto Denko Corporation, Osaka (JP)

(72) Inventors: Shijun Zheng, San Diego, CA (US); Adam Basiago, Temecula, CA (US)

(73) Assignee: Nitto Denko Corporation, Osaka (JP)

(21) Appl. No.: 14/890,153

(22) PCT Filed: May 9, 2014
(86) PCT No.: PCT/US14/37572

§ 371 Date: Nov. 9, 2015

Related U.S. Application Data
(60) Provisional application No. 61/821,597, filed on May 9, 2013.
(60) Provisional application No. 61/917,876, filed on Dec. 18, 2013.

(51) Int. Cl. H01L 51/00; C09K 11/06

(52) U.S. Cl. CPC H01L 51/0072; C09K 11/06; H01L 51/0052; H01L 51/0067; C09K 2211/1007; C09K 2211/1029; C09K 2211/1011; H01L 51/5012

(57) ABSTRACT

Disclosed herein are compounds represented by Formula (1), wherein R₂ is an cyano, aryl and/or heteroaryl which can be from an optionally substituted phenyl, optionally substituted pyridinyl and optionally substituted pyrimidinyl; and wherein, R₃ is a heteroaryl which can be from an optionally substituted carbazolyl, an optionally substituted benzocarbazolyl, an optionally substituted phenoxazolyl, an optionally substituted phenothiazenyl and an optionally substituted phenazinyl. Other embodiments provide an organic light-emitting diode device comprising a compound of Formula (1).

### BACKGROUND

1. Field

This invention relates to compounds for use in organic light emitting diodes, such as for emissive materials.

2. Description of the Related Art

Organic light-emitting devices have been widely developed for flat panel displays, and are moving fast toward solid state lighting (SSL) applications. Organic Light Emitting Diodes (OLEDs) comprise a cathode, a hole transporting layer, an emissive layer, an electron transporting layer, and an anode. Light emitted from an OLED device is the result of recombination of positive charges (holes) and negative charges (electrons) inside an organic (emissive) layer. The holes and electrons combine within a single molecule or a small cluster of molecules to generate excitons, which are molecules in an excited state, or groups of organic molecules bound together in an excited state. When the organic molecules release the required energy and return to their stable state, photons are generated. Organic materials which emit the photons are referred as an electro-fluorescent material or electro-phosphorescent material depending on the nature of the radiative process. Thus the OLED emissive compounds may be selected for their ability to absorb primary radiation and emit radiation of a desired wavelength.

SSL applications may require a white OLED device to achieve greater than 1,500 lm brightness, a color rendering index (CRI) greater than 70, and an operating time greater than 100,000 hours at 1,000 lm/w. There are many approaches for generating white light from an OLED, but two common approaches are: direct combination of red, blue, and green light using either lateral patterning or vertical stacking of three emitters; and partial down conversion of blue light in combination with yellow phosphors. Both of these common approaches may be more effective if a highly efficient chemical- and photo-stable emissive materials are employed. Thus, the development of emissive materials with good stability and high luminescence efficiency is desirable to effectively reduce power consumption and generate emission of different colors.

### SUMMARY

In some embodiments, a compound for use in emissive elements of organic light emitting devices, the compound being represented by Formula 1:

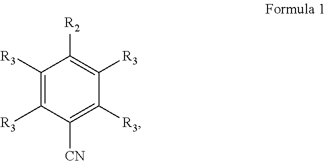

wherein R₂ can be an optionally substituted substituent, such as optionally substituted phenyl, an optionally substituted polycyclic aromatic, an optionally substituted C₁₋₄ alkynyl, or a heteroaryl group; R₃ is an electron donor heteroaryl selected from an optionally substituted carbazolyl, an optionally substituted benzocarbazolyl, an optionally substituted phenoxazolyl, an optionally substituted phenothiazenyl and an optionally substituted phenazinyl.

Some embodiments also include optionally substituted 2,3,5,6-tetra(9H-carbazol-9-yl)-[1,1′-biphenyl]-4-carbonitrile (Emissive Material [EM]-1); optionally substituted 2,3,5,6-tetra(9H-carbazol-9-yl)-4′-methoxy-[1,1′-biphenyl]-4-carbonitrile (EM-2); optionally substituted 2,3,5,6-tetra(9H-carbazol-9-yl)-4-(phenylethynyl)benzonitrile (EM-3); optionally substituted (3r,5s)-2,3,5,6-tetra(9H-carbazol-9-yl)-2′,6′-dimethyl-[1,1′-biphenyl]-4-carbonitrile (EM-4); and optionally substituted 2,3,5,6-tetra(9H-carbazol-9-yl)-4-((2,6-dimethylphenyl)ethynyl)benzonitrile (EM-5); optionally substituted 2,3,5,6-tetra(9H-carbazol-9-yl)-4-(naphthalen-2-yl)benzonitrile (EM-6); optionally substituted 2,3,5,6-tetra(9H-carbazol-9-yl)-4-(1,2-dihydroacenaphthylen-5-yl)benzonitrile (EM-7); optionally substituted 2,3,5,6-tetra(9H-carbazol-9-yl)-[1,1′-biphenyl]-4,4′-dicarbonitrile (EM-8); optionally substituted and optionally substituted 3,5,6-tetrakis(3,6-dimethyl-9H-carbazol-9-yl)-[1,1′-biphenyl]-4,4′-dicarbonitrile (EM-9); 2,3,5,6-tetrakis(3,6-(9H-carbazol-9-yl)-9H-carbazol-9-yl)-[1,1′-biphenyl]-4,4′-dicarbonitrile (EM-10); 2,3,5,6-tetrakis(3,6-bis((E)-2-cyclohexylvinyl)-9H-carbazol-9-yl)-[1,1′-biphenyl]-4,4′-dicarbonitrile (EM-11); (S)-2,3,5,6-tetrakis(7H-benzo[c]carbazol-7-yl)-[1,1′-biphenyl]-4,4′-dicarbonitrile (EM-12); (S)-2,3,5,6-tetrakis(11H-benzo[a]carbazol-11-yl)-[1,1′-biphenyl]-4,4′-dicarbonitrile (EM-13); (2r,3r,6r)-2,3,5,6-tetra(9H-carbazol-9-yl)-4′-(trifluoromethyl)-[1,1′-biphenyl]-4-carbonitrile (EM-14); (2r,3r,6r)-2,3,5,6-tetra(9H-carbazol-9-yl)-3′,5′-bis(trifluoromethyl)-[1,1′-biphenyl]-4-carbonitrile (EM-15); (3r,5s)-2,3,5,6-tetrakis(3,6-diphenyl-9H-carbazol-9-yl)-3′,5′-bis(trifluoromethyl)-[1,1′-biphenyl]-4-carbonitrile (EM-16); (2R,3R,5S,6S)-2,3,5,6-tetrakis(7H-benzo[c]carbazol-7-yl)-3′,5′-bis(trifluoromethyl)-[1,1′-biphenyl]-4-carbonitrile (EM-17); 5-((3r,5s)-4-cyano-2,3,5,6-tetrakis(3,6-diphenyl-9H-carbazol-9-yl)phenyl)pyrimidine-2-carbonitrile (EM-18); and/or 5-((3r,5s)-4-cyano-2,3,5,6-tetrakis(3,6-diphenyl-9H-carbazol-9-yl)phenyl)picolinonitrile (EM-19).

Other embodiments provide an organic light-emitting diode device comprising a cathode; an anode; a light-emitting layer disposed between and electrically connected to the anode and the cathode; a hole-transport layer between the anode and the light-emitting layer; and an electron-transport layer between the cathode and the light-emitting layer; wherein at least one of the light-emitting layer, the hole-transport layer and the electron-transport layer comprise a host compound described herein.

Other embodiments provide an organic light-emitting diode device comprising: a cathode; an anode; and a light-emitting layer disposed between and electrically connected to the anode and the cathode; wherein the light-emitting layer comprises a host compound described herein.

These and other embodiments are described in greater detail below.

### BRIEF DESCRIPTION OF THE DRAWINGS

FIG. 1 is a schematic of a device incorporating an embodiment of a compound described herein.

FIG. 2 shows the power efficiency (PE) and luminescence efficiency (LE) as a function luminescence (brightness) of an embodiment of a device described herein.

FIG. 3 shows the EQE (external quantum efficiency) with respect to the current density of various embodiments of the light-emitting device featured in FIG. 1.

### DETAILED DESCRIPTION

By employing a newly designed molecular structure, an example shown below, we report a new series emissive material that can be used in OLED device applications. The synthesis of at least some compounds in this series of host material can be straightforward and high yield.

As used herein the term “aryl” has the broadest meaning generally understood in the art, and may include an aromatic ring or aromatic ring system. Exemplary non-limiting aryl groups are phenyl, naphthyl, dihydroacenaphthyl, etc. “C₆₋₃₀ aryl” refers to aryl where the ring or ring system has from 6-30 carbon atoms. “C₆₋₃₀ aryl” does not characterize or limit any substituents attached to the ring atoms. As used herein, the term “heteroaryl” also has the meaning understood by a person of ordinary skill in the art, and in some embodiments, may refer to an “aryl” which has one or more heteroatoms in the ring or ring system. Exemplary non-limiting “heteroaryl” groups may include, but are not limited to, pyridinyl, furyl, thienyl, oxazolyl, thiazolyl, imidazolyl, indolyl, quinolinyl, benzofuranyl, benzothienyl, benzooxazolyl, benzothiazolyl, benzoimidazolyl, etc. “C₆₋₃₀ heteroaryl” refers to aryl where the ring or ring system has from 6-30 carbon atoms. “C₆₋₃₀ heteroaryl” does not characterize or limit any substituents attached to the ring atoms.

As used herein, the term “alkyl” refers to a hydrocarbon moiety having no double or triple bonds. Examples include, but are not limited to, linear alkyl, branched alkyl, cycloalkyl, or combinations thereof. Alkyl may also be defined by the following general formulas: the general formula for linear or branched alkyls not containing a cyclic structure is CₙH₂ₙ₊₂, and the general formula for alkyls containing one ring is CₙH₂ₙ. A C_{X-Y} alkyl or C_{X}-C_{Y} alkyl is an alkyl having from X to Y carbon atoms. For example, C₁₋₁₂ alkyl or C₁-C₁₂ alkyl includes hydrocarbon containing 1, 2, 3, 4, 5, 6, 7, 8, 9, 10, 11, or 12 carbon atoms and no double or triple bonds.

Unless otherwise indicated, when a compound or chemical structural feature such as aryl is referred to as being “optionally substituted,” it includes a feature that has no substituents (i.e. unsubstituted), or a feature that is “substituted,” meaning that the feature has one or more substituents. The term “substituent” has the broadest meaning known to one of ordinary skill in the art, and includes a moiety that occupies a position normally occupied by one or more hydrogen atoms attached to a parent compound or structural feature. In some embodiments, a substituent may be an ordinary organic moiety known in the art, which may have a molecular weight (e.g. the sum of the atomic masses of the atoms of the substituent) of 15 g/mol to 50 g/mol, 15 g/mol to 100 g/mol, 15 g/mol to 150 g/mol, 15 g/mol to 200 g/mol, 15 g/mol to 300 g/mol, or 15 g/mol to 500 g/mol. In some embodiments, a substituent comprises, or consists of: 0-30, 0-20, 0-10, or 0-5 carbon atoms; and 0-30, 0-20, 0-10, or 0-5 heteroatoms, wherein each heteroatom may independently be: N, O, S, Si, F, Cl, Br, or I; provided that the substituent includes one C, N, O, S, Si, F, Cl, Br, or I atom. Examples of substituents include, but are not limited to, alkyl, alkenyl, alkynyl, heteroalkyl, heteroalkenyl, heteroalkynyl, aryl, heteroaryl, hydroxy, alkoxy, aryloxy, acyl, acyloxy, alkylcarboxylate, thiol, alkylthio, cyano, halo, thiocarbonyl, O-carbamyl, N-carbamyl, O-thiocarbamyl, N-thiocarbamyl, C-amido, N-amido, S-sulfonamido, N-sulfonamido, isocyanato, thiocyanato, isothiocyanato, nitro, silyl, sulfenyl, sulfinyl, sulfonyl, haloalkyl, haloalkoxyl, trihalomethanesulfonyl, trihalomethanesulfonamido, amino, etc. Hydrogen atoms may also be included.

Other examples of substituents include without limitation; optionally substituted alkyl, —O-alkyl (e.g. —OCH₃, —OC₂H₅, —OC₃H₇, —OC₄H₉, etc.), —S-alkyl (e.g. —SCH₃, —SC₂H₅, —SC₃H₇, —SC₄H₉, etc.), —NR′R″, —OH, —SH, —CN, —NO₂, or a halogen, wherein R′ and R″ are independently H or optionally substituted alkyl. Wherever a substituent is described as “optionally substituted,” that substituent can be substituted with the above substituents.

Optionally substituted alkyl refers to unsubstituted alkyl and substituted alkyl. The substituted alkyl refers to substituted alkyl where one or more H atoms are replaced by one or more substituent groups, such as —O-alkyl (e.g. —OCH₃, —OC₂H₅, —OC₃H₇, —OC₄H₉, etc.), —S-alkyl (e.g. —SCH₃, —SC₂H₅, —SC₃H₇, —SC₄H₉, etc.), —NR′R″ where R′ and R″ are independently H or alkyl, —OH, —SH, —CN, —CF₃, —NO₂, perfluoroalkyl, or a halogen. Some examples of optionally substituted alkyl may be alkyl, haloalkyl, perfluoroalkyl, hydroxyalkyl, alkylthiol (i.e. alkyl-SH), -alkyl-CN, etc.

The term “perfluoroalkyl” refers to fluoroalkyl with a formula CₙF₂ₙ₊₁ for a linear or branched structure, e.g., CF₃, C₂F₅, C₃F₇, C₄F₉, C₅F₁₁, C₆F₁₃, etc., or CₙF₂ₙ for a cyclic structure, e.g., cyclic C₃F₆, cyclic C₄F₈, cyclic C₅F₁₀, cyclic C₆F₁₂, etc. In other words, every hydrogen atom in alkyl is replaced by fluorine. For example, while not intending to be limiting, C₁₋₃ perfluoroalkyl refers to CF₃, C₂F₅, and C₃F₇ isomers. The term “perfluoroalkyl” refers to fluoroalkyl with a formula CₙF₂ₙ₊₁ for a linear or branched structure, e.g., CF₃, C₂F₅, C₃F₇, C₄F₉, C₅F₁₁, C₆F₁₃, etc., or CₙF₂ₙ for a cyclic structure, e.g., cyclic C₃F₆, cyclic C₄F₈, cyclic C₅F₁₀, cyclic C₆F₁₂, etc. In other words, every hydrogen atom in alkyl is replaced by fluorine. For example, while not intending to be limiting, C₁₋₃ perfluoroalkyl refers to CF₃, C₂F₅, and C₃F₇ isomers.

Optionally substituted C₁₋₁₂ alkyl refers to unsubstituted C₁₋₁₂ alkyl and substituted C₁₋₁₂ alkyl. The substituted C₁₋₁₂ alkyl refers to C₁₋₁₂ alkyl where one or more hydrogen atoms are independently replaced by one or more of the substituent groups indicated above.

In some embodiments, a compound for use in emissive elements of organic light emitting devices, the compound being represented by Formula 1:

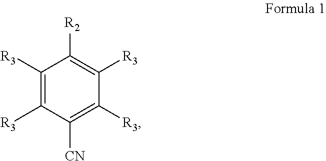

wherein R₂ can be an optionally substituted substituent, such as optionally substituted phenyl, an optionally substituted polycyclic aromatic, an optionally substituted C₁₋₄ alkynyl, or a heteroaryl group. For example, R₂ could be an optionally substituted phenyl, an optionally substituted polycyclic, selected from but not limited to an optionally substituted phenyl, an optionally substituted polycyclic such as, naphthyl or 1,2-dihydroacenaphthyl, an optionally substituted pyridinyl, an optionally substituted cyanopyridinyl, an optionally substituted cyanopyrimidinyl, an optionally substituted cyanophenyl, optionally substituted phenylethynyl, or an optionally substituted pyrimidinyl.

Some embodiments provide a compound represented by Formula 1A:

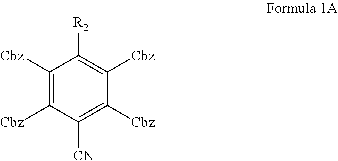

wherein R₂ can be an optionally substituted aryl and/or optionally substituted heteroaryl; and wherein Cbz can be an optionally substituted carbazolyl.

Some embodiments include a compound for use in emissive elements of organic light emitting devices, the compound being represented by Formula 1B:

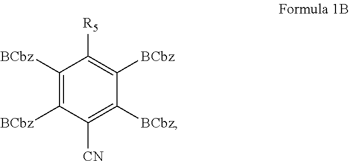

wherein R₅ can be an optionally substituted aryl and/or an optionally substituted heteroaryl; and wherein BCbz can be an optionally substituted benzocarbazolyl.

Some embodiments include a compound for use in emissive elements of organic light emitting devices, the compound being represented by Formula 2:

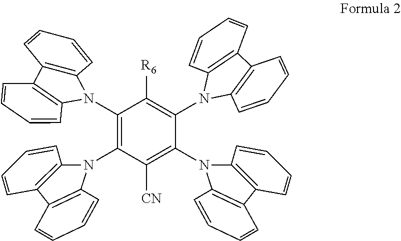

wherein R₆ is selected from is optionally substituted phenyl, optionally substituted 2-phenylethynyl, optionally substituted naphthalene, cyano, or optionally substituted 1,2-dihydroacenaphthylene.

In some embodiments, a compound for use in emissive elements of organic light emitting devices, the compound being represented by the following Formula:

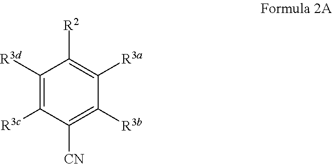

In some embodiments, a compound for use in emissive elements of organic light emitting devices, the compound being represented by Formula 3:

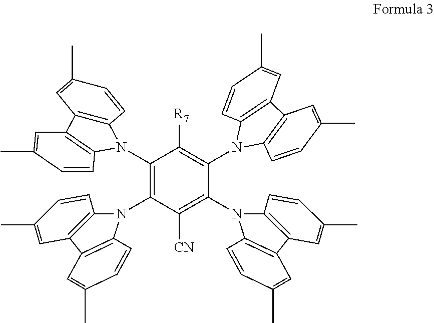

wherein R₇ is selected from is selected from optionally substituted phenyl, optionally substituted 2-phenylethynyl, optionally substituted naphthalene, and optionally substituted 1,2-dihydroacenaphthylene. In some embodiments, the compound is an emissive compound. In some embodiments, the compound can be used in emissive elements of organic light emitting devices.

With respect to Formula 1, 1A, or 2A, R² or R₂ is optionally substituted phenyl, an optionally substituted polycyclic aromatic, an optionally substituted C₁₋₄ alkynyl, or a heteroaryl group. For example, R² or R₂ could be an optionally substituted phenyl, an optionally substituted polycyclic such as, naphthyl, dihydronaphthyl or 1,2-dihydroacenaphthyl, an optionally substituted pyridinyl, an optionally substituted cyanopyridinyl, an optionally substituted cyanopyrimidinyl, an optionally substituted cyanophenyl, optionally substituted phenylethynyl, or an optionally substituted pyrimidinyl. Any substituent may be included on R² or R₂. In some embodiments, some or all of the substituents on R² or R₂ may have: from 0-10 carbon atoms and from 0-10 heteroatoms, wherein each heteroatom is independently: O, N, S, F, Cl, Br, or I (provided that there is at least 1 non-hydrogen atom); and/or a molecular weight of 15 g/mol to 500 g/mol. For example, the substituents may be C₁₋₂₀ alkyl, such as CH₃, C₂H₅, C₃H₇, cyclic C₃H₅, C₄H₉, cyclic C₄H₇, C₅H₁₁, cyclic C₅H₉, C₆H₁₃, cyclic C₆H₁₁, etc.; C₁₋₂₀ alkoxyl; C₁₋₂₀ hydroxyalkyl; halo, such as F, Cl, Br, or I; OH; CN; NO₂; C₁₋₆ fluoroalkyl, such as CF₃, CF₂H, C₂F₅, etc.; a C₁₋₁₀ ester such as —O₂CCH₃, —CO₂CH₃, —O₂CC₂H₅, —CO₂C₂H₅, —O₂C-phenyl, etc.; or a C₁₋₁₀ amine such as NH₂, NH(CH₃), N(CH₃)₂, N(CH₃)C₂H₅, etc. In some embodiments, R² or R₂ has a OCH₃, CH₃, CN, or CF₃ substituent. In some embodiments, R² or R₂ has an OCH₃ substituent. In some embodiments, R² or R₂ has a CH₃ substituent. In some embodiments, R² or R₂ has a CN substituent. In some embodiments, R² or R₂ has a CF₃ substituent.

With respect to Formula 2A, R^{3a} is an optionally substituted carbazolyl, an optionally substituted benzocarbazolyl, an optionally substituted phenoxazolyl, an optionally substituted phenothiazenyl, or an optionally substituted phenazinyl. In some embodiments, Any substituent may be included on R^{3a}. In some embodiments, some or all of the substituents on R^{3a} may have: from 0-10 carbon atoms and from 0-10 heteroatoms, wherein each heteroatom is independently: O, N, S, F, Cl, Br, or I (provided that there is at least 1 non-hydrogen atom); and/or a molecular weight of 15 g/mol to 500 g/mol. For example, the substituents may be C₁₋₂₀ alkyl, such as CH₃, C₂H₅, C₃H₇, cyclic C₃H₅, C₄H₉, cyclic C₄H₇, C₅H₁₁, cyclic C₅H₉, C₆H₁₃, cyclic C₆H₁₁, etc.; C₁₋₂₀ alkoxyl; C₁₋₂₀ hydroxyalkyl; halo, such as F, Cl, Br, or I; OH; CN; NO₂; C₁₋₆ fluoroalkyl, such as CF₃, CF₂H, C₂F₅, etc.; a C₁₋₁₀ ester such as —O₂CCH₃, —CO₂CH₃, —O₂CC₂H₅, —CO₂C₂H₅, —O₂C-phenyl, etc.; or a C₁₋₁₀ amine such as NH₂, NH(CH₃), N(CH₃)₂, N(CH₃)C₂H₅, etc. In some embodiments, R^{3a} has a phenyl substituent, such as unsubstituted phenyl, 4-methoxyphenyl, or 4-methylphenyl In some embodiments, R^{3a} has a 2-phenylethenyl substituent. In some embodiments, R^{3a} has a carbazolyl substituent. In some embodiments, R^{3a} has a 1,2-dihydroacenaphthyl substituent. In some embodiments, R^{3a} is:

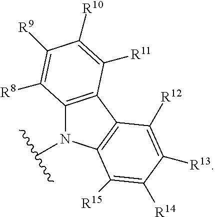

With respect to Formula 2A, R^{3b} is an optionally substituted carbazolyl, an optionally substituted benzocarbazolyl, an optionally substituted phenoxazolyl, an optionally substituted phenothiazenyl and an optionally substituted phenazinyl. In some embodiments, Any substituent may be included on R^{3b}. In some embodiments, some or all of the substituents on R^{3b} may have: from 0-10 carbon atoms and from 0-10 heteroatoms, wherein each heteroatom is independently: O, N, S, F, Cl, Br, or I (provided that there is at least 1 non-hydrogen atom); and/or a molecular weight of 15 g/mol to 500 g/mol. For example, the substituents may be C₁₋₂₀ alkyl, such as CH₃, C₂H₅, C₃H₇, cyclic C₃H₅, C₄H₉, cyclic C₄H₇, C₅H₁₁, cyclic C₅H₉, C₆H₁₃, cyclic C₆H₁₁, etc.; C₁₋₂₀ alkoxyl; C₁₋₂₀ hydroxyalkyl; halo, such as F, Cl, Br, or I; OH; CN; NO₂; C₁₋₆ fluoroalkyl, such as CF₃, CF₂H, C₂F₅, etc.; a C₁₋₁₀ ester such as —O₂CCH₃, —CO₂CH₃, —O₂CC₂H₅, —CO₂C₂H₅, —O₂C-phenyl, etc.; or a C₁₋₁₀ amine such as NH₂, NH(CH₃), N(CH₃)₂, N(CH₃)C₂H₅, etc. In some embodiments, R^{3b} has a phenyl substituent, such as unsubstituted phenyl, 4-methoxyphenyl, or 4-methylphenyl In some embodiments, R^{3b} has a 2-phenylethenyl substituent. In some embodiments, R^{3b} has a carbazolyl substituent. In some embodiments, R^{3b} has a 1,2-dihydroacenaphthyl substituent. In some embodiments, R^{3b} is:

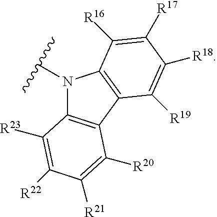

With respect to Formula 2A, R^{3c} is an optionally substituted carbazolyl, an optionally substituted benzocarbazolyl, an optionally substituted phenoxazolyl, an optionally substituted phenothiazenyl and an optionally substituted phenazinyl. In some embodiments, Any substituent may be included on R^{3c}. In some embodiments, some or all of the substituents on R^{3c} may have: from 0-10 carbon atoms and from 0-10 heteroatoms, wherein each heteroatom is independently: O, N, S, F, Cl, Br, or I (provided that there is at least 1 non-hydrogen atom); and/or a molecular weight of 15 g/mol to 500 g/mol. For example, the substituents may be C₁₋₂₀ alkyl, such as CH₃, C₂H₅, C₃H₇, cyclic C₃H₅, C₄H₉, cyclic C₄H₇, C₅H₁₁, cyclic C₅H₉, C₆H₁₃, cyclic C₆H₁₁, etc.; C₁₋₂₀ alkoxyl; C₁₋₂₀ hydroxyalkyl; halo, such as F, Cl, Br, or I; OH; CN; NO₂; C₁₋₆ fluoroalkyl, such as CF₃, CF₂H, C₂F₅, etc.; a C₁₋₁₀ ester such as —O₂CCH₃, —CO₂CH₃, —O₂CC₂H₅, —CO₂C₂H₅, —O₂C-phenyl, etc.; or a C₁₋₁₀ amine such as NH₂, NH(CH₃), N(CH₃)₂, N(CH₃)C₂H₅, etc. In some embodiments, R^{3c} has a phenyl substituent, such as unsubstituted phenyl, 4-methoxyphenyl, or 4-methylphenyl In some embodiments, R^{3c} has a 2-phenylethenyl substituent. In some embodiments, R³ has a carbazolyl substituent. In some embodiments, R^{3c} has a 1,2-dihydroacenaphthyl substituent. In some embodiments, R^{3c} is:

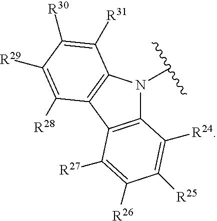

With respect to Formula 2A, R^{3d} is an optionally substituted carbazolyl, an optionally substituted benzocarbazolyl, an optionally substituted phenoxazolyl, an optionally substituted phenothiazenyl and an optionally substituted phenazinyl. In some embodiments, Any substituent may be included on R^{3d}. In some embodiments, some or all of the substituents on R^{3d} may have: from 0-10 carbon atoms and from 0-10 heteroatoms, wherein each heteroatom is independently: O, N, S, F, Cl, Br, or I (provided that there is at least 1 non-hydrogen atom); and/or a molecular weight of 15 g/mol to 500 g/mol. For example, the substituents may be C₁₋₂₀ alkyl, such as CH₃, C₂H₅, C₃H₇, cyclic C₃H₅, C₄H₉, cyclic C₄H₇, C₅H₁₁, cyclic C₅H₉, C₆H₁₃, cyclic C₆H₁₁, etc.; C₁₋₂₀ alkoxyl; C₁₋₂₀ hydroxyalkyl; halo, such as F, Cl, Br, or I; OH; CN; NO₂; C₁₋₆ fluoroalkyl, such as CF₃, CF₂H, C₂F₅, etc.; a C₁₋₁₀ ester such as —O₂CCH₃, —CO₂CH₃, —O₂CC₂H₅, —CO₂C₂H₅, —O₂C-phenyl, etc.; or a C₁₋₁₀ amine such as NH₂, NH(CH₃), N(CH₃)₂, N(CH₃)C₂H₅, etc. In some embodiments, R^{3d} has a phenyl substituent, such as unsubstituted phenyl, 4-methoxyphenyl, or 4-methylphenyl In some embodiments, R^{3d} has a 2-phenylethenyl substituent. In some embodiments, R^{3d} has a carbazolyl substituent. In some embodiments, R^{3d} has a 1,2-dihydroacenaphthyl substituent. In some embodiments, R^{3d} is:

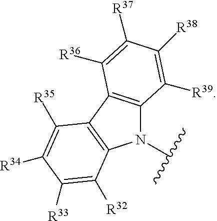

In some embodiments, R² or R₂ can be

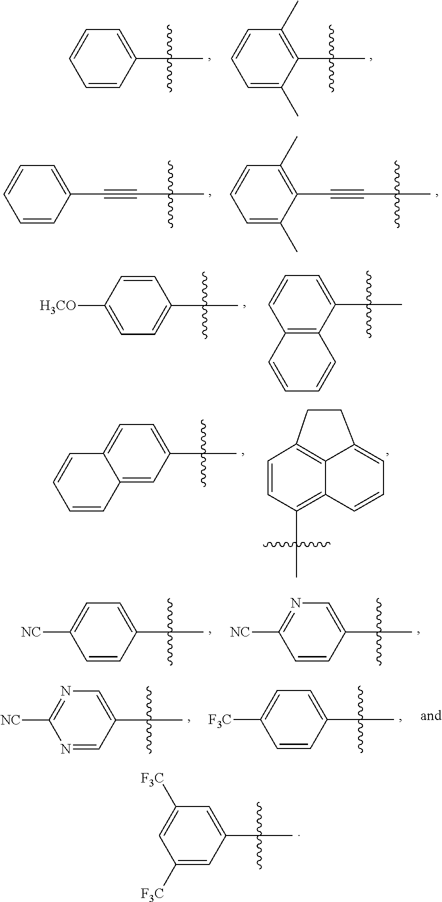

In some embodiments, an optionally substituted cbz can be

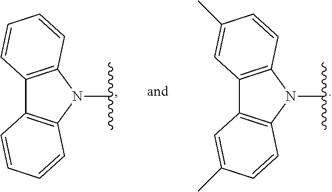 [SMILES: *n1c2ccccc2c2ccccc21 ; *n1c2ccc(C)cc2c2cc(C)ccc21]

Structures associated with some of the chemical names referred to herein are depicted below. These structures may be unsubstituted, as shown below, or a substituent may independently be in any position normally occupied by a hydrogen atom when the structure is unsubstituted. Unless a point of attachment is indicated by

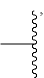

attachment may occur at any position normally occupied by a hydrogen atom.

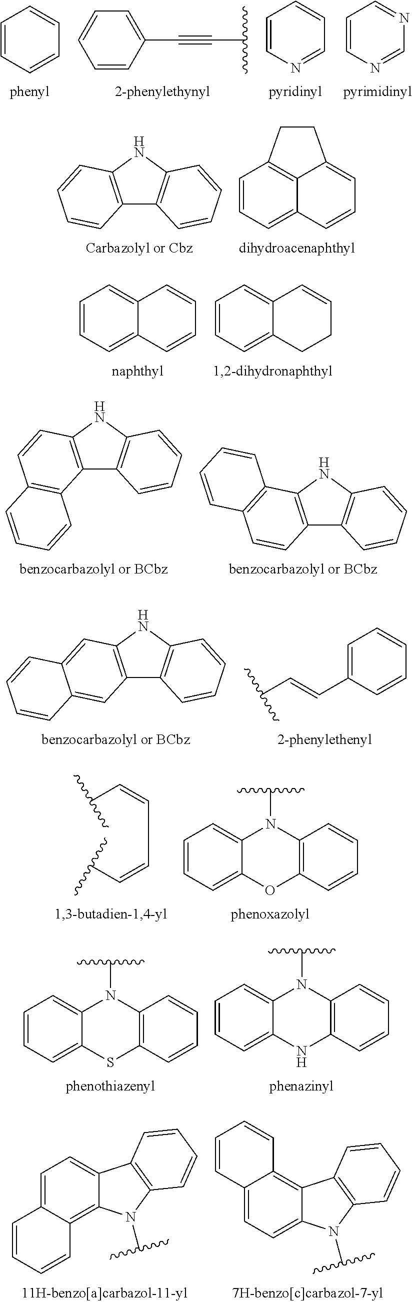

In some embodiments, R₂, R₄, R₅, R₆ and/or R₇ can be an optionally substituted aryl and/or heteroaryl. In some embodiments, R₂, R₄, R₅, R₆ and/or R₇ can be an unsubstituted aryl. In some embodiments, R₂, R₄, R₅, R₆ and/or R₇ can be a mono-substituted aryl. In some embodiments, R₂, R₄, R₅, R₆, and/or R₇ can be di-substituted aryl. In some embodiments, R₂, R₄, R₅, R₆, and/or R₇ can be an unsubstituted heteroaryl. In some embodiments, R₂, R₄, R₅, R₆, and/or R₇ can be a mono-substituted heteroaryl. In some embodiments, R₂, R₄, R₅, R₆, and/or R₇ can be a di-substituted heteroaryl. In some embodiments, R₂, R₄, R₅, R₆, and/or R₇ can be an optionally substituted phenyl, optionally substituted 2-phenylethynyl, optionally substituted naphthalene, optionally substituted 1,2-dihydroacenaphthylene, an optionally substituted pyrimidinyl and/or an optionally substituted pyridinyl. In some embodiments, the optionally substituted aryl and/or heteroaryl can be:

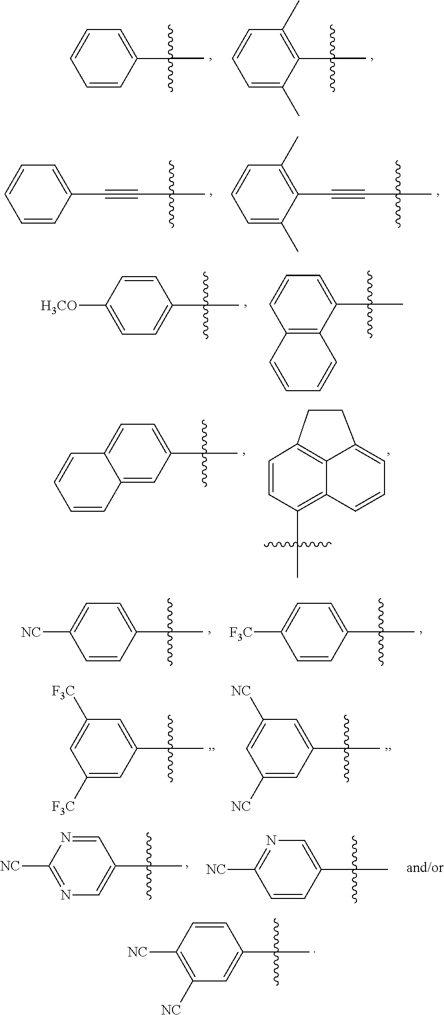

In some embodiments, R₃, and/or an optionally substituted electron donor heteroaryl, e.g., Cbz, can be

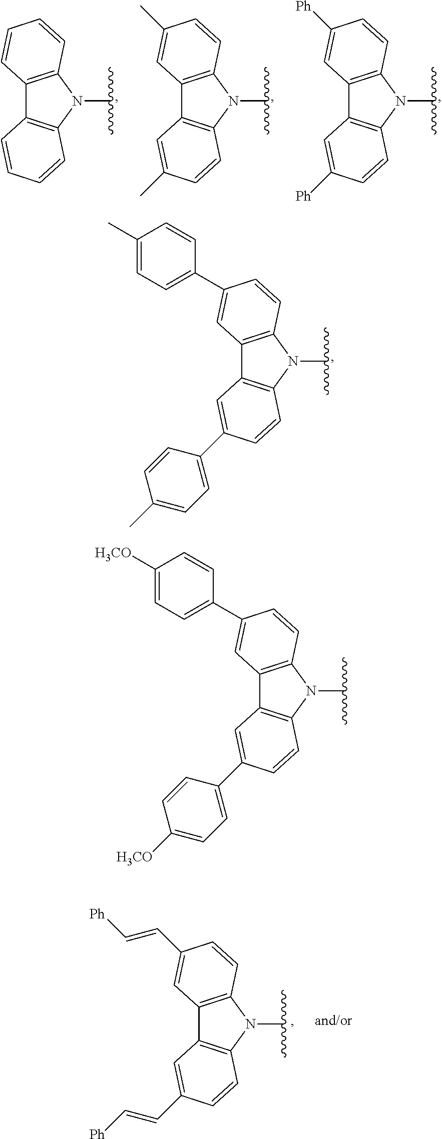

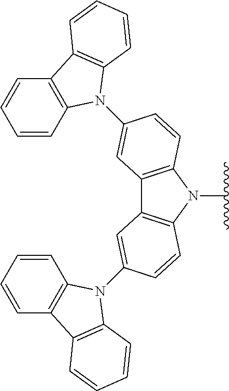 [SMILES: *n1c2ccc(-n3c4ccccc4c4ccccc43)cc2c2cc(-n3c4ccccc4c4ccccc43)ccc21]

In some embodiments, R₃ and/or an optionally substituted BCbz can be selected from:

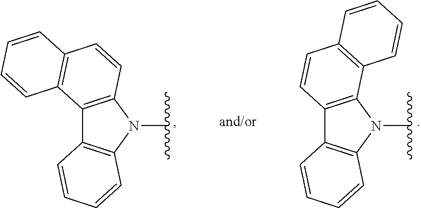 [SMILES: *n1c2ccccc2c2c3ccccc3ccc21 ; *n1c2ccccc2c2ccc3ccccc3c21]

In some embodiments, a compound for use in emissive elements of organic light emitting devices, the compound being represented by Formula 4:

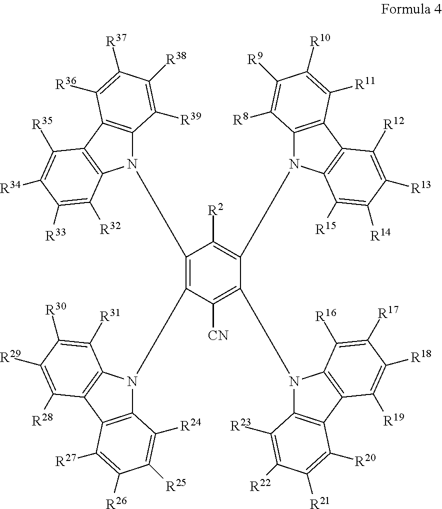

If stereochemistry is not indicated, such as in Formulas 1-4, a name or structural depiction includes any stereoisomer or any mixture of stereoisomers.

With respect to any relevant structural representation, such as Formula 2A; R⁸, R⁹, R¹⁰, R¹¹, R¹², R¹³, R¹⁴, R¹⁵, R¹⁶, R¹⁷, R¹⁸, R¹⁹, R²⁰, R²¹, R²², R²³, R²⁴, R²⁵, R²⁶, R²⁷, R²⁸, R²⁹, R³⁰, R³¹, R³², R³³, R³⁴, R³⁵, R³⁶, R³⁷, R³⁸, and R³⁹ (R⁸⁻³⁹) may independently be H or any substituent, such as a substituent having from 0 to 6 carbon atoms and from 0 to 5 heteroatoms, wherein each heteroatom is independently: O, N, S, F, Cl, Br, or I; and/or having a molecular weight of 15 g/mol to 300 g/mol, or 15 g/mol to 150 g/mol. In some embodiments, R⁸⁻³⁹ are independently optionally substituted C₆₋₁₂ aryl, optionally substituted C₄₋₁₂ heteroaryl, 2-phenylethenyl, R^{A}, F, Cl, CN, OR^{A}, CF₃, NO₂, NR^{A}R^{B}, COR^{A}, CO₂R^{A}, OCOR^{A}, NR^{A}COR^{B}, CONR^{A}R^{B}, etc. In some embodiments, R⁸⁻³⁹ are independently H; F; Cl; CN; CF₃; OH; NH₂; C₁₋₆ alkyl, such as methyl, ethyl, propyl isomers (e.g. n-propyl and isopropyl), cyclopropyl, butyl isomers, cyclobutyl isomers (e.g. cyclobutyl and methylcyclopropyl), pentyl isomers, cyclopentyl isomers, hexyl isomers, cyclohexyl isomers, etc.; or C₁₋₆ alkoxy, such as —O-methyl, —O-ethyl, isomers of —O-propyl, —O-cyclopropyl, isomers of —O-butyl, isomers of —O-cyclobutyl, isomers of —O-pentyl, isomers of —O-cyclopentyl, isomers of —O-hexyl, isomers of —O-cyclohexyl, etc.

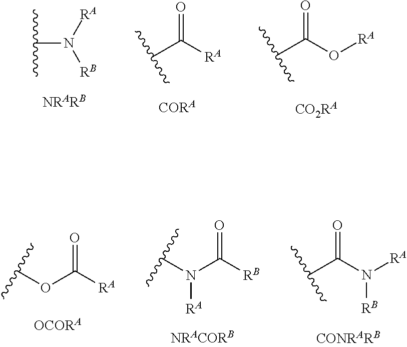

Each R^{A} may independently be H, optionally substituted phenyl, optionally substituted, carbazolyl, optionally substituted 2-phenylethenyl, or C₁₋₁₂ alkyl, including: linear or branched alkyl having a formula CₐHₐ₊₁, or cycloalkyl having a formula wherein a is 1, 2, 3, 4, 5, 6, 7, 8, 9, 10, 11, or 12, such as linear or branched alkyl of a formula: CH₃, C₂H₅, C₃H₇, C₄H₉, C₅H₁₁, C₆H₁₃, C₇H₁₅, C₉H₁₇, C₉H₁₉, C₁₀H₂₁, etc., or cycloalkyl of a formula: C₃H₅, C₄H₇, C₅H₉, C₆H₁₁, C₇H₁₃, C₈H₁₅, C₉H₁₇, C₁₀H₁₉, etc. In some embodiments, R^{A} may be H or C₁₋₆ alkyl. In some embodiments, R^{A} may be H or C₁₋₃ alkyl. In some embodiments, R^{A} may be H or CH₃. In some embodiments, R^{A} may be H.

Each R^{B} may independently be H, or C₁₋₁₂ alkyl, including: linear or branched alkyl having a formula CₐHₐ₊₁; or cycloalkyl having a formula CₐHₐ₋₁, wherein a is 1, 2, 3, 4, 5, 6, 7, 8, 9, 10, 11, or 12, such as linear or branched alkyl of a formula: CH₃, C₂H₅, C₃H₇, C₄H₉, C₅H₁₁, C₆H₁₃, C₈H₁₇, C₇H₁₅, C₉H₁₉, C₁₀H₂₁, etc., or cycloalkyl of a formula: C₃H₅, C₄H₇, C₅H₉, C₆H₁₁, C₇H₁₃, C₈H₁₅, C₉H₁₇, C₁₀H₁₉, etc. In some embodiments, R^{B} may be H or C₁₋₃ alkyl. In some embodiments, R^{B} may be H or CH₃. In some embodiments, such as R¹-R³⁹, R^{B} can be H.

With respect to any relevant structural representation, such as Formula 4, R⁸ is H, or any substituent, such as a substituent having a molecular weight of 15 mol/g to 500 mol/g. In some embodiments, R⁸ is NO₂, CN, H, F, Cl, Br, I, —CO₂H, —OH, C₁₋₆ alkylamino, C₁₋₆ alkyl, or C₁₋₆—O-alkyl. In some embodiments, R⁸ is H. In some embodiments R⁸ is optionally substituted butadienyl. Additionally, for any embodiments above in this paragraph, the remaining groups of R⁹ to R³⁹, can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R⁸ is H; R⁹, R¹¹, R¹², R¹⁴, and R¹⁵, can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R⁹ is H, or any substituent, such as a substituent having a molecular weight of 15 mol/g to 500 mol/g. In some embodiments, R⁹ is NO₂, CN, H, F, Cl, Br, I, —CO₂H, —OH, C₁₋₆ alkylamino, C₁₋₆ alkyl, or C₁₋₆—O-alkyl. In some embodiments, R⁹ is H. In some embodiments R⁹ is optionally substituted butadienyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R⁹ is H, R⁸, R¹¹, R¹², R¹⁴, and R¹⁵, can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁰ is H, or any substituent, such as a substituent having a molecular weight of 15 mol/g to 500 mol/g. In some embodiments, R¹⁰ is H. In some embodiments R¹⁰ is optionally substituted butadienyl. In some embodiments R¹⁰ is optionally substituted phenyl, such as unsubstituted phenyl, 4-methoxyphenyl, 4-methylphenyl, carbazolyl. In some embodiments R¹⁰ is optionally substituted 2-phenylethenyl. In some embodiments R¹⁰ is optionally substituted carbazolyl. Additionally, for any embodiments above in this paragraph, R⁸ to R³⁹, can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁰ is H, unsubstituted phenyl, 4-methoxyphenyl, 4-methylphenyl, carbazolyl, or 2-phenylethenyl; R⁸, R⁹, R¹¹, R¹², R¹⁴, and R¹⁵, can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹¹ is H, or any substituent, such as a substituent having a molecular weight of 15 mol/g to 500 mol/g. In some embodiments, R¹¹ is NO₂, CN, H, F, Cl, Br, I, —CO₂H, —OH, C₁₋₆ alkylamino, C₁₋₆ alkyl, or C₁₋₆—O-alkyl. In some embodiments, R¹¹ is H. In some embodiments R¹¹ is optionally substituted butadienyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹¹ is H; R⁸, R⁹, R¹², R¹⁴, and R¹⁵, can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹² is H, or any substituent, such as a substituent having a molecular weight of 15 mol/g to 500 mol/g. In some embodiments, R¹² is NO₂, CN, H, F, Cl, Br, I, —CO₂H, —OH, C₁₋₆ alkylamino, C₁₋₆ alkyl, or C₁₋₆—O-alkyl. In some embodiments, R¹² is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹² is H; R⁸, R⁹, R¹¹, R¹⁴, and R¹⁵ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹³ is H, or any substituent, such as a substituent having a molecular weight of 15 mol/g to 500 mol/g. In some embodiments, R¹³ is H. In some embodiments R¹³ is optionally substituted butadienyl. In some embodiments R¹³ is optionally substituted phenyl, such as unsubstituted phenyl, 4-methoxyphenyl, 4-methylphenyl, carbazolyl. In some embodiments R¹³ is optionally substituted 2-phenylethenyl. In some embodiments R¹³ is optionally substituted carbazolyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹³ is unsubstituted phenyl, 4-methoxyphenyl, 4-methylphenyl, carbazolyl, or 2-phenylethenyl; R⁸, R⁹, R¹⁰, R¹², R¹⁴, and R¹⁵ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁴ is H, or any substituent, such as a substituent having a molecular weight of 15 mol/g to 500 mol/g. In some embodiments, R¹⁴ is NO₂, CN, H, F, Cl, Br, I, —CO₂H, —OH, C₁₋₆ alkylamino, C₁₋₆ alkyl, or C₁₋₆—O-alkyl. In some embodiments, R¹⁴ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁴ is H; R⁸, R⁹, R¹¹, R¹², and R¹⁵ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁵ is H, or any substituent, such as a substituent having a molecular weight of 15 mol/g to 500 mol/g. In some embodiments, R¹⁵ is NO₂, CN, H, F, Cl, Br, I, —CO₂H, —OH, C₁₋₆ alkylamino, C₁₋₆ alkyl, or C₁₋₆—O-alkyl. In some embodiments, R¹⁵ is H. Additionally, for any embodiments above in this paragraph, the remaining groups of R⁸ to R³⁹, can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁵ is H; R⁸, R⁹, R¹¹, R¹², and R¹⁴ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁶ is H, or any substituent, such as a substituent having a molecular weight of 15 mol/g to 500 mol/g. In some embodiments, R¹⁶ is NO₂, CN, H, F, Cl, Br, I, —CO₂H, —OH, C₁₋₆ alkylamino, C₁₋₆ alkyl, or C₁₋₆—O-alkyl. In some embodiments, R¹⁶ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁶ is H; R¹⁷, R¹⁹, R²⁰, R²², and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁷ is H, or any substituent, such as a substituent having a molecular weight of 15 mol/g to 500 mol/g. In some embodiments, R¹⁷ is NO₂, CN, H, F, Cl, Br, I, —CO₂H, —OH, C₁₋₆ alkylamino, C₁₋₆ alkyl, or C₁₋₆—O-alkyl. In some embodiments, R¹⁷ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁷ is H; R¹⁶, R¹⁹, R²⁰, R²², and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁸ is H, or any substituent, such as a substituent having a molecular weight of 15 mol/g to 500 mol/g. In some embodiments, R¹⁸ is H. In some embodiments R¹⁸ is optionally substituted butadienyl. In some embodiments R¹⁸ is optionally substituted phenyl, such as unsubstituted phenyl, 4-methoxyphenyl, 4-methylphenyl, carbazolyl. In some embodiments R¹⁸ is optionally substituted 2-phenylethenyl. In some embodiments R¹⁸ is optionally substituted carbazolyl. Additionally, for any embodiments above in this paragraph, R⁸ to R³⁹, can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁸ is H, phenyl, carbazolyl, or 2-phenylethenyl; R¹⁶, R¹⁷, R¹⁹, R²⁰, R²², and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R¹⁹ is H, or any substituent, such as a substituent having a molecular weight of 15 mol/g to 500 mol/g. In some embodiments, R¹⁹ is NO₂, CN, H, F, Cl, Br, I, —CO₂H, —OH, C₁₋₆ alkylamino, C₁₋₆ alkyl, or C₁₋₆—O-alkyl. In some embodiments, R¹⁹ is H. In some embodiments, R¹⁹ is optionally substituted butadienyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R¹⁹ is H; R¹⁶, R¹⁷, R²⁰, R²², and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁰ is H, or any substituent, such as a substituent having a molecular weight of 15 mol/g to 500 mol/g. In some embodiments, R²⁰ is NO₂, CN, H, F, Cl, Br, I, —CO₂H, —OH, C₁₋₆ alkylamino, C₁₋₆ alkyl, or C₁₋₆—O-alkyl. In some embodiments, R²⁰ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁰ is H; R¹⁶, R¹⁷, R¹⁹, R²², and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²¹ is H, or any substituent, such as a substituent having a molecular weight of 15 mol/g to 500 mol/g. In some embodiments, R²¹ is H. In some embodiments R²¹ is optionally substituted butadienyl. In some embodiments R²¹ is optionally substituted phenyl, such as unsubstituted phenyl, 4-methoxyphenyl, 4-methylphenyl, carbazolyl. In some embodiments R²¹ is optionally substituted 2-phenylethenyl. In some embodiments R²¹ is optionally substituted carbazolyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²¹ is H, unsubstituted phenyl, 4-methoxyphenyl, 4-methylphenyl, carbazolyl, or 2-phenylethenyl; R¹⁶, R¹⁷, R¹⁹, R²⁰, R²², and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²² is H, or any substituent, such as a substituent having a molecular weight of 15 mol/g to 500 mol/g. In some embodiments, R²² is NO₂, CN, H, F, Cl, Br, I, —CO₂H, —OH, C₁₋₆ alkylamino, C₁₋₆ alkyl, or C₁₋₆—O-alkyl. In some embodiments, R²² is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²² is H; R¹⁶, R¹⁷, R¹⁹, R²⁰, and R²³ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²³ is H, or any substituent, such as a substituent having a molecular weight of 15 mol/g to 500 mol/g. In some embodiments, R²³ is NO₂, CN, H, F, Cl, Br, I, —CO₂H, —OH, C₁₋₆ alkylamino, C₁₋₆ alkyl, or C₁₋₆—O-alkyl. In some embodiments, R²³ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²³ is H; R¹⁶, R¹⁷, R¹⁹, R²⁰, and R²² can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁴ is H, or any substituent, such as a substituent having a molecular weight of 15 mol/g to 500 mol/g. In some embodiments, R²⁴ is NO₂, CN, H, F, Cl, Br, I, —CO₂H, —OH, C₁₋₆ alkylamino, C₁₋₆ alkyl, or C₁₋₆—O-alkyl. In some embodiments, R²⁴ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁴ is H; R²⁵, R²⁷, R²⁸, R³⁰, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁵ is H, or any substituent, such as a substituent having a molecular weight of 15 mol/g to 500 mol/g. In some embodiments, R²⁵ is NO₂, CN, H, F, Cl, Br, I, —CO₂H, —OH, C₁₋₆ alkylamino, C₁₋₆ alkyl, or C₁₋₆—O-alkyl. In some embodiments, R²⁵ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁵ is H, R²⁴, R²⁷, R²⁸, R³⁰, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁶ is H, or any substituent, such as a substituent having a molecular weight of 15 mol/g to 500 mol/g. In some embodiments, R²⁶ is H. In some embodiments R²⁶ is optionally substituted butadienyl. In some embodiments R²⁶ is optionally substituted phenyl, such as unsubstituted phenyl, 4-methoxyphenyl, 4-methylphenyl, carbazolyl. In some embodiments R²⁶ is optionally substituted 2-phenylethenyl. In some embodiments R²⁶ is optionally substituted carbazolyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁶ is H, unsubstituted phenyl, 4-methoxyphenyl, 4-methylphenyl, carbazolyl, or 2-phenylethenyl; R²⁴, R²⁵, R²⁷, R²⁸, R³⁰, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁷ is H, or any substituent, such as a substituent having a molecular weight of 15 mol/g to 500 mol/g. In some embodiments, R²⁷ is NO₂, CN, H, F, Cl, Br, I, —CO₂H, —OH, C₁₋₆ alkylamino, C₁₋₆ alkyl, or C₁₋₆—O-alkyl. In some embodiments, R²⁷ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁷ is H; R²⁴, R²⁵, R²⁸, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁸ is H, or any substituent, such as a substituent having a molecular weight of 15 mol/g to 500 mol/g. In some embodiments, R²⁸ is NO₂, CN, H, F, Cl, Br, I, —CO₂H, —OH, C₁₋₆ alkylamino, C₁₋₆ alkyl, or C₁₋₆—O-alkyl. In some embodiments, R²⁸ is H. In some embodiments R²⁸ is optionally substituted butadienyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁸ is H; R²⁴, R²⁵, R²⁷, R³⁰, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R²⁹ is H, or any substituent, such as a substituent having a molecular weight of 15 mol/g to 500 mol/g. In some embodiments, R²⁹ is H. In some embodiments R²⁹ is optionally substituted butadienyl. In some embodiments R²⁹ is optionally substituted phenyl, such as unsubstituted phenyl, 4-methoxyphenyl, 4-methylphenyl, carbazolyl. In some embodiments R²⁹ is optionally substituted 2-phenylethenyl. In some embodiments R²⁹ is optionally substituted carbazolyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R²⁹ is H, unsubstituted phenyl, 4-methoxyphenyl, 4-methylphenyl, carbazolyl, or 2-phenylethenyl; R²⁴, R²⁵, R²⁷, R²⁸, R³⁰, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁰ is H, or any substituent, such as a substituent having a molecular weight of 15 mol/g to 500 mol/g. In some embodiments, R³⁰ is NO₂, CN, H, F, Cl, Br, I, —CO₂H, —OH, C₁₋₆ alkylamino, C₁₋₆ alkyl, or C₁₋₆—O-alkyl. In some embodiments, R³⁰ is H. Additionally, for any embodiments above in this paragraph, the remaining groups of R⁸ to R³⁹, can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁰ is H; R²⁴, R²⁵, R²⁶, R²⁷, R²⁸, R²⁹, and R³¹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³¹ is H, or any substituent, such as a substituent having a molecular weight of 15 mol/g to 500 mol/g. In some embodiments, R³¹ is NO₂, CN, H, F, Cl, Br, I, —CO₂H, —OH, C₁₋₆ alkylamino, C₁₋₆ alkyl, or C₁₋₆—O-alkyl. In some embodiments, R³¹ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³¹ is H; R²⁴, R²⁵, R²⁷, R²⁸, and R³⁰ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³² is H, or any substituent, such as a substituent having a molecular weight of 15 mol/g to 500 mol/g. In some embodiments, R³² is NO₂, CN, H, F, Cl, Br, I, —CO₂H, —OH, C₁₋₆ alkylamino, C₁₋₆ alkyl, or C₁₋₆—O-alkyl. In some embodiments, R³² is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³² is H; R³³, R³⁵, R³⁶, R³⁸, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³³ is H, or any substituent, such as a substituent having a molecular weight of 15 mol/g to 500 mol/g. In some embodiments, R³³ is NO₂, CN, H, F, Cl, Br, I, —CO₂H, —OH, C₁₋₆ alkylamino, C₁₋₆ alkyl, or C₁₋₆—O-alkyl. In some embodiments, R³³ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³³ is H; R³², R³⁵, R³⁶, R³⁸, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁴ is H, or any substituent, such as a substituent having a molecular weight of 15 mol/g to 500 mol/g. In some embodiments, R³⁴ is H. In some embodiments R³⁴ is optionally substituted butadienyl. In some embodiments R³⁴ is phenyl. In some embodiments R³⁴ is optionally substituted 2-phenylethenyl. In some embodiments R³⁴ is optionally substituted carbazolyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁴ is H, unsubstituted phenyl, 4-methoxyphenyl, 4-methylphenyl, carbazolyl, or 2-phenylethenyl; R³², R³³, R³⁵, R³⁶, R³⁸, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁵ is H, or any substituent, such as a substituent having a molecular weight of 15 mol/g to 500 mol/g. In some embodiments, R³⁵ is NO₂, CN, H, F, Cl, Br, I, —CO₂H, —OH, C₁₋₆ alkylamino, C₁₋₆ alkyl, or C₁₋₆—O-alkyl. In some embodiments, R³⁵ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁵ is H; R³², R³³, R³⁶, R³⁸, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁶ is H, or any substituent, such as a substituent having a molecular weight of 15 mol/g to 500 mol/g. In some embodiments, R³⁶ is NO₂, CN, H, F, Cl, Br, I, —CO₂H, —OH, C₁₋₆ alkylamino, C₁₋₆ alkyl, or C₁₋₆—O-alkyl. In some embodiments, R³⁶ is H. In some embodiments R³⁶ is optionally substituted butadienyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁶ is H; R³², R³³, R³⁵, R³⁸, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁷ is H, or any substituent, such as a substituent having a molecular weight of 15 mol/g to 500 mol/g. In some embodiments, R³⁷ is H. In some embodiments R³⁷ is optionally substituted butadienyl. In some embodiments R³⁷ is phenyl. In some embodiments R³⁷ is optionally substituted 2-phenylethenyl. In some embodiments R³⁷ is optionally substituted carbazolyl. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁷ is H, unsubstituted phenyl, 4-methoxyphenyl, 4-methylphenyl, carbazolyl, or 2-phenylethenyl; R³², R³³, R³⁵, R³⁶, R³⁸, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁸ is H, or any substituent, such as a substituent having a molecular weight of 15 mol/g to 500 mol/g. In some embodiments, R³⁸ is NO₂, CN, H, F, Cl, Br, I, —CO₂H, —OH, C₁₋₆ alkylamino, C₁₋₆ alkyl, or C₁₋₆—O-alkyl. In some embodiments, R³⁸ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁸ is H; R³², R³³, R³⁵, R³⁶, and R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

With respect to any relevant structural representation, such as Formula 4, R³⁹ is H, or any substituent, such as a substituent having a molecular weight of 15 mol/g to 500 mol/g. In some embodiments, R³⁹ is NO₂, CN, H, F, Cl, Br, I, —CO₂H, —OH, C₁₋₆ alkylamino, C₁₋₆ alkyl, or C₁₋₆—O-alkyl. In some embodiments, R³⁹ is H. Additionally, for any embodiments above in this paragraph, the remaining groups of R⁸ to R³⁹ can independently be: R^{A}, F, Cl, CN, OR^{A}, CF₃, NO₂, NR^{A}R^{B}, COR^{A}, CO₂R^{A}, OCOR^{A}, NR^{A}COR^{B}, or CONR^{A}R^{B}; or H, F, Cl, CN, CF₃, OH, NH₂, C₁₋₆ alkyl, or C₁₋₆ alkoxy. In some embodiments wherein R³⁹ is H; R³², R³³, R³⁵, R³⁶, and R³⁸ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R⁸ and R⁹ together form optionally substituted 1,3-butadien-1,4-yl as part of a 6-membered ring incorporating the carbons to which R⁸ and R⁹ are attached. When this occurs, R^{3a} can be optionally substituted 11H-benzo[a]carbazol-11-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R¹⁰ and R¹¹ together form optionally substituted 1,3-butadien-1,4-yl as part of a 6-membered ring incorporating the carbons to which R¹⁰ and R¹¹ are attached. When this occurs, R^{3a} can be optionally substituted 7H-benzo[c]carbazol-7-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R²² and R²³ together form optionally substituted 1,3-butadien-1,4-yl as part of a 6-membered ring incorporating the carbons to which R²² and R²³ are attached. When this occurs, R^{3b} can be optionally substituted 11H-benzo[a]carbazol-11-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R¹⁸ and R¹⁹ together form optionally substituted 1,3-butadien-1,4-yl as part of a 6-membered ring incorporating the carbons to which R¹⁸ and R¹⁹ are attached. When this occurs, R^{3b} can be optionally substituted 7H-benzo[c]carbazol-7-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R²⁴ and R²⁵ together form optionally substituted 1,3-butadien-1,4-yl as part of a 6-membered ring incorporating the carbons to which R²⁴ and R²⁵ are attached. When this occurs, R^{3c} can be optionally substituted 11H-benzo[a]carbazol-11-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R²⁸ and R²⁹ together form optionally substituted 1,3-butadien-1,4-yl as part of a 6-membered ring incorporating the carbons to which R²⁸ and R²⁹ are attached. When this occurs, R^{3c} can be optionally substituted 7H-benzo[c]carbazol-7-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R³⁸ and R³⁹ together form optionally substituted 1,3-butadien-1,4-yl as part of a 6-membered ring incorporating the carbons to which R³⁸ and R³⁹ are attached. When this occurs, R^{3d} can be optionally substituted 11H-benzo[a]carbazol-11-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

In some embodiments R³⁶ and R³⁷ together form optionally substituted 1,3-butadien-1,4-yl as part of a 6-membered ring incorporating the carbons to which R³⁶ and R³⁷ are attached. When this occurs, R^{3d} can be optionally substituted 7H-benzo[c]carbazol-7-yl. In some such embodiments, the remaining groups of R⁸ to R³⁹ can independently be H, C₁₋₄ alkyl, OH, C₁₋₄—O-alkyl, —CHO, C₂₋₄—CO-alkyl, C₂₋₄—CO-alkyl, CO₂H, C₂₋₄—CO₂-alkyl, F, Cl, Br, I, NO₂, or CN.

The structures associated with some of the chemical names referred to herein are depicted below. These structures may be unsubstituted, as shown below, or a substituent may independently be in any position normally occupied by a hydrogen atom when the structure is unsubstituted. Unless a point of attachment is indicated by

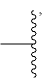

attachment may occur at any position normally occupied by a hydrogen atom.

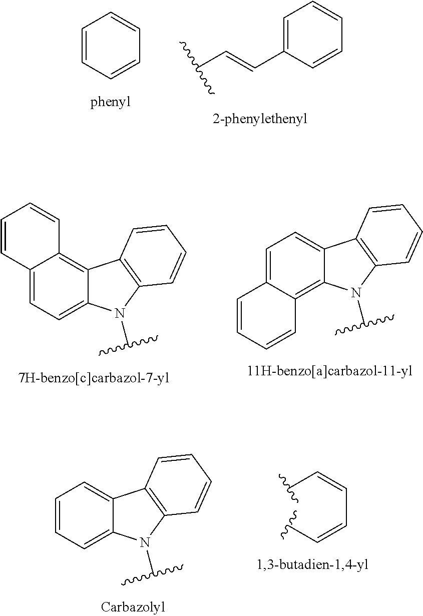 [SMILES: c1ccccc1 ; */C=C/c1ccccc1 ; *n1c2ccccc2c2c3ccccc3ccc21 ; *n1c2ccccc2c2ccc3ccccc3c21 ; *n1c2ccccc2c2ccccc21 ; */C=C\C=C/*]

In some embodiments, the compound can be:

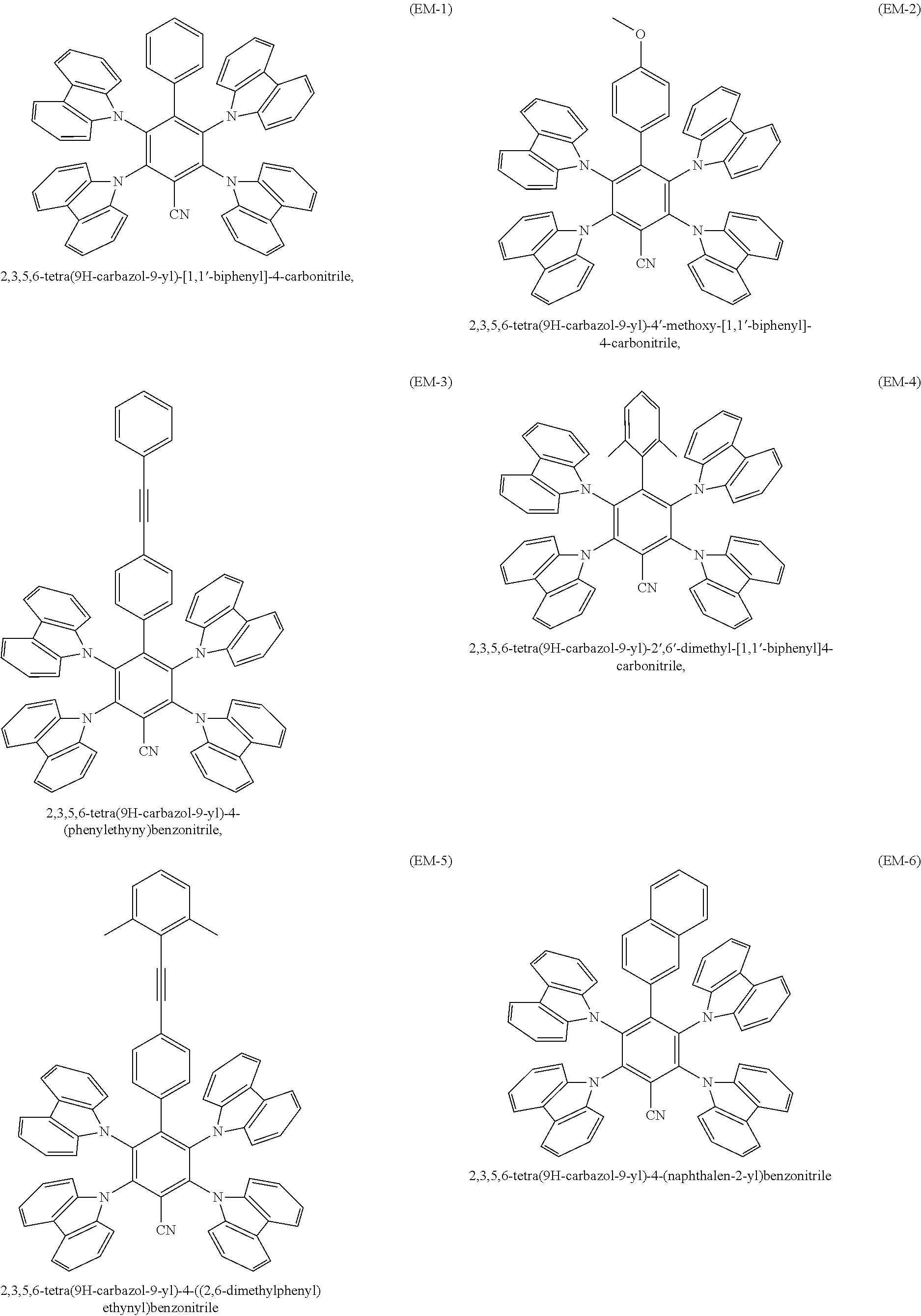

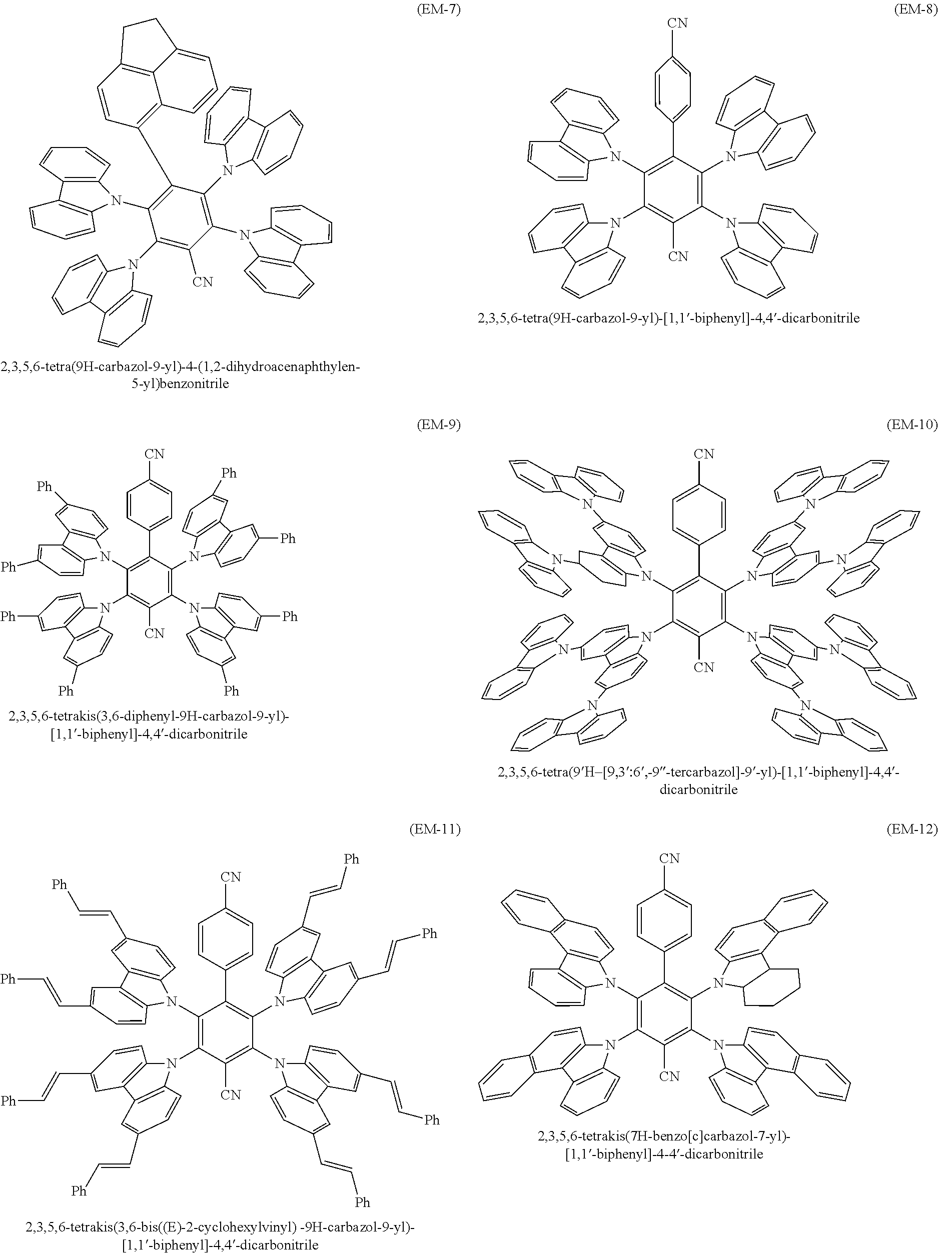

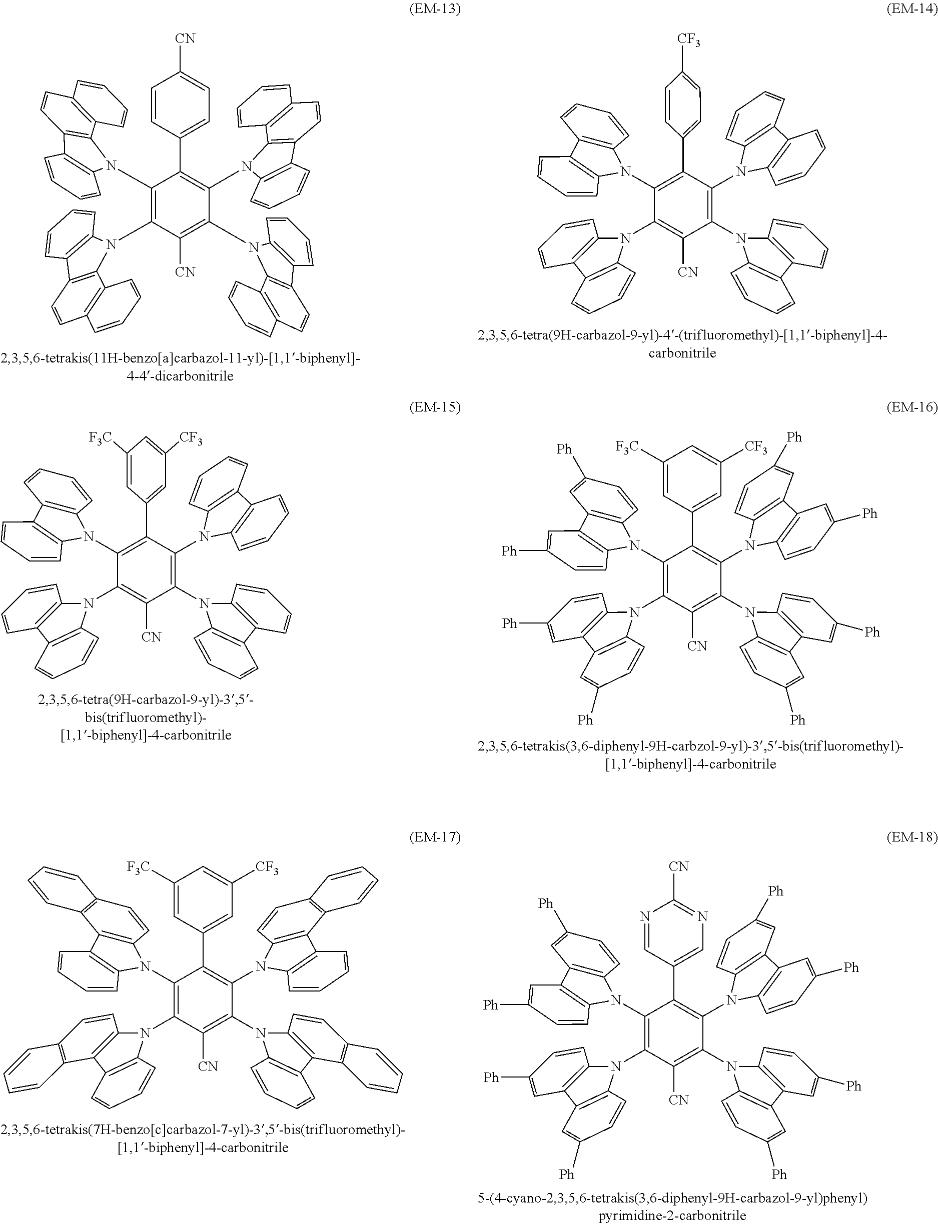

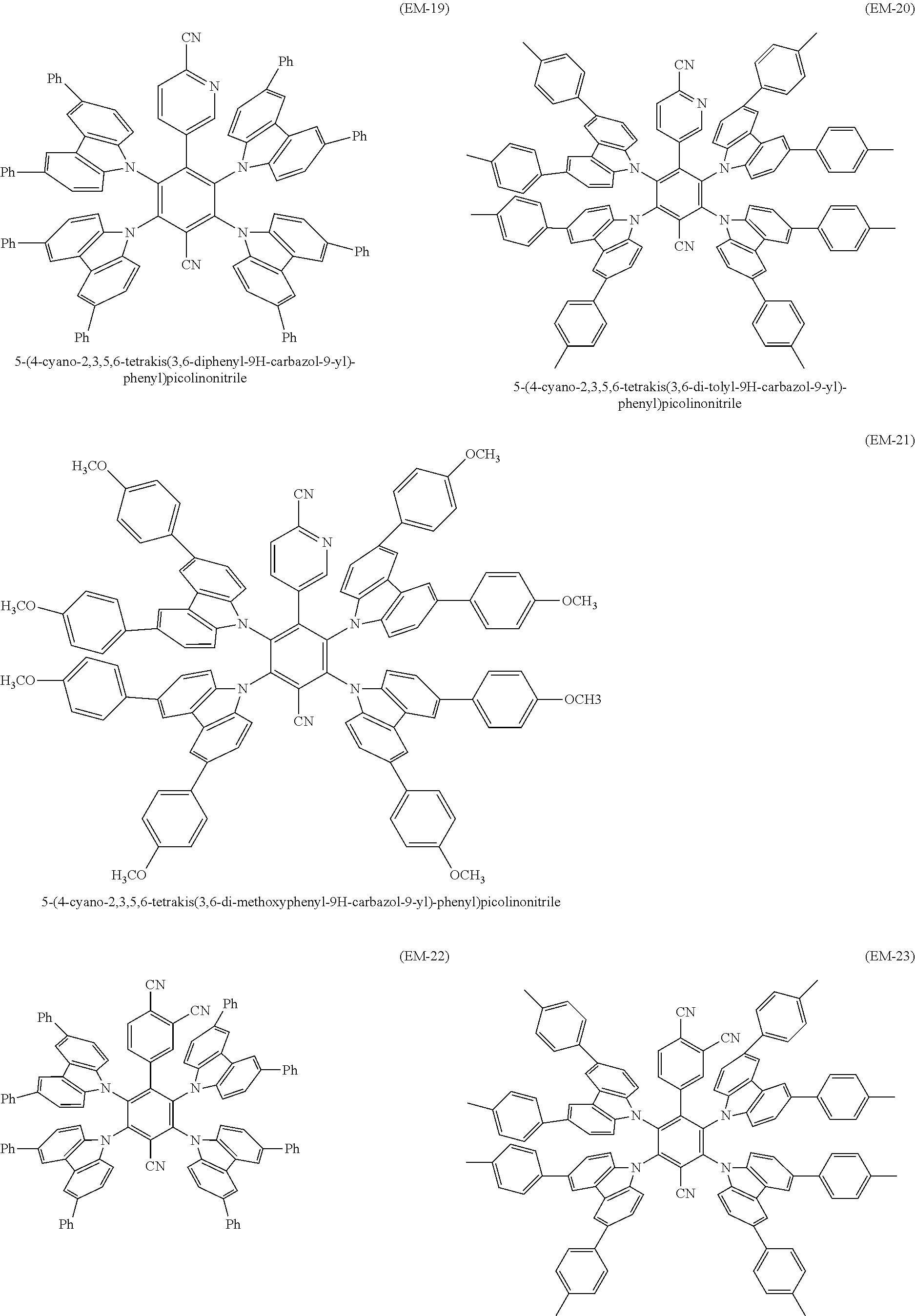

In some embodiments, an emissive layer can comprise any or all of the compounds described above.

In another embodiment, an emissive element is described comprising any or all of the aforementioned compounds.

In another embodiment, a device is described comprising any or all of the aforementioned compounds.

In some embodiments, the compound described is an emissive compound. In some embodiments, the compound described can be used in emissive elements of organic light emitting devices.

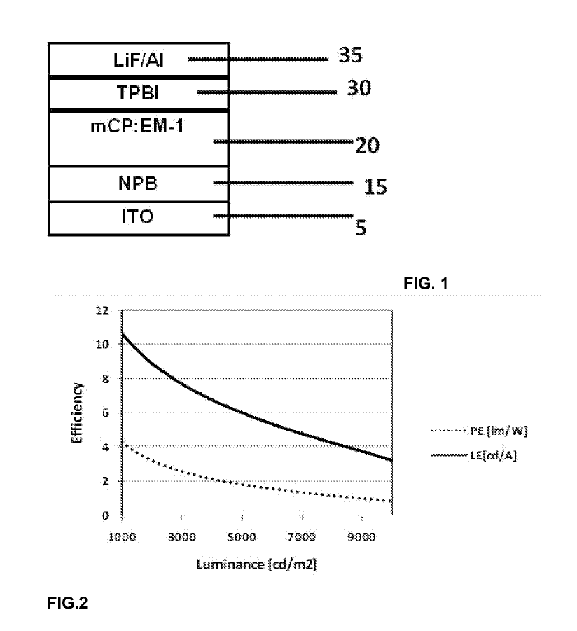

As shown in FIG. 1, there is shown an embodiment of an organic light emitting device incorporating the compounds of the present application. The embodiment also provide an organic light-emitting diode device 10 comprising a cathode 20, an anode 30, a light-emitting layer 40 disposed between and electrically connected to the anode and the cathode, a hole-transport layer 50 between the anode and the light-emitting layer 40 and an electron-transport layer 60 between the cathode 30 and the light-emitting layer 40, wherein at least one of the light-emitting layer, the hole-transport layer and the electron-transport layer comprise a host compound described herein. In some embodiments, a hole injection layer 70 can be between the anode 20 and the hole transport layer 50.

An anode layer may comprise a conventional material such as a metal, mixed metal, alloy, metal oxide or mixed-metal oxide, or a conductive polymer. Examples of suitable metals include the Group 1 metals, the metals in Groups 4, 5, 6, and the Group 8-10 transition metals. If the anode layer is to be light-transmitting, mixed-metal oxides of Group 12, 13, and 14 metals or alloys thereof, such as Au, Pt, and indium-tin-oxide (ITO), may be used. The anode layer may include an organic material such as polyaniline, e.g., as described in “Flexible light-emitting diodes made from soluble conducting polymer,” Nature, vol. 357, pp. 477-479 (11 Jun. 1992). Examples of suitable high work function metals include but are not limited to Au, Pt, indium-tin-oxide (ITO), or alloys thereof. In some embodiments, the anode layer can have a thickness in the range of about 1 nm to about 1000 nm.

A cathode layer may include a material having a lower work function than the anode layer. Examples of suitable materials for the cathode layer include those selected from alkali metals of Group 1, Group 2 metals, Group 12 metals including rare earth elements, lanthanides and actinides, materials such as aluminum, indium, calcium, barium, samarium and magnesium, and combinations thereof. Li-containing organometallic compounds, LiF, and Li₂O may also be deposited between the organic layer and the cathode layer to lower the operating voltage. Suitable low work function metals include but are not limited to Al, Ag, Mg, Ca, Cu, Mg/Ag, LiF/Al, CsF, CsF/Al or alloys thereof. In some embodiments, the cathode layer can have a thickness in the range of about 1 nm to about 1000 nm.

In some embodiments, the light-emissive layer may further comprise an emissive component or compound. The emissive component may be a fluorescent and/or a phosphorescent compound. In some embodiments, the emissive component comprises a phosphorescent material. In some embodiments, the emissive component may comprise a dopant. In some embodiments, the dopant is from about 0.01% (w/w) of the host, from about 1% of the host, up to about 15% (w/w), up to about 20% (w/w), about 15% (w/w) of the host.

The thickness of the light-emitting layer may vary. In some embodiments, the light-emitting layer has a thickness from about 20 nm to about 200 nm. In some embodiments, the light-emitting layer has a thickness in the range of about 20 nm to about 150 nm.

In some embodiments, the light-emitting layer can further include additional host material. Exemplary host materials are known to those skilled in the art. For example, host materials described in U.S. Pat. No. 8,003,229, United States Patent Publication US2012/0193614, filed 27 Jan. 2012; United States Patent Publication US2013/0075706, filed 18 Sep. 2012; and United States Patent Publication US/2012/0179389, filed 14 Sep. 2011, which are incorporated by reference in their entirety for their description of host compounds. For example, the host material included in the light-emitting layer can be an optionally substituted compound selected from: an aromatic-substituted amine, an aromatic-substituted phosphine, a thiophene, an oxadiazole, 2-(4-biphenylyl)-5-(4-tert-butylphenyl)-1,3,4-oxadiazole (PBD), 1,3-bis(N,N-t-butyl-phenyl)-1,3,4-oxadiazole (OXD-7), a triazole, 3-phenyl-4-(1′-naphthyl)-5-phenyl-1,2,4-triazole (TAZ), 3,4,5-Triphenyl-1,2,3-triazole, 3,5-Bis(4-tert-butyl-phenyl)-4-phenyl[1,2,4]triazole, an aromatic phenanthroline, 2,9-dimethyl-4,7-diphenyl-phenanthroline (bathocuproine or BCP), 2,9-Dimethyl-4,7-diphenyl-1,10-phenanthroline, a benzoxazole, a benzothiazole, a quinoline, aluminum tris(8-hydroxyquinolate) (Alq3), a pyridine, a dicyanoimidazole, cyano-substituted aromatic, 1,3,5-tris(2-N-phenylbenzimidazolyl)benzene (TPBI), 4,4′-bis[N-(naphthyl)-N-phenyl-amino]biphenyl (α-NPD), N,N′-bis(3-methylphenyl)N,N′-diphenyl-[1,1′-biphenyl]-4,4′-diamine (TPD), 4,4′-bis[N,N′-(3-tolyl)amino]-3,3′-dimethylbiphenyl (M14), 4,4′-bis[N,N′-(3-tolyl)amino]-3,3′-dimethylbiphenyl (HMTPD), 1,1-Bis(4-bis(4-methylphenyl)aminophenyl)cyclohexane, a carbazole, 4,4′-N,N′-dicarbazole-biphenyl (CBP), 1,3-N,N-dicarbazole-benzene (mCP); 4,4′4″-tri(N-carbazolyl)triphenylamine (TcTa), poly(9-vinylcarbazole) (PVK), N,N′N″-1,3,5-tricarbazoloylbenzene (tCP), a polythiophene, a benzidine, N,N′-bis(4-butylphenyl)-N,N′-bis(phenyl)benzidine, a triphenylamine, 4,4′,4″-Tris(N-(naphthylen-2-yl)-N-phenylamino)triphenylamine, 4,4′,4″-tris(3-methylphenylphenylamino)triphenylamine (MTDATA), a phenylenediamine, a polyacetylene, and a phthalocyanine metal complex.

In some embodiments, the light-emitting device may further comprise a hole-transport layer between the anode and the light-emitting layer and an electron-transport layer between the cathode and the light-emitting layer. In some embodiments, all of the light-emitting layer, the hole-transport layer and the electron-transport layer comprise the host compound described herein.

In some embodiments, the hole-transport layer may comprise at least one hole-transfer material. Suitable hole-transport materials are known to those skilled in the art. Exemplary hole-transport materials include: 1,1-Bis(4-bis(4-methylphenyl)aminophenyl)cyclohexane; 2,9-Dimethyl-4,7-diphenyl-1,10-phenanthroline; 3,5-Bis(4-tert-butyl-phenyl)-4-phenyl[1,2,4]triazole; 3,4,5-Triphenyl-1,2,3-triazole; 4,4′,4″-Tris(N-(naphthylen-2-yl)-N-phenylamino)triphenylamine; 4,4′,4′-tris(3-methylphenylphenylamino)triphenylamine (MTDATA); 4,4′-bis[N-(naphthyl)-N-phenyl-amino]biphenyl (α-NPD); 4,4′-bis[N,N′-(3-tolyl)amino]-3,3′-dimethylbiphenyl (HMTPD); 4,4′-bis[N,N′-(3-tolyl)amino]-3,3′-dimethylbiphenyl (M14); 4,4′-N,N′-dicarbazole-biphenyl (CBP); 1,3-N,N-dicarbazole-benzene (mCP); poly(9-vinylcarbazole) (PVK); a benzidine; a carbazole; a phenylenediamine; a phthalocyanine metal complex; a polyacetylene; a polythiophene; a triphenylamine; an oxadiazole; copper phthalocyanine; N,N′-bis(3-methylphenyl)N,N′-diphenyl-[1,1′-biphenyl]-4,4′-diamine (TPD); N,N′N″-1,3,5-tricarbazoloylbenzene (tCP); N,N′-bis(4-butylphenyl)-N,N′-bis(phenyl)benzidine; 4,4′-bis[N-(1-napthyl)-N-phenylamino]biphenyl (NPB), 4,4′4″-tri(N-carbazolyl)triphenylamine (TcTa) and the like.

In some embodiments, the electron-transport layer may comprise at least one electron-transfer material. Suitable electron transport materials are known to those skilled in the art. Exemplary electron transport materials that can be included in the electron transport layer are an optionally substituted compound selected from: aluminum tris(8-hydroxyquinolate) (Alq3), 2-(4-biphenylyl)-5-(4-tert-butylphenyl)-1,3,4-oxadiazole (PBD), 1,3-bis(N,N-t-butyl-phenyl)-1,3,4-oxadiazole (OXD-7), 1,3-bis[2-(2,2′-bipyridine-6-yl)-1,3,4-oxadiazo-5-yl]benzene (BPY-OXD), 3-phenyl-4-(1′-naphthyl)-5-phenyl-1,2,4-triazole (TAZ), 2,9-dimethyl-4,7-diphenyl-phenanthroline (bathocuproine or BCP), and 1,3,5-tris[2-N-phenylbenzimidazol-z-yl]benzene (TPBI). In one embodiment, the electron transport layer is aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl]benzene (TPBI), or a derivative or a combination thereof.

If desired, additional layers may be included in the light-emitting device. Additional layers that may be included include an electron injection layer (EIL), hole blocking layer (HBL), exciton blocking layer (EBL), and/or hole injection layer (HIL). In addition to separate layers, some of these materials may be combined into a single layer.

In some embodiments, the light-emitting device can include an electron injection layer between the cathode layer and the light emitting layer. In some embodiments, the lowest un-occupied molecular orbital (LUMO) energy level of the material(s) that can be included in the electron injection layer is high enough to prevent it from receiving an electron from the light emitting layer. In other embodiments, the energy difference between the LUMO of the material(s) that can be included in the electron injection layer and the work function of the cathode layer is small enough to allow efficient electron injection from the cathode. A number of suitable electron injection materials are known to those skilled in the art. Examples of suitable material(s) that can be included in the electron injection layer include but are not limited to, an optionally substituted compound selected from the following: aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl]benzene (TPBI) a triazine, a metal chelate of 8-hydroxyquinoline such as tris(8-hydroxyquinoliate)aluminum, and a metal thioxinoid compound such as bis(8-quinolinethiolato) zinc. In one embodiment, the electron injection layer is aluminum quinolate (Alq₃), 2-(4-biphenylyl)-5-(4-tert-butylphenyl)-1,3,4-oxadiazole (PBD), phenanthroline, quinoxaline, 1,3,5-tris[N-phenylbenzimidazol-z-yl]benzene (TPBI), or a derivative or a combination thereof.

In some embodiments, the device can include a hole blocking layer, e.g., between the cathode and the light-emitting layer. Various suitable hole blocking materials that can be included in the hole blocking layer are known to those skilled in the art. Suitable hole blocking material(s) include but are not limited to, an optionally substituted compound selected from the following: bathocuproine (BCP), 3,4,5-triphenyl-1,2,4-triazole, 3,5-bis(4-tert-butyl-phenyl)-4-phenyl-[1,2,4]triazole, 2,9-dimethyl-4,7-diphenyl-1,10-phenanthroline, and 1,1-bis(4-bis(4-methylphenyl)aminophenyl)-cyclohexane.

In some embodiments, the light-emitting device can include an exciton blocking layer, e.g., between the light-emitting layer and the anode. In one embodiment, the band gap of the material(s) that comprise exciton blocking layer is large enough to substantially prevent the diffusion of excitons. A number of suitable exciton blocking materials that can be included in the exciton blocking layer are known to those skilled in the art. Examples of material(s) that can compose an exciton blocking layer include an optionally substituted compound selected from the following: aluminum quinolate (Alq₃), 4,4′-bis[N-(naphthyl)-N-phenyl-amino]biphenyl (α-NPD), 4,4′-N,N′-dicarbazole-biphenyl (CBP), and bathocuproine (BCP), and any other material(s) that have a large enough band gap to substantially prevent the diffusion of excitons.

In some embodiments, the light-emitting device can include a hole injection layer, e.g., between the light-emitting layer and the anode. Various suitable hole injection materials that can be included in the hole injection layer are known to those skilled in the art. Exemplary hole injection material(s) include an optionally substituted compound selected from the following: a polythiophene derivative such as poly(3,4-ethylenedioxythiophene (PEDOT)/polystyrene sulphonic acid (PSS), a benzidine derivative such as N,N,N′,N′-tetraphenylbenzidine, poly(N,N′-bis(4-butylphenyl)-N,N′-bis(phenyl)benzidine), a triphenylamine or phenylenediamine derivative such as N,N′-bis(4-methylphenyl)-N,N′-bis(phenyl)-1,4-phenylenediamine, 4,4′,4″-tris(N-(naphthylen-2-yl)-N-phenylamino)triphenylamine, an oxadiazole derivative such as 1,3-bis(5-(4-diphenylamino)phenyl-1,3,4-oxadiazol-2-yl)benzene, a polyacetylene derivative such as poly(1,2-bis-benzylthio-acetylene), and a phthalocyanine metal complex derivative such as phthalocyanine copper. Hole-injection materials, while still being able to transport holes, may have a hole mobility substantially less than the hole mobility of conventional hole transport materials.

Those skilled in the art would recognize that the various materials described above can be incorporated in several different layers depending on the configuration of the device. In one embodiment, the materials used in each layer are selected to result in the recombination of the holes and electrons in the light-emitting layer.

Light-emitting devices comprising the compounds disclosed herein can be fabricated using techniques known in the art, as informed by the guidance provided herein. For example, a glass substrate can be coated with a high work functioning metal such as ITO which can act as an anode. After patterning the anode layer, a light-emitting layer that includes at least a compound disclosed herein can be deposited on the anode. The cathode layer, comprising a low work functioning metal (e.g., Mg:Ag), can then be vapor evaporated onto the light-emitting layer. If desired, the device can also include an electron transport/injection layer, a hole blocking layer, a hole injection layer, an exciton blocking layer and/or a second light-emitting layer that can be added to the device using techniques known in the art, as informed by the guidance provided herein.

### EXAMPLES

Embodiments of optical elements described herein improve the ability of colorblind individuals to distinguish a first color from a second color having a different wavelength. These benefits are further shown by the following examples, which are intended to be illustrative of the embodiments of the disclosure, but are not intended to limit the scope or underlying principles in any way.

### Example 1

### Synthesis of Emissive Materials

### Synthesis of EM-1

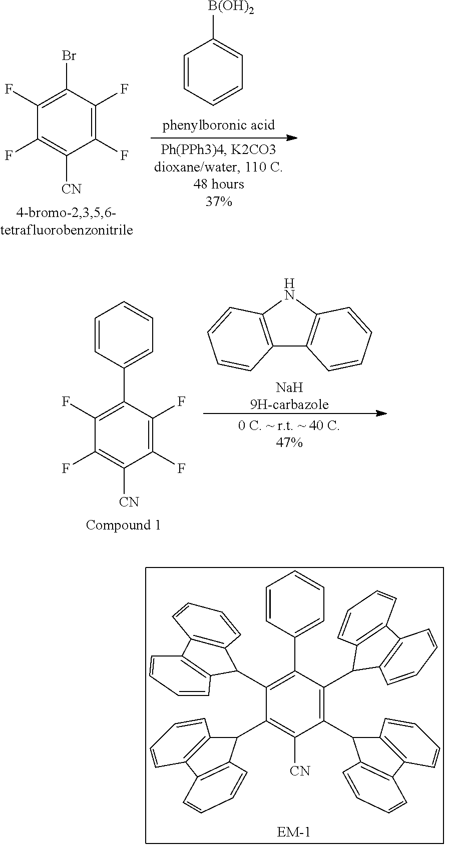

### 2,3,5,6-Tetrafluoro-4-phenyl-benzonitrile (Compound 1)

A mixture of 4-bromo-2,3,5,6-tetrafluorobenzonitrile (1.0 g, 3.94 mmol), phenylboronic acid (0.448 g, 4.0 mmol), Pd(PPh₃)₄ (0.231 g, 0.2 mmol) and potassium carbonate (1.38 g, 10 mmol) in dioxane/water (50 mL/10 mL) was degassed and heated at about 85° C. for about 16 hours. The resulting mixture was worked up with ethyl acetate/brine, the organic phase was collected and dried over Na₂SO₄, loaded on silica gel and purified by flash column using eluents of hexanes/dichloromethane (1:0 to 4:1). The desired fraction was collected and concentrated to give a white solid (Compound 1) (0.37 g, in 37% yield).

EM-1:

To a solution of 9H-carbazole (1.336 g, 8 mmol) and 2,3,5,6-tetrafluoro-4-phenyl-benzonitrile (Compound 1) (0.37 g, 1.47 mmol) in anhydrous tetrahydrofuran (THF) (35 mL) was added sodium hydride (NaH)(60% in mineral oil, 0.4 g, 10 mmol) at about 0 C. The mixture was stirred at about 0 C for about one hour then heated at about 60° C. for about 16 hours. The resulting mixture was poured into water (50 mL), filtration and the solid was washed with methanol and dried in vacuum oven for about 8 hours, then recrystallized in chloroform/hexanes to give a yellow solid (EM-1) (0.58 g, in 47% yield). Confirmed by LCMS (APCI): Calcd for C₆₁H₃₈N₅ (M+H): 840. Found: 840.

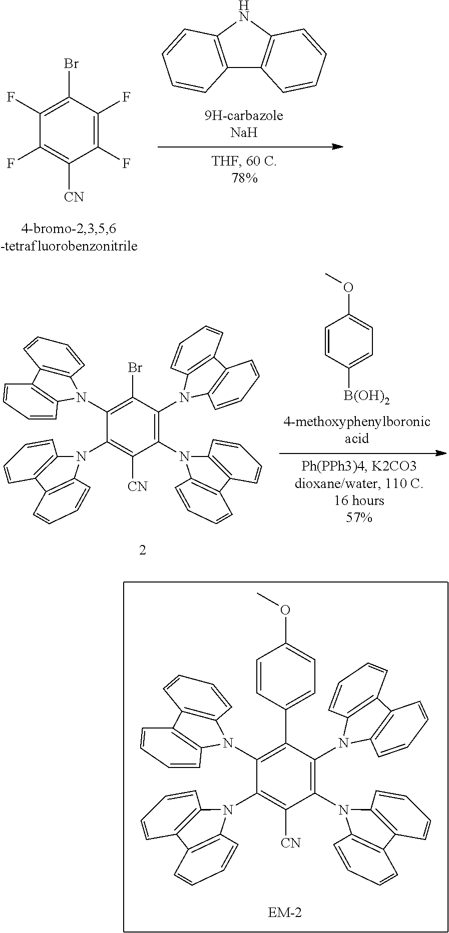 [SMILES: N#Cc1c(F)c(F)c(Br)c(F)c1F ; c1ccc2c(c1)[nH]c1ccccc12 ; N#Cc1c(-n2c3ccccc3c3ccccc32)c(-n2c3ccccc3c3ccccc32)c(Br)c(-n2c3ccccc3c3ccccc32)c1-n1c2ccccc2c2ccccc21 ; COc1ccc(B(O)O)cc1 ; COc1ccc(-c2c(-n3c4ccccc4c4ccccc43)c(-n3c4ccccc4c4ccccc43)c(C#N)c(-n3c4ccccc4c4ccccc43)c2-n2c3ccccc3c3ccccc32)cc1]

### 4-Bromo-2,3,5,6-tetra(9H-carbazol-9-yl)benzonitrile (Compound 2)

To a solution of 9H-carbazole (5.0 g, 30 mmol), 4-bromo-2,3,5,6-tetrafluorobenzonitrile (1.50 g, 6 mmol) in anhydrous THF (30 mL) was added sodium hydride (60% in mineral oil, 1.4 g, 35 mmol) at about 0° C. The mixture was stirred at about 0° C. for about 30 min, then heated at about 60° C. for about 16 hours. The resulting mixture was poured into water (100 mL). the suspension was filtered and washed with acetonitrile to give a yellow solid (Compound 2), which was sonicated in dichloromethane (50 ml). After filtration, a yellow solid was obtained (3.92 g, in 78% yield).

EM-2:

A mixture of 4-Bromo-2,3,5,6-tetra(9H-carbazol-9-yl)benzonitrile (Compound 2) (0.844 g, 1 mmol), 4-methoxyphenylboronic acid (0.30 g, 2 mmol), Pd(PPh₃)₄ (0.06 g, 0.5 mmol) and potassium carbonate (0.414 g, 3 mmol) in dioxane/water (40 mL/5 mL) was degassed and heated at about 110° C. for about 16 hours. The mixture was poured into ethyl acetate (100 mL), washed with brine, dried over Na₂SO₄, loaded on silica geland purified by flash column using eluents of dichloromethane/hexanes (10% to 50%). The desired fraction was collected, concentrated and recrystallized in dichloromethane/hexanes to give a yellow solid (EM-2) (0.50 g, in 57% yield). Confirmed by LCMS (APCI): Calcd for C₆₂H₄₀N₅O (M+H): 870. Found: 870.

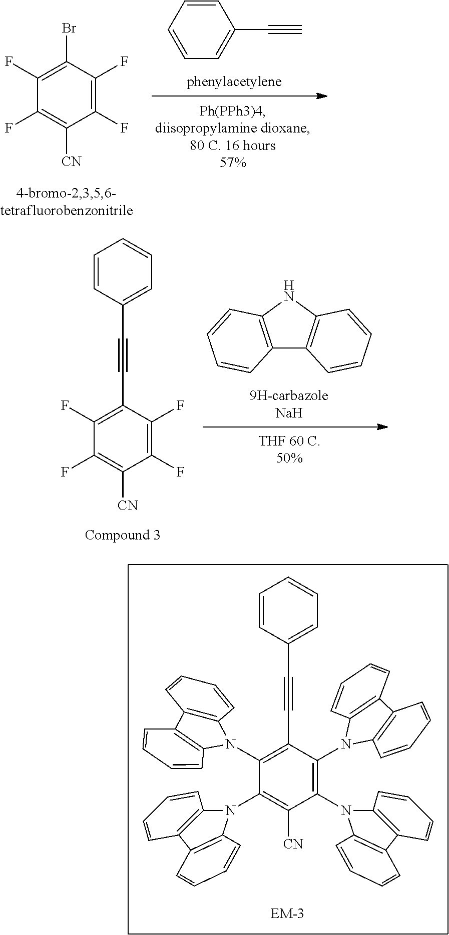

### 2,3,5,6-tetrafluoro-4-(phenylethynyl)benzonitrile (Compound 3)

A mixture of 4-bromo-2,3,5,6-tetrafluorobenzonitrile (1.0 g, 3.94 mmol), 2-phenylethynyl (0.80 g, 7.87 mmol), Pd(PPh₃)₄ (0.45 g, 0.39 mmol), CuI (0.152 g, 0.8 mmol) and diisopropylamine (1.0 g, 10 mmol) in dioxane (25 mL) was degassed and heated at about 80° C. for about 16 hours. The resulting mixture was poured into ethyl acetate (100 mL) and filtered off the precipitate. The solution was loaded on silica gel and purified by flash column using eluents of dichloromethane/hexanes (10% to 20%). The desired fraction was collected, concentrated and washed with methanol to give a white solid (Compound 3) (0.62 g, in 57% yield).

Compound EM-3:

To a mixture of 2,3,5,6-tetrafluoro-4-(phenylethynyl)benzonitrile (Compound 3) (0.50 g, 1.8 mmol), 9H-carbazole (1.336 g, 8 mmol) in anhydrous THF (25 mL) was added sodium hydride (60% in mineral oil, 0.40 g, 10 mmol) at about 0° C. and stirred for about 30 min. Then the mixture was heated at about 60° C. for about 18 hours. After being cooled to room temperature, the suspension was filtered and the solid was washed with water, methanol, dried in vacuum to give a yellow solid (EM-3) (0.8 g, 50% yield). Confirmed by LCMS (APCI): calcd for C₆₃H₃₈N₅ (M+H): 864. Found: 864.

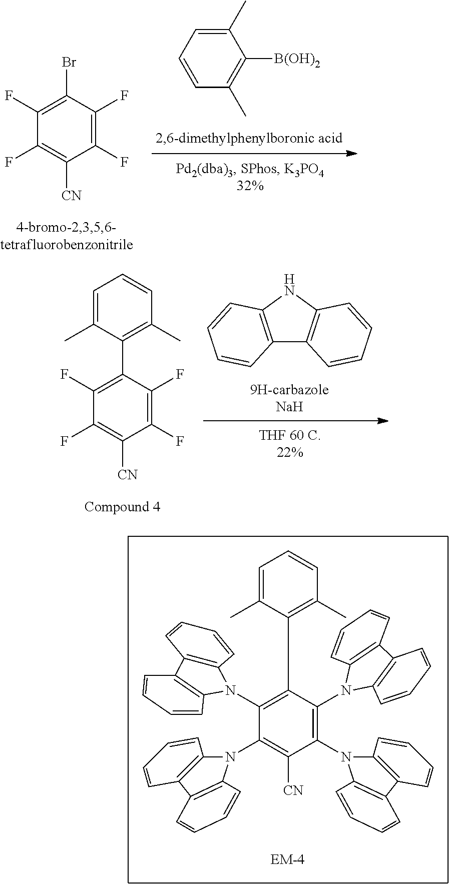

### 2,3,5,6-tetrafluro-4-(2′,6′-dimethylphenyl)benzonitrile (Compound 4)

A mixture of 4-bromo-2,3,5,6-tetrafluorobenzonitrile (1.0 g, 3.9 mmol), 2,6-dimethylphenylboronic acid (1.2 g, 8 mmol), Pd₂(dba)₃ (0.18 g, 0.2 mmol), SPhos (0.16 g, 0.4 mmol) and potassium phosphate (0.23 g, 10 mmol) in toluene (50 mL) was degassed and heated at about 120° C. for about 16 hours. After being cooled to room temperature, the mixture was filtered, washed with toluene. The filtrate solution was loaded on flash column and using eluents of hexanes/dichloromethane (1:0 to 4:1). The desired fraction was collected and concentrated slowly to give a colorless liquid (Compound 4) (0.35 g, in 32% yield).

Compound EM-4:

To a solution of 2,3,5,6-tetrafluro-4-(2′,6′-dimethylphenyl)benzonitrile (Compound 4) (0.36 g, 1.28 mmol), 9H-carbazole (0.86 g, 5.1 mmol) in THF (25 mL), was added sodium hydride (60% in mineral oil, 0.24 g, 6 mmol) at 0° C. and stirred for about 30 min. The resulting mixture was heated at about 60° C. for about 36 hours. Then worked up with dichloromethane/brine, the organic was dried over Na₂SO₄, loaded on silica gel and purified by flash column using eluents of hexanes/dichloromethane (100% to 70%). The desired fraction was collected and concentrated to give a white solid (EM-4) (0.25 g, in 22% yield). Confirmed by LCMS (APCI): calcd for C₆₃H₄₂N₅ (M+H): 868. Found: 868.

### Synthesis of EM-5

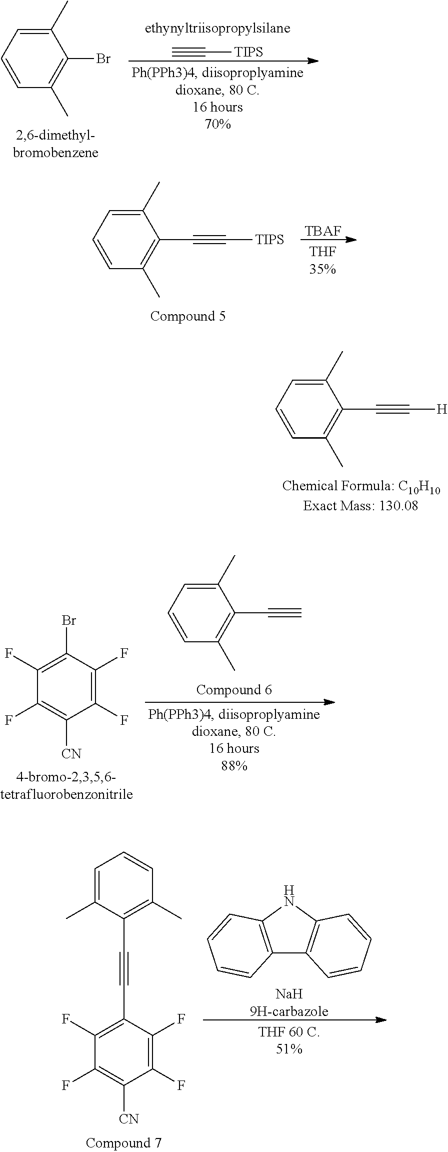

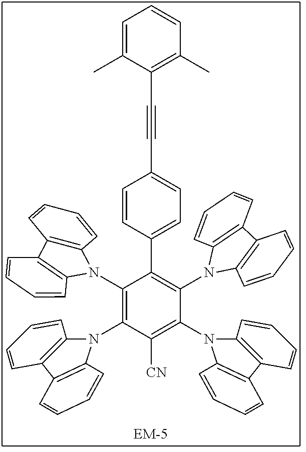 [SMILES: Cc1cccc(C)c1C#Cc1ccc(-c2c(-n3c4ccccc4c4ccccc43)c(-n3c4ccccc4c4ccccc43)c(C#N)c(-n3c4ccccc4c4ccccc43)c2-n2c3ccccc3c3ccccc32)cc1]

### ((2,6-dimethylphenyl)ethynyl)triisopropylsilane (Compound 5)

A mixture of 2,6-dimethyl-bromobenzene (1.85 g, 10 mmol), ethynyltriisopropylsilane (2.0 g, 11 mmol), PdCl₂(PPh₃)₂ (0.35 g, 0.5 mmol), CuI (0.19 g, 31 mmol) and diisopropylamine (3.0 g, 30 mmol) in dioxane (50 mL) was degassed and heated at 100° C. for 16 hours. The resulting mixture was worked up with ethyl acetate (100 mL), washed with brine, dried over Na₂SO₄, loaded on silica gel and purified by flash column using eluent of hexanes. After removal of solvent, a colorless liquid (Compound 5) was obtained (2.0 g, in 70% yield).

### 2-ethynyl-1,3-dimethylbenzene (Compound 6)

To a solution of ((2,6-dimethylphenyl)ethynyl)triisopropylsilane (Compound 5) (2.0 g, 7 mmol) in THF (25 mL) was added tetrabutylammonium fluoride (TBAF) solution (1.0M in THF, 7 mL, 7 mmol) at about 0° C. the solution was stirred for about 2 hours at about 0° C. then poured into ethyl acetate (100 mL), washed with NH₄Cl aqueous solution, dried over Na₂SO₄, loaded on silica gel and purified by flash column using eluent of hexanes. The desired fraction was collected and slowly removal of solvent to give a colorless volatile liquid (Compound 6) (0.4 g, in 35% yield).

### 2,3,5,6-tetrafluoro-4-(2′,6′-dimethylphenylethynyl)benzonitrile (Compound 7)

A mixture of 2-ethynyl-1,3-dimethylbenzene (Compound 6) (0.4 g, 3.0 mmol), 4-bromo-2,3,5,6-tetrafluorobenzonitrile (0.38 g, 1.5 mmol), Pd(PPh₃)₄ (0.173 g, 0.15 mmol), CuI (0.057 g, 0.3 mmol) and diisopropylamine (0.4 g, 4 mmol) in dioxane (40 mL) was degassed and heated at about 80° C. for about 16 hours. The resulting mixture was worked up with ethyl acetate. After filtered off precipitate, the solution was loaded on silica gel and purified by flash column using eluents of hexanes to hexanes/dichloromethane (4:1). Removal of solvent gave a white solid (Compound 7) (0.4 g, in 88% yield).

EM-5:

To a solution of 2,3,5,6-tetrafluoro-4-(2′,6′-dimethylphenylethynyl)benzonitrile (Compound 7) (0.4 g, 1.32 mmol) and), 9H-carbazole (1.1 g, 6.6 mmol) in anhydrous THF was added sodium hydride (60% in mineral oil, 0.32 g, 8 mmol) at about 0° C. and stirred for about 30 min. Then the mixture was heated at about 60° C. for about 16 hours. To the resulting mixture was added methanol (20 mL), and precipitate formed. After filtration and washing with water, methanol, and dried under vacuum at 80° C., a solid was obtained, which was dissolved in dichloromethane, then purified by flash column using eluents of hexane/dichloromethane (7:3) to give a solid (EM-5) (0.6 g, 51% yield). Confirmed by LCMS (APCI): Calcd for C₆₅H₄₂N₅ (M+H): 892. Found: 892.

### Synthesis of EM-6

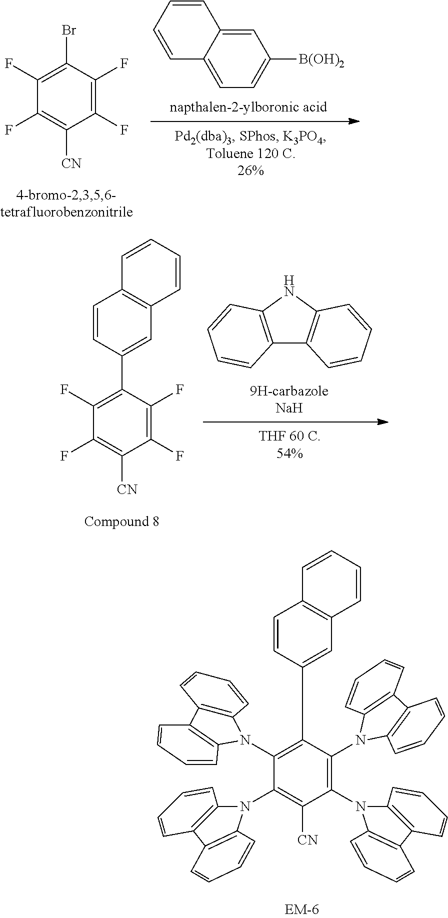

### 2,3,5,6-tetrafluoro-4-(naphthalen-2-yl)benzonitrile (Compound 8)

A mixture of naphthalen-2-ylboronic acid (1.38 g, 8 mmol), 4-bromo-2,3,5,6-tetrafluorobenzonitrile (1.0 g, 3.9 mmol), Pd₂(dba)₃ (0.18 g, 0.2 mmol), sodium 2′-dicyclohexylphosphino-2,6-dimethoxy-1,1′-biphenyl-3-sulfonate hydrate (SPhos) (0.16 g, 0.4 mmol) and K₃PO₄ (2.0 g, 8.7 mmol) in toluene (50 mL) was degassed and heated at about 120° C. for about 16 hours. After filtered off precipitate and washing with toluene, the filtrate was purified by flash column using eluents of hexanes to hexanes/dichloromethane (2:1). The desired fraction was collected to give a white solid (Compound 8) after removal of solvents (0.30 g, in 26% yield).

EM-6:

To a solution of 2,3,5,6-tetrafluoro-4-(naphthalen-2-yl)benzonitrile (Compound 8) (0.26 g, 0.86 mmol) and 9H-carbazole (0.668 g, 4 mmol) in THF was added sodium hydride (60% in mineral oil, 0.2 g, 5 mmol) at about 0° C. and stirred for about 20 min. Then the mixture was heated at about 60° C. for about 16 hours. The resulting mixture was worked up with dichloromethane/brine, dried over Na₂SO₄, loaded on silica gel and purified by flash column using eluents of dichloromethane/hexanes (10% to 40%). After concentration and recrystallization in dichloromethane/hexanes, a yellow solid (EM-6) was obtained (0.41 g, in 54% yield).

### Synthesis of EM-7

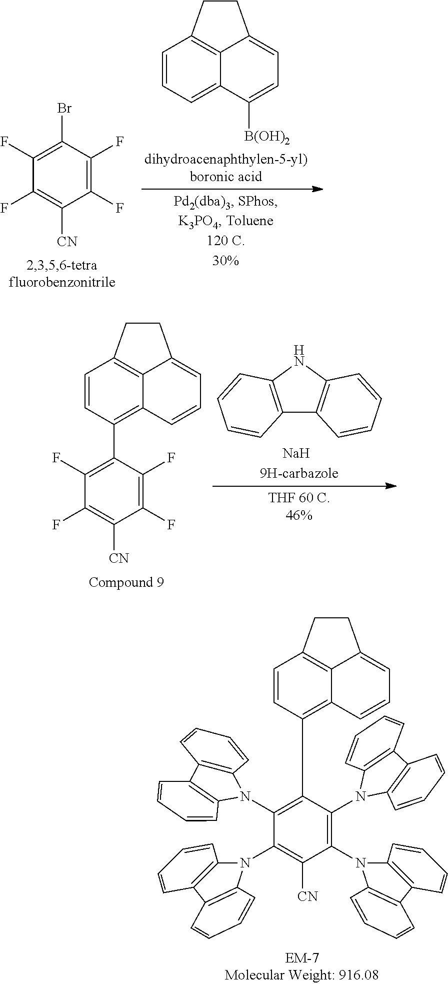

### 4-(1,2-dihydroacenaphthylen-5-yl)-2,3,5,6-tetrafluorobenzonitrile (Compound 9)

A mixture of (1,2-dihydroacenaphthylen-5-yl)boronic acid (1.6 g, 8 mmol), 4-bromo-2,3,5,6-tetrafluorobenzonitrile (1.0 g, 3.9 mmol), Pd₂(dba)₃ (0.18 g, 0.20 mmol), SPhos (0.16 g, 0.4 mmol), K₃PO₄ (2.0 g, 8.7 mmol) in toluene (50 mL) was degassed and heated at about 120° C. for about 16 hours. After filtered off precipitate and washed with toluene, the filtrate was purified by flash column using eluents of hexanes to hexanes/dichloromethane (7:3). Removal of solvent gave a white solid (Compound 9) (0.54 g, in 42% yield).

EM-7:

To a solution of 4-(1,2-dihydroacenaphthylen-5-yl)-2,3,5,6-tetrafluorobenzonitrile (Compound 9) (0.327 g, 1 mmol), 9H-carbazole (0.835 g, 5 mmol) in THF was added sodium hydride (60% in mineral oil, 0.2 g, 5 mmol) at about 0° C. and stirred for about 30 min. The mixture was heated at about 60° C. for about 34 hours, then worked up with dichoromethane/brine. The organic was dried over Na₂SO₄, then loaded on silica gel and purified by flash column using eluents of dichloromethane/hexanes (10% to 35%). The desired fraction was collected, and concentrated to give a yellow solid (EM-7) (0.42 g, in 46% yield). Confirmed by LCMS (APCI): calcd for C₆₇H₄₂N₅ (M+H): 916. Found: 916.

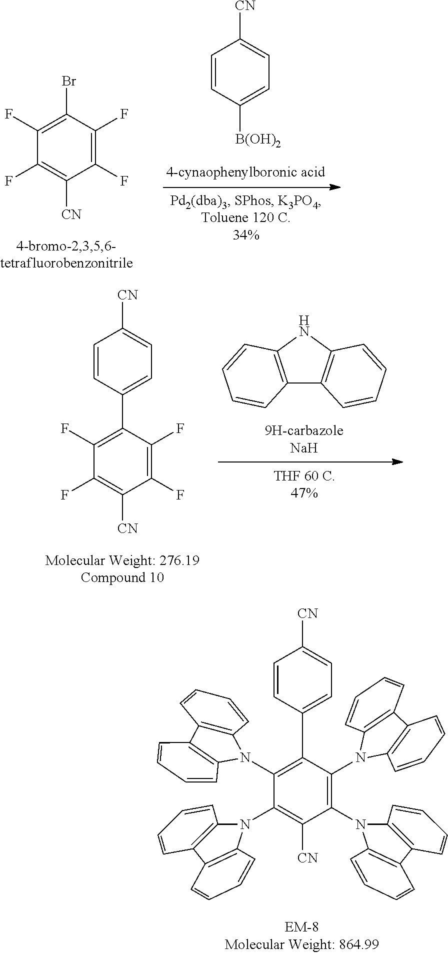 [SMILES: N#Cc1c(F)c(F)c(Br)c(F)c1F ; N#Cc1ccc(B(O)O)cc1 ; N#Cc1ccc(-c2c(F)c(F)c(C#N)c(F)c2F)cc1 ; c1ccc2c(c1)[nH]c1ccccc12 ; N#Cc1ccc(-c2c(-n3c4ccccc4c4ccccc43)c(-n3c4ccccc4c4ccccc43)c(C#N)c(-n3c4ccccc4c4ccccc43)c2-n2c3ccccc3c3ccccc32)cc1]

### 2,3,5,6-tetrafluro-4-(4′-cyanophenyl)-benzonitrile (Compound 10)

A mixture of 4-cyanophenylboronic acid (1.83 g, 8 mmol), 4-bromo-2,3,5,6-tetrafluorobenzonitrile (1.0 g, 3.9 mmol), Pd₂(dba)₃ (0.18 g, 0.2 mmol), SPhos (0.16 g, 0.4 mmol) and K₃PO₄ (2.0 g, 8.7 mmol) in toluene (40 mL) was degassed and heated at about 120° C. for about 16 hours. After cooled to room temperature, the mixture was filtered and washed with toluene. The filtrate was loaded on silica gel and purified by flash column using eluents of dichloromethane/hexanes (10% to 40%). The desired fraction was collected and concentrated to give a white solid (Compound 10) (0.367 g, in 34% yield).

EM-8:

To a solution of 2,3,5,6-tetrafluro-4-(4′-cyanophenyl)-benzonitrile (Compound 10) (0.277 g, 1 mmol), 9H-carbazole (0.835 g, 5 mmol) in THF (25 mL) was added sodium hydride (60% in mineral oil, 0.2 g, 5 mmol) at about 0° C. and stirred for about 30 min. The mixture was heated at about 60° C. for about 16 hours, then worked up with dichloromethane/brine, dried over Na₂SO₄, loaded on silica gel and purified by flash column using eluents of dichloromethane/hexanes (10% to 60%). The desired fraction was collected and concentrated to give a light yellow solid (EM-8) (0.41 g, in 47% yield). Confirmed by LCMS (APCI): Calcd for C₆₂H₃₇N₆ (M+H): 865. Found: 865.

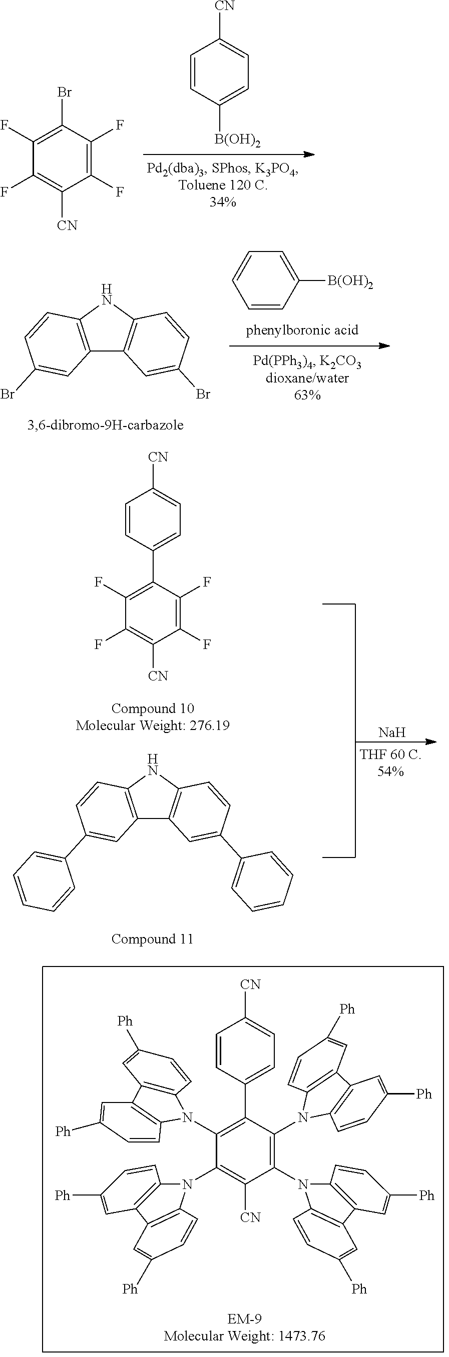

### 3,6-diphenyl-9H-carbazole (Compound 11)

A mixture of 3,6-dibromo-9H-carbazole (3.0 g, 9.2 mmol), phenylboronic acid (3.0 g, 25 mmol), Pd(PPh₃)₄ (0.3 g, 0.26 mmol) and potassium carbonate (6.5 g, 47 mmol) in dioxane/water (75 mL/15 mL) was degassed and heated at about 100° C. for about 16 hours. Upon cooling to room temperature, the whole was worked up with ethyl acetate/brine, the organic was dried over Na₂SO₄, loaded on silica gel and purified by flash column using eluents of ethyl acetate/hexanes (10% to 30%). After removal of solvents, a white solid (Compound 11) was obtained (2.1 g, in 63% yield).

Compound EM-9:

To a solution of 3,6-diphenyl-9H-carbazole (Compound 11) (1.51 g, 4.5 mmol) and 2,3,5,6-tetrafluro-4-(4′-cyanophenyl)-benzonitrile (Compound 10) (0.277 g, 1 mmol) in anhydrous THF (25 mL) was added sodium hydride (60% in mineral oil, 0.2 g, 5 mmol) at about 0° C. and stirred for about 30 min. The mixture was heated at about 60° C. for about 24 hours. Upon cooling to room temperature, the whole was worked up with dichloromethane/brine, dried over Na₂SO₄, then purified by flash column using eluents of dicholoromethane/hexanes (20% to 60%). The yellow desired fractions were collected and concentrated to give a bright yellow solid (EM-9) (0.80 g, in 54% yield). Confirmed by ¹H NMR (CD₂Cl₂, 400 MHz): 7.97 (s, 4H), 7.84 (d, J=1.4 Hz, 4H), 7.54 (d, Hz, J=7.36 Hz, 8H), 7.48 (d, J=7.36 Hz, 8H), 7.41-7.28 (m, 32H), 7.24 (d, J=8.4 Hz, 2H), 7.14 (d, J=8.4 Hz, 4H), 7.02 (d, J=8.4 Hz, 2H).

### Synthesis of EM-10

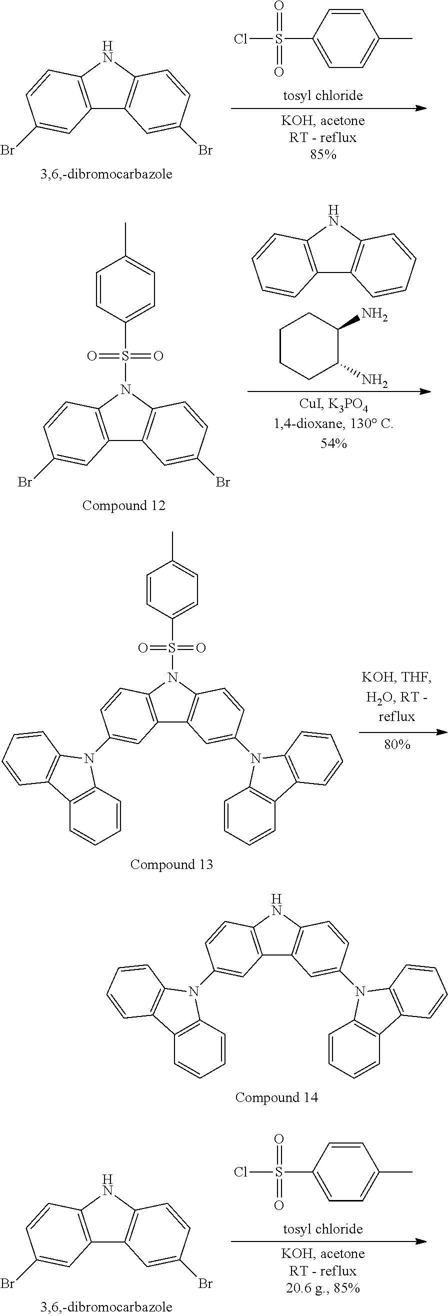

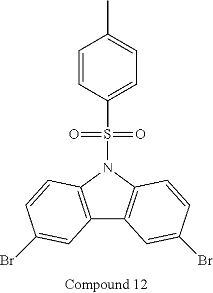 [SMILES: Cc1ccc(S(=O)(=O)n2c3ccc(Br)cc3c3cc(Br)ccc32)cc1]

### 3,6-dibromo-N-tosylcarbazole (Compound 12)

To a solution of 3,6-dibromocarbazole (16.25 g, 50.00 mmol), and potassium hydroxide (3.93 g, 70.00 mmol) in anhydrous acetone (100.00 mL), tosyl chloride (13.35 g, 70.00 mmol) was added in 4 g portions at room temperature. The reaction was then heated at reflux for about 3 hours. The resulting mixture was then poured into stirring water (300.00 mL) while still hot. The precipitate was filtered, washed with methanol, and dried. It was then recrystallized from dichloromethane/methanol to give 12 as a white solid, 20.6 g, 82% yield. Confirmed by ¹HNMR.

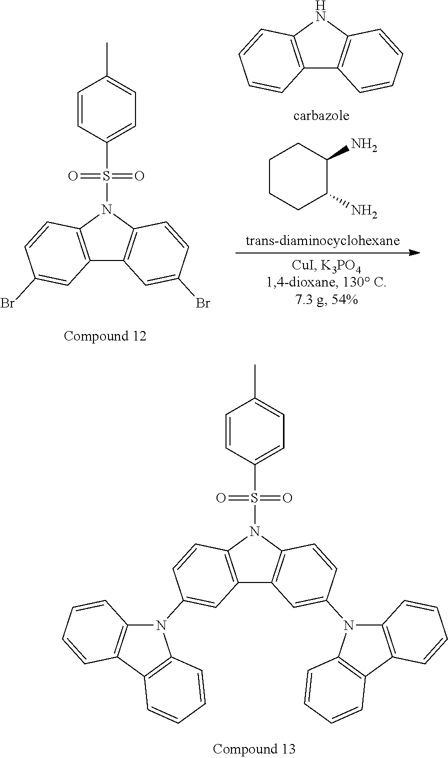 [SMILES: Cc1ccc(S(=O)(=O)n2c3ccc(Br)cc3c3cc(Br)ccc32)cc1 ; c1ccc2c(c1)[nH]c1ccccc12 ; N[C@@H]1CCCC[C@H]1N ; Cc1ccc(S(=O)(=O)n2c3ccc(-n4c5ccccc5c5ccccc54)cc3c3cc(-n4c5ccccc5c5ccccc54)ccc32)cc1]

### 3,6-bis(N-carbazolyl)-N-tosylcarbazole (13)

A mixture of 12 (10.00 g, 20.87 mmol), carbazole (13.37 g, 79.93 mmol), copper iodide (1.59 g, 8.33 mmol), trans-diaminocyclohexane (1.0 mL, 8.34 mmol), and potassium phosphate (19.21 g, 90.51 mmol) in anhydrous dioxane (165.00 mL) was degassed with bubbling argon for 2 hours at room temperature. The mixture was then heated at about 120° C. for about 16 hours. An aqueous workup was performed with ethyl acetate and brine, dried with magnesium sulfate. A silica gel plug was run to remove the copper catalyst, using dichloromethane as the eluent. The semi-crude product was then purified by silica gel column using dichloromethane/hexanes eluent in a linear gradient of 25% to 70%, holding at 70% until the product fully eluted. The product fractions were then recrystallized twice from dichloromethane in methanol to yield 13 as a white solid, 7.3 g, 54% yield. Confirmed by LCMS (APCI): calcd for C₄₃H₃₀N₃O₂S (M+H): 652. Found: 652.

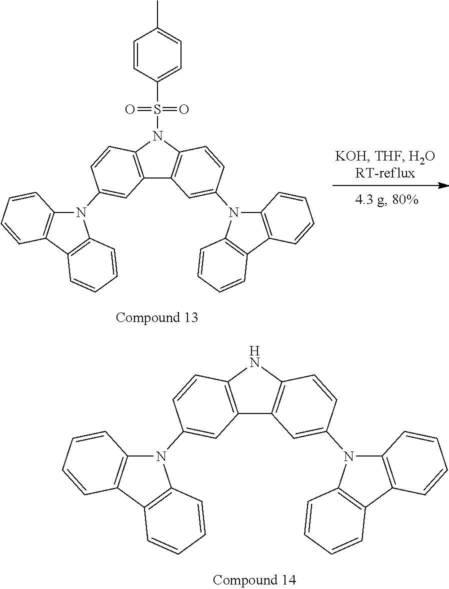 [SMILES: Cc1ccc(S(=O)(=O)n2c3ccc(-n4c5ccccc5c5ccccc54)cc3c3cc(-n4c5ccccc5c5ccccc54)ccc32)cc1 ; c1ccc2c(c1)c1ccccc1n2-c1ccc2[nH]c3ccc(-n4c5ccccc5c5ccccc54)cc3c2c1]

### 3,6-bis(N-carbazolyl)carbazole (14)

To a solution of 13 in tetrahydrofuran/methanol (90.00 mL/35.00 mL), sodium hydroxide (6.08 g, 151.93 mmol) dissolved in water (35.00 mL) was added, and the resulting mixture was heated at about 80° C. for about 18 hours. An aqueous workup was performed with ethyl acetate and brine, and was dried with magnesium sulfate. The material was purified by recrystallization by dissolving in dichloromethane and adding an equal volume of methanol before concentrating. The resulting solid was collected to yield 14 as a white solid, 4.3 g, 80% yield. Confirmed by LCMS (APCI): calcd for C₃₆H₂₄N₃ (M+H): 498. Found: 498.

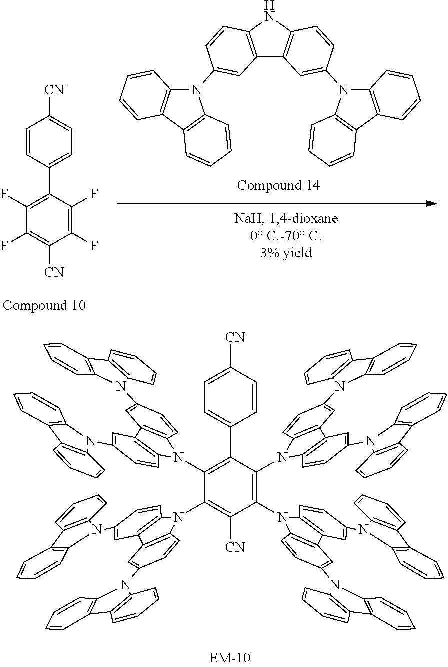 [SMILES: N#Cc1ccc(-c2c(F)c(F)c(C#N)c(F)c2F)cc1 ; c1ccc2c(c1)c1ccccc1n2-c1ccc2[nH]c3ccc(-n4c5ccccc5c5ccccc54)cc3c2c1 ; N#Cc1ccc(-c2c(-n3c4ccc(-n5c6ccccc6c6ccccc65)cc4c4cc(-n5c6ccccc6c6ccccc65)ccc43)c(-n3c4ccc(-n5c6ccccc6c6ccccc65)cc4c4cc(-n5c6ccccc6c6ccccc65)ccc43)c(C#N)c(-n3c4ccc(-n5c6ccccc6c6ccccc65)cc4c4cc(-n5c6ccccc6c6ccccc65)ccc43)c2-n2c3ccc(-n4c5ccccc5c5ccccc54)cc3c3cc(-n4c5ccccc5c5ccccc54)ccc32)cc1]

EM-10:

To a solution of 3,6-bis(carbazolyl)carbazole (Compound 14) (1.35 g, 2.72 mmol) and 2,3,5,6-tetrafluoro-[1,1′-biphenyl]-4,4′-dicarbonitrile (Compound 10) (0.15 g, 0.54 mmol) in anhydrous 1,4-dioxane (60 mL) was added sodium hydride (NaH) (60% in mineral oil, 0.120 g, 2.99 mmol) at about 0° C. The mixture was stirred at about 0° C. for about one hour (until H₂(g) fully evolved) then heated at about 70° C. for about 96 hours. The resulting mixture was worked up with ethyl acetate/brine and dried over magnesium sulfate. The crude material was purified by column chromatography on a silica gel column using eluents of 15% to 25% ethyl acetate in hexanes/100% ethyl acetate, then 15% to 100% ethyl acetate in hexanes. The product was dried by rotary evaporation and recrystallized from dichloromethane/hexanes to yield EM-10 (0.025 g, 3% yield) as an orange solid. Confirmed by ¹HNMR.

### Synthesis of EM-11

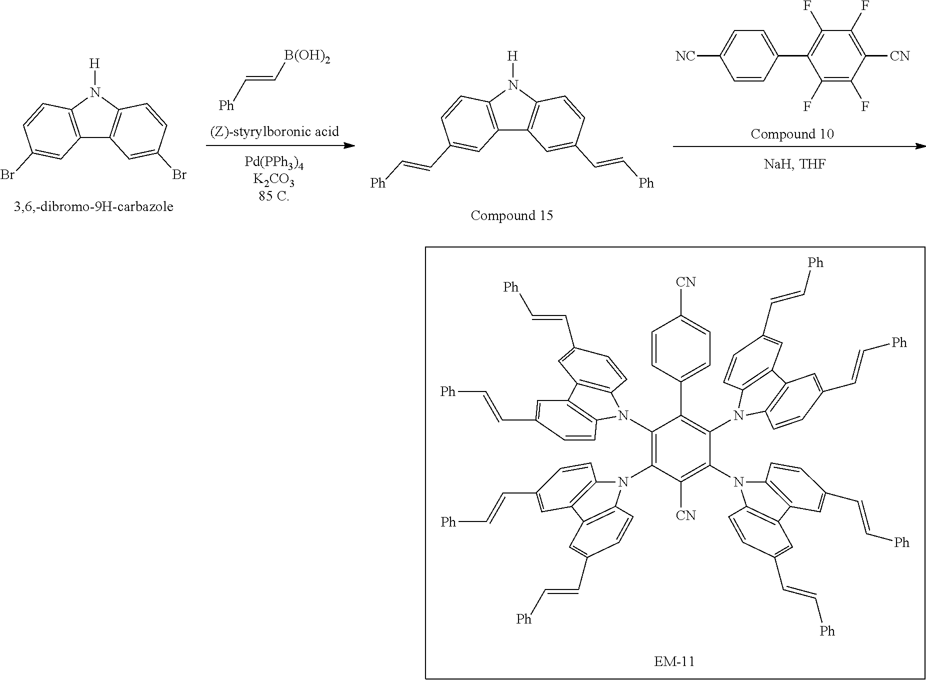 [SMILES: Brc1ccc2[nH]c3ccc(Br)cc3c2c1 ; OB(O)/C=C/c1ccccc1 ; C(=C\c1ccc2[nH]c3ccc(/C=C/c4ccccc4)cc3c2c1)/c1ccccc1 ; N#Cc1ccc(-c2c(F)c(F)c(C#N)c(F)c2F)cc1 ; N#Cc1ccc(-c2c(-n3c4ccc(/C=C/c5ccccc5)cc4c4cc(/C=C/c5ccccc5)ccc43)c(-n3c4ccc(/C=C/c5ccccc5)cc4c4cc(/C=C/c5ccccc5)ccc43)c(C#N)c(-n3c4ccc(/C=C/c5ccccc5)cc4c4cc(/C=C/c5ccccc5)ccc43)c2-n2c3ccc(/C=C/c4ccccc4)cc3c3cc(/C=C/c4ccccc4)ccc32)cc1]

### 3,6-di((E)-styryl)-9H-carbazole (Compound 15)

A mixture of 3,6,-dibromo-9H-carbazole (4.0 g, 12.3 mmol), (Z)-styrylboronic acid (5.0 g, 34 mmol), Pd(PPh3)₄ (0.693 g, 0.6 mmol), K₂CO₃ (5.52 g, 40 mmol) in dioxane/water (80 mL/10 mL) was degassed and heated at about 100° C. for about 18 hours. The resulting mixture was worked up with ethyl acetate/brine. The solid was collected by filtration, then washed with dichloromethane to give a light yellow solid (Compound 15) (2.5 g, in 55% yield).

EM-11:

To a mixture of 3,6-di((E)-styryl)-9H-carbazole (Compound 15) (0.5 g, 1.35 mmol), 4-(4′-cyanophenyl)-2,3,5,6-tetrafluorobenzonitrile (Compound 10) (0.083 g, 0.3 mmol) in anhydrous THF (10 mL) was added sodium hydride (60% in mineral oil, 0.080 g, 2 mmol), then heated at about 60° C. for about 24 hours. The resulting mixture was diluted with dichloromethane, then washed with brine, dried over Na₂SO₄, loaded on silica gel then purified by flash column using eluents of dichloromethane/hexanes (20% to 50%). The desired fractions (yellow-orange) were collected, concentrated, repricipitated by dichloromethane/hexanes to give a orange solid (EM-11) (0.23 g, in 46% yield). Confirmed by LCMS (APCI⁺): calcd for C₁₂₆H₈₅N₆ (M⁺H): 1682.

Found: 1682.

### Synthesis EM-12

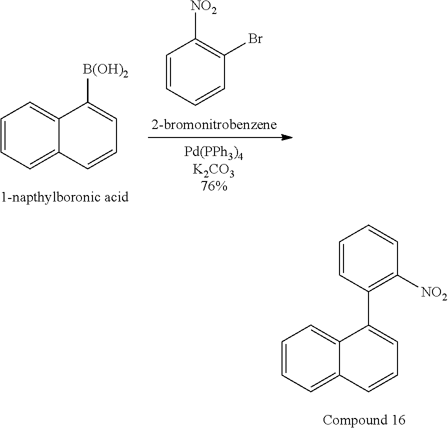 [SMILES: OB(O)c1cccc2ccccc12 ; O=[N+]([O-])c1ccccc1Br ; O=[N+]([O-])c1ccccc1-c1cccc2ccccc12]

### 1-(2-nitrophenyl)naphthalene (Compound 16)

A mixture of 2-bromonitrobenzene (10.00 g, 49.5 mmol, 1.00 eq), 1-napthylboronic acid (16.18 g, 94.0 mmol, 1.90 eq), tetrakis(triphenylphosphine)palladium (4.0 g, 3.47 mmol, 0.07 eq), and 1,4-dioxane (400.0 mL) were degassed with bubbling argon for about 1.5 hours at room temperature. Aqueous potassium carbonate (27.37 g, 198.0 mmol, 4.0 eq K₂CO₃ in 80.0 mL of water) was then added and the reaction was degassed for an additional 30 minutes. The reaction mixture was then heated to about 90° C. overnight, maintaining an argon atmosphere. Once complete and cooled to room temperature, an aqueous workup was performed using ethyl acetate, water, and brine, and the organic phase was dried by magnesium sulfate. The crude material was then purified by flash chromatography using the following eluent gradient (% dichloromethane in hexanes over column volumes (CV)): linear from 10% to 15% over 7 CV, linear from 15% to 20% over 2 CV, isocratic at 20% until the product was fully eluted. The product fractions were concentrated to yield desired compound (12.0 g, in 76% yield) as a light yellow solid (Compound 16). Confirmed by LCMS and ¹HNMR.

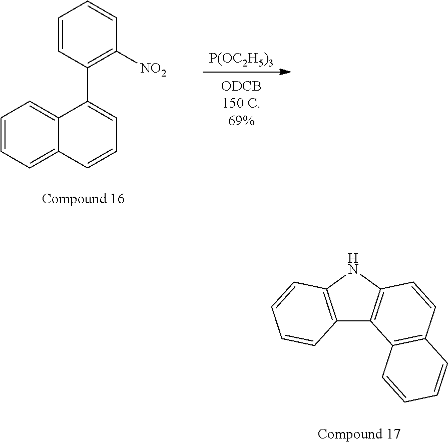

### 7H-benzo[c]carbazole (Compound 17)

To a solution of 1-(2-nitrophenyl)naphthalene (Compound 16) (4.5 g, 18 mmol) in 1,2-dichlorobenzene (20 mL) was added triethylphosphite (20 mL, 144 mmmol). The solution was heated at about 150° C. for about 15 hours. After removal of solvent and excess reagent by vacuum distillation, the remaining was dissolved in dichloromethane/hexanes (20 mL/20 mL) and purified by flash column using eluents of hexanes to hexanes/dichloromethane (4:1). The desired fractions were collected, concentrated, loaded on silica gel and purified by flash column again using eluents of dichloromethane/hexanes (10% to 20%). Removal of solvents gives a white solid (2.70 g, in 69% yield).

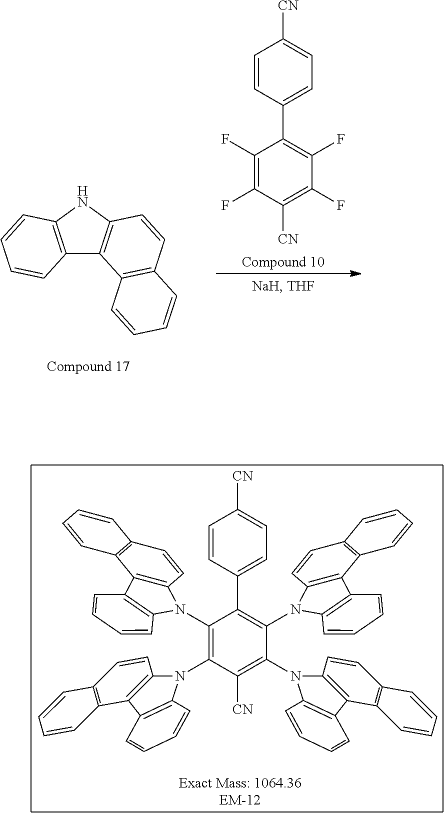 [SMILES: c1ccc2c(c1)ccc1[nH]c3ccccc3c12 ; N#Cc1ccc(-c2c(F)c(F)c(C#N)c(F)c2F)cc1 ; N#Cc1ccc(-c2c(-n3c4ccccc4c4c5ccccc5ccc43)c(-n3c4ccccc4c4c5ccccc5ccc43)c(C#N)c(-n3c4ccccc4c4c5ccccc5ccc43)c2-n2c3ccccc3c3c4ccccc4ccc32)cc1]

Compound EM-12:

To a solution of benzocarbazole (Compound 17) (1.085 g, 5 mmol), 4-(4′-cyanophenyl)-2,3,5,6-tetrafluorobenzonitrile (Compound 10) (0.277 g, 1.0 mmol) in anhydrous THF (15 mL), was added sodium hydride (60% in mineral oil, 0.32 g, 8 mmol) at about 0° C. The mixture was stirred for about one hour, then heated at about 55° C. for about 15 hours. The resulting mixture was worked up with dichloromethane/brine, dried over Na₂SO₄, purified by flash column using eluents of dichloromethane/hexanes (20% to 70%). The desired fractions were collected, concentrated and recrystallized in dichloromethane/methanol to give a yellow solid (EM-12) (0.3 g, in 28% yield. Confirmed by LCMS (APCI⁺): Calcd for C₇₈H₄₅N₆ (M+H): 1065. Found: 1065.

### Synthesis of EM-13

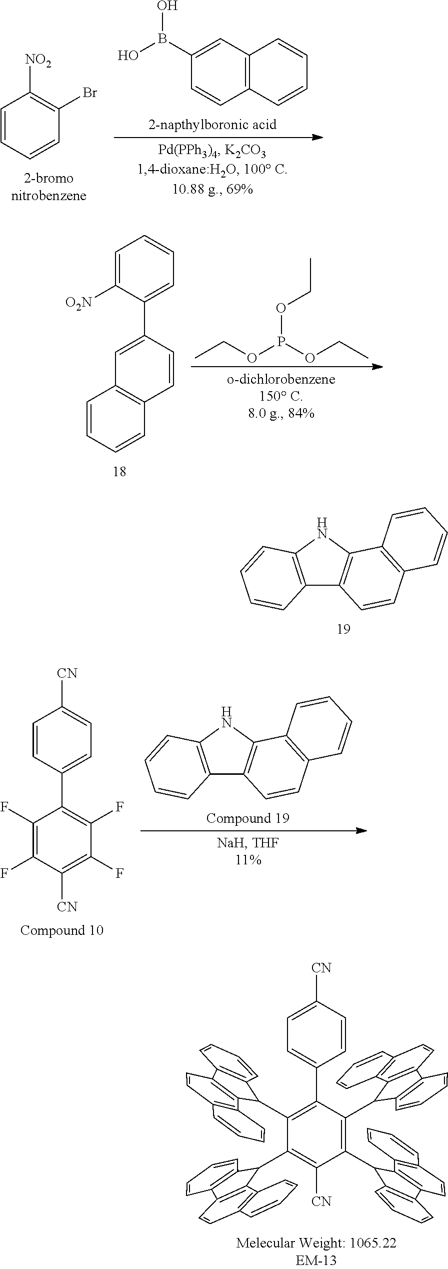

### 2-(2-nitrophenyl)naphthalene (Compound 18)

A mixture of 2-bromonitrobenzene (10.00 g, 49.5 mmol, 1.00 eq), 2-napthylboronic acid (14.05 g, 81.68 mmol, 1.65 eq), tetrakis(triphenylphosphine)palladium (Pd(PPh₃)₄) (4.0 g, 3.47 mmol, 0.07 eq), and 1,4-dioxane (400.0 mL) were degassed with bubbling argon for about 1 hour at room temperature. Aqueous potassium carbonate (K₂CO₃) (27.37 g, 198.0 mmol, 4.0 eq K₂CO₃ in 80.0 mL of water) was then added and the reaction mixture was then heated to about 100° C. overnight, maintaining an argon atmosphere. An aqueous workup was performed using ethyl acetate, water, and brine, and the organic phase was dried by magnesium sulfate. The crude material was then purified twice by flash chromatography on a silica gel column using eluents of 10% to 50% dichloromethane in hexanes, and then 15% to 30% dichloromethane in hexanes. The product fractions were concentrated to yield Compound 3 (10.88 g, 69%) as a white solid (Compound 18). Confirmed by LCMS and ¹HNMR.

### 11H-benzo[a]carbazole (Compound 19)

To a solution of 2-(2-nitrophenyl)naphthalene (Compound 18) (10.88 g, 43.65 mmol) in 1,2-dichlorobenzene (60 mL) was added triethylphosphite (60 mL, 384.57 mmol). The solution was heated at about 150° C. for about 15 hours. After removal of solvent and excess reagent by vacuum distillation, the crude material was purified by column chromatography on a silica gel column using eluents of 15% to 35% dichloromethane in hexanes. The product fractions were dried by rotary evaporation and recrystallized from dichloromethane/hexanes to yield Compound 4 (2.70 g, in 69% yield) as a white solid (Compound 19). Confirmed by ¹HNMR.

EM-13:

To a solution of 11H-benzo[a]carbazole (Compound 19) (1.24 g, 5.70 mmol) and 2,3,5,6-tetrafluoro-[1,1′-biphenyl]-4,4′-dicarbonitrile (Compound 10) (0.35 g, 1.27 mmol) in anhydrous tetrahydrofuran (THF) (45 mL) was added sodium hydride (NaH) (60% in mineral oil, 0.253 g, 6.34 mmol) at about 0° C. The mixture was stirred at about 0° C. for about one hour (until H2(g) fully evolved) then heated at about 85° C. for about 96 hours. The resulting mixture was worked up with ethyl acetate/brine and dried over magnesium sulfate. The crude material was purified thrice by column chromatography on a silica gel column using eluents of 15% to 25% ethyl acetate in hexanes/100% ethyl acetate, then 40% to 50% dichloromethane in hexanes, and finally 20% to 40% ethyl acetate in hexanes/100% ethyl acetate. The product was dried by rotary evaporation and recrystallized from dichloromethane/hexanes to yield AB-14 (0.15 g, 11% yield) as a yellow solid. Confirmed by ¹HNMR.

### Synthesis of EM-14

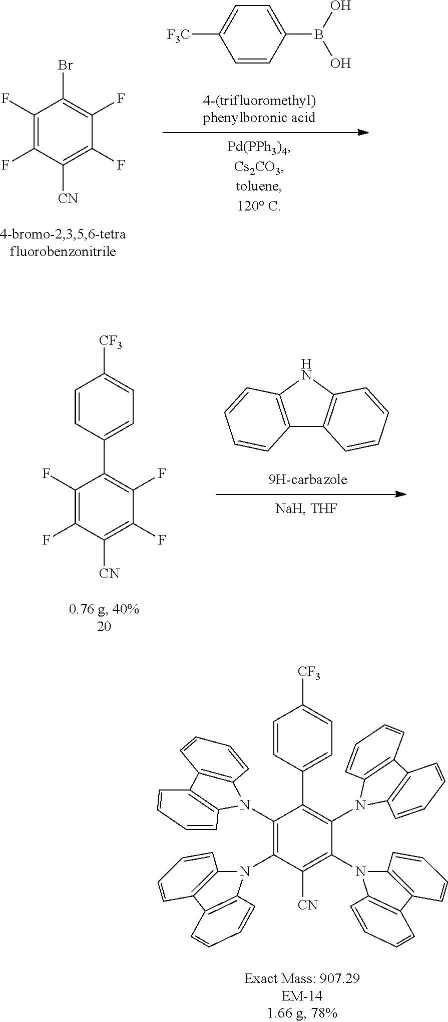 [SMILES: OB(O)c1ccc(C(F)(F)F)cc1 ; N#Cc1c(F)c(F)c(Br)c(F)c1F ; N#Cc1c(F)c(F)c(-c2ccc(C(F)(F)F)cc2)c(F)c1F ; c1ccc2c(c1)[nH]c1ccccc12 ; N#Cc1c(-n2c3ccccc3c3ccccc32)c(-n2c3ccccc3c3ccccc32)c(-c2ccc(C(F)(F)F)cc2)c(-n2c3ccccc3c3ccccc32)c1-n1c2ccccc2c2ccccc21]

### 2,3,5,6-tetrafluoro-4′-(trifluoromethyl)-[1,1-biphenyl]-4-carbonitrile (Compound 20)

A mixture of 4-bromo-2,3,5,6-tetrafluorobenzonitrile (1.5 g, 5.91 mmol), 4-(trifluoromethyl)phenylboronic acid (2.24 g, 11.81 mmol), Pd(PPh₃)₄ (0.340 g, 0.3 mmol) in toluene (70 mL) was degassed for about 1.5 hours with bubbling argon. Cesium carbonate (5.77 g, 17.72 mmol) was added and the mixture was heated to about 35° C., degassed for an additional 30 minutes, then heated to about 110° C. for about 16 hours, then at about 120° C. for about 3 hours. The resulting mixture was worked up with ethyl acetate/brine, the organic phase was collected and dried over MgSO₄. The crude mixture was purified twice by column chromatography on a silica gel column using eluents of 0% to 10% tetrahydrofuran (THF) in hexanes, and then 2.5% to 3.5% ethyl acetate in hexanes. The product was dried by rotary evaporation to yield (Compound 20) (0.76 g, 40% yield) as a clear liquid.

EM-14:

To a solution of 9H-carbazole (1.77 g, 10.57 mmol) and Compound 20 (0.75 g, 2.35 mmol) in anhydrous tetrahydrofuran (THF) (25 mL) was added sodium hydride (NaH) (60% in mineral oil, 0.470 g, 11.75 mmol) at about 0° C. The mixture was stirred at about 0° C. for about one hour (until H₂(g) fully evolved) then heated at about 60° C. for about 16 hours. The resulting mixture was worked up with ethyl acetate/brine and dried over magnesium sulfate. The crude material was purified by column chromatography on a silica gel column with an eluent of 50% to 75% toluene in hexanes. The product was dried by rotary evaporation and recrystallized from dichloromethane/hexanes to yield EM-14 (1.66 g, 78% yield) as a yellow solid. Confirmed by ¹HNMR.

### Synthesis of EM-15

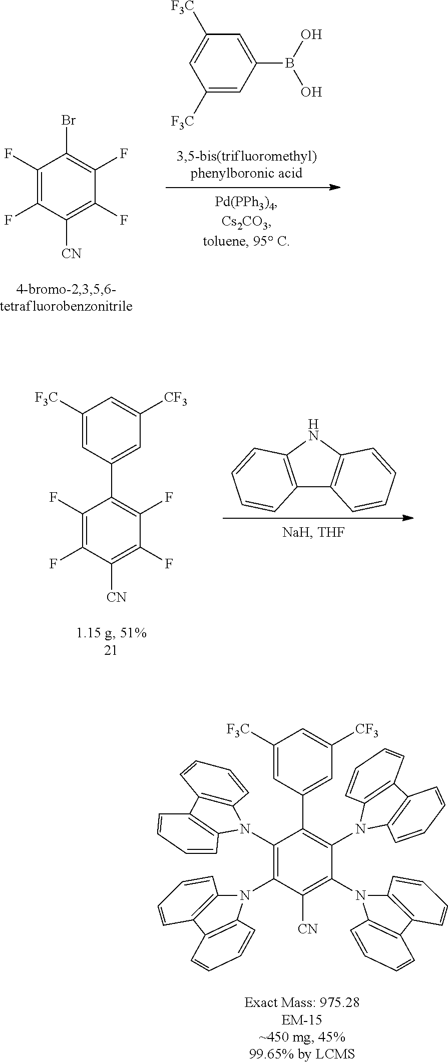 [SMILES: N#Cc1c(F)c(F)c(Br)c(F)c1F ; OB(O)c1cc(C(F)(F)F)cc(C(F)(F)F)c1 ; N#Cc1c(F)c(F)c(-c2cc(C(F)(F)F)cc(C(F)(F)F)c2)c(F)c1F ; c1ccc2c(c1)[nH]c1ccccc12 ; N#Cc1c(-n2c3ccccc3c3ccccc32)c(-n2c3ccccc3c3ccccc32)c(-c2cc(C(F)(F)F)cc(C(F)(F)F)c2)c(-n2c3ccccc3c3ccccc32)c1-n1c2ccccc2c2ccccc21]

### Synthesis of EM-15

### 2,3,5,6-tetrafluoro-3′,5′-bis(trifluoromethyl)-[1,1-biphenyl]-4-carbonitrile (Compound 21)

A mixture of 4-bromo-2,3,5,6-tetrafluorobenzonitrile (1.5 g, 5.91 mmol), 3,5-bis(trifluoromethyl)phenylboronic acid (1.90 g, 7.38 mmol), Pd(PPh₃)₄ (0.341 g, 0.3 mmol) in toluene (70 mL) was degassed for about 1.5 hours with bubbling argon. Vacuum-oven-dried cesium carbonate (3.61 g, 11.07 mmol) was added and the mixture was degassed for an additional 30 minutes and then heated to about 110° C. for about 64 hours. The resulting mixture was worked up with dichloromethane/brine, and the organic phase was collected and dried over MgSO₄. The crude mixture was purified twice by column chromatography on a silica gel column using eluents of 0% to 3.5% ethyl acetate in hexanes, and then 5% to 30% dichloromethane in hexanes. The clean product fractions were dried by rotary evaporation to yield Compound 21 (1.15 g, 51% yield) as a clear crystalline solid.

EM-15:

To a solution of 9H-carbazole (0.778 g, 4.65 mmol) and 2,3,5,6-tetrafluoro-3′,5′-bis(trifluoromethyl)-[1,1′-biphenyl]-4-carbonitrile (Compound 21) (0.40 g, 1.03 mmol) in anhydrous tetrahydrofuran (THF) (40 mL) was added sodium hydride (NaH) (60% in mineral oil, 0.207 g, 5.17 mmol) at about 0° C. The mixture was stirred at about 0° C. for about one hour (until H₂(g) fully evolved) then heated at about 60° C. for about 16 hours. The resulting mixture was worked up with dichloromethane/brine and dried over magnesium sulfate. The crude material was purified twice by column chromatography on a silica gel column using eluents of 40% to 80% toluene in hexanes and then 25% to 35% dichloromethane in hexanes. The product was dried by rotary evaporation and recrystallized from dichloromethane/hexanes to yield EM-15 (0.45 g, 45% yield) as a yellow solid. Confirmed by ¹HNMR.

### Synthesis of EM-16

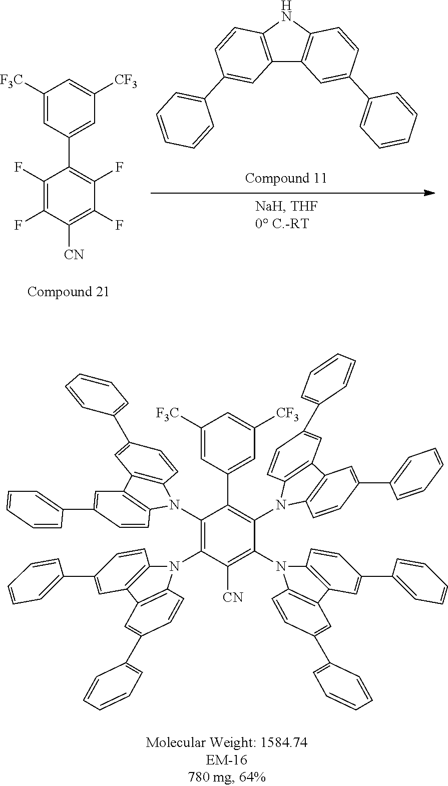 [SMILES: N#Cc1c(F)c(F)c(-c2cc(C(F)(F)F)cc(C(F)(F)F)c2)c(F)c1F ; c1ccc(-c2ccc3[nH]c4ccc(-c5ccccc5)cc4c3c2)cc1 ; N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(-c2cc(C(F)(F)F)cc(C(F)(F)F)c2)c(-n2c3ccc(-c4ccccc4)cc3c3cc(-c4ccccc4)ccc32)c1-n1c2ccc(-c3ccccc3)cc2c2cc(-c3ccccc3)ccc21]

EM-16:

To a solution of 3,6-diphenyl-9H-carbazole (Compound 11) (1.18 g, 3.68 mmol) and Compound 21 (0.30 g, 0.77 mmol) in anhydrous tetrahydrofuran (THF) (45 mL) was added sodium hydride (NaH) (60% in mineral oil, 0.155 g, 3.87 mmol) at about 0° C. The mixture was stirred at about 0° C. for about one hour (until H2(g) fully evolved) then heated at about 65° C. for about 16 hours. The resulting mixture was worked up with ethyl acetate/brine and dried over magnesium sulfate. The crude material was purified thrice by column chromatography on a silica gel column using eluents of 35% to 60% dichloromethane in hexanes, then 0% to 40% dichloromethane in hexanes, then finally 25% to 40% dichloromethane in hexanes. The product was dried by rotary evaporation and recrystallized from dichloromethane/hexanes to yield EM-16 (0.78 g, 64% yield) as a yellow solid. Confirmed by ¹HNMR.

### Synthesis of EM-17

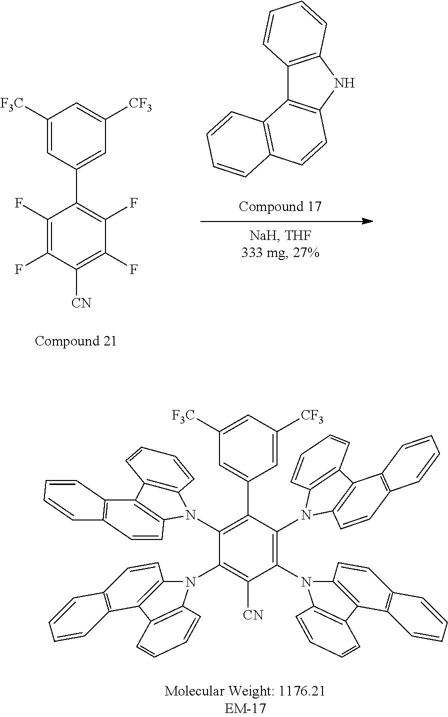 [SMILES: N#Cc1c(F)c(F)c(-c2cc(C(F)(F)F)cc(C(F)(F)F)c2)c(F)c1F ; c1ccc2c(c1)ccc1[nH]c3ccccc3c12 ; N#Cc1c(-n2c3ccccc3c3c4ccccc4ccc32)c(-n2c3ccccc3c3c4ccccc4ccc32)c(-c2cc(C(F)(F)F)cc(C(F)(F)F)c2)c(-n2c3ccccc3c3c4ccccc4ccc32)c1-n1c2ccccc2c2c3ccccc3ccc21]

EM-17:

To a solution of 7H-benzo[c]carbazole (Compound 17) (1.12 g, 5.17 mmol) and 2,3,5,6-tetrafluoro-3′,5′-bis(trifluoromethyl)-[1,1′-biphenyl]-4-carbonitrile (Compound 21) (0.40 g, 1.03 mmol) in anhydrous tetrahydrofuran (THF) (45 mL) was added sodium hydride (NaH) (60% in mineral oil, 0.227 g, 5.68 mmol) at about 0° C. The mixture was stirred at about 0° C. for about one hour (until H₂(g) fully evolved) then heated at about 70° C. for about 16 hours. The resulting mixture was worked up with ethyl acetate/brine and dried over magnesium sulfate. The crude material was purified twice by column chromatography on a silica gel column using eluents of 10% to 25% dichloromethane in hexanes, then 15% to 25% dichloromethane in hexanes, then finally 25% to 40% dichloromethane in hexanes. The product was dried by rotary evaporation and recrystallized from dichloromethane/hexanes to yield EM-17 (0.33 g, 27% yield) as a yellow solid. Confirmed by ¹HNMR.

### Synthesis of EM-18

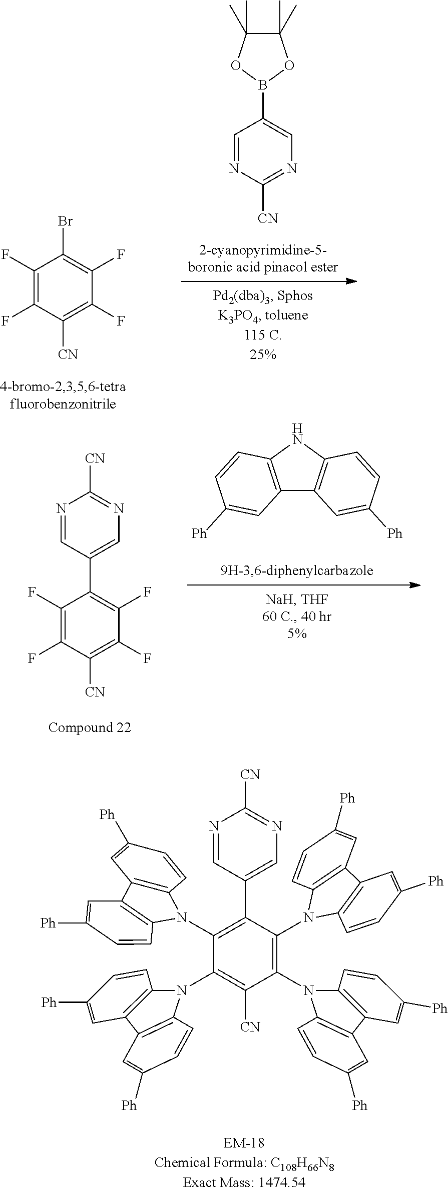

### 5-(4-cyano-2,3,5,6-tetrafluorophenyl)pyrimidine-2-carbonitrile (Compound 22)

A mixture of 4-bromo-2,3,5,6-tetrafluorobenzonitrile (0.44 g, 1.73 mmol), 2-cyanopyrimidine-5-boronic acid pinacol ester (0.40 g, 1.73 mmol), Pd₂(dba)₃ (0.09 g, 0.1 mmol), 2-Dicyclohexylphosphino-2′,6′-dimethoxybiphenyl (0.08 g, 0.2 mmol) and K₃PO₄ (0.575 g, 2.5 mmol) in anhydrous toluene (20 mL) was degassed and heated at 115° C. for 16 hours. The resulting mixture was poured into ethyl acetate (100 mL), after filtered off precipitate, the solution was loaded on silica gel and purified by flash column using eluents of ethyl acetate/hexanes (10% to 30%). The desired fractions were collected and concentrated to give white solid (Compound 22) (0.12 g, in 25% yield).

Compound EM-18:

To a solution of 5-(4-cyano-2,3,5,6-tetrafluorophenyl)pyrimidine-2-carbonitrile (Compound 22) (0.12 g, 0.43 mmol), 9H-3,6-diphenylcarbazole (0.58 g, 1.73 mmol) in THF (10 mL), was added sodium hydride (60% in mineral oil, 0.10 g, 2.5 mmol) at about 0° C. After stirred at room temperature for about 20 min., the mixture was heated at about 60° C. for about 16 hours. The resulting mixture was worked up with dichloromethane/brine, the organic phase was dried and purified by flash column using eluents of dichloromethane/hexanes (20% to 50%). The orange fraction was collected and concentrated to give a orange solid (EM-18) (0.05 g, in 5% yield). Confirmed by LCMS (APCI): calcd for C₁₀₈H₆₇N₈ (M+H): 1476. found: 1476.

### Synthesis of EM-19

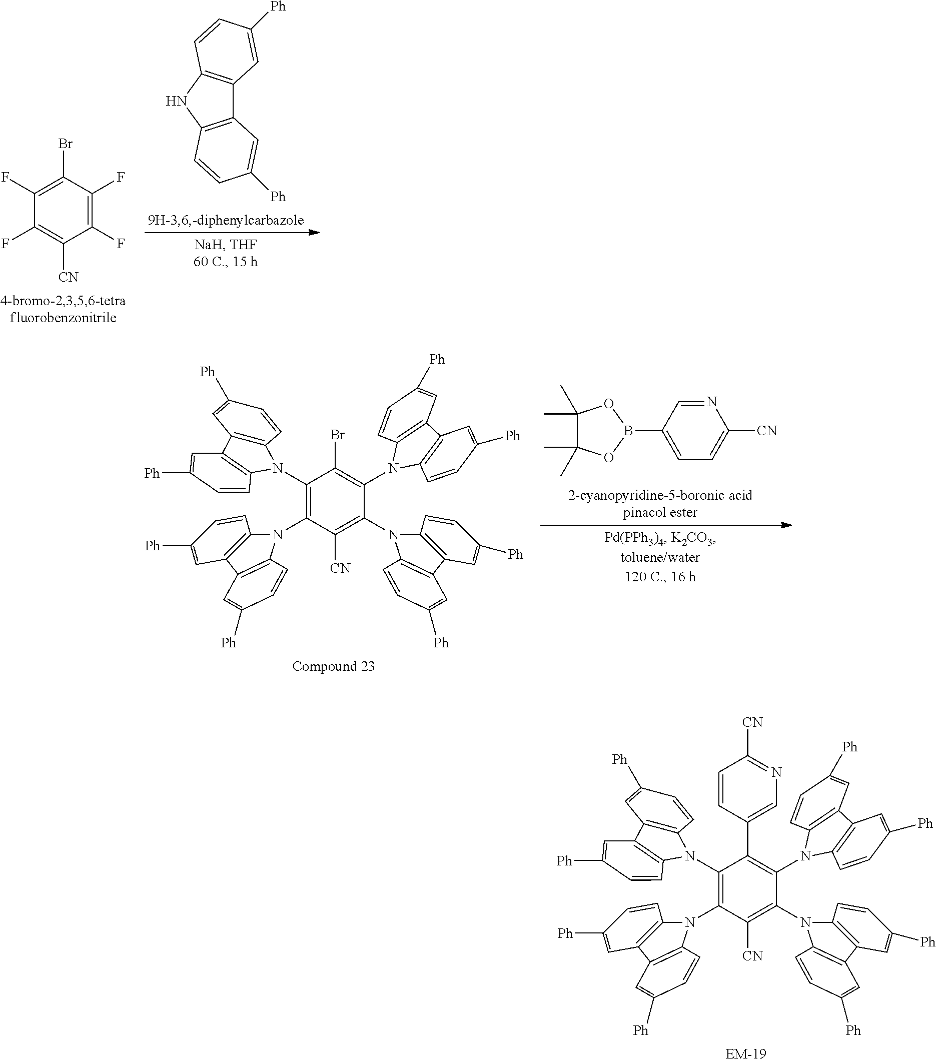

### 4-bromo-2,3,5,6-tetra-(3′,6′-diphenylcarbazoyl)benzonitrile (Compound 23)

To a solution of 4-bromo-2,3,5,6-tetrafluorobenzonitrile (0.356 g, 1.4 mmol), 9H-3,6,-diphenylcarbazole (2.01 g, 6 mmol) in anhydrous THF (15 mL), was added sodiumhydride (60% in mineral oil, 0.28 g, 7 mmol) at 0° C. The resulting mixture was stirred at 0° C. for 30 min, then 60° C. for 15 hours. Yellow precipitate formed, and diluted with THF (200 mL), washed with brine, dried over Na₂SO₄, loaded on silica gel and purified by flash column using eluents of dichloromethane/hexanes (30% to 100%). The desired fractions were collected, concentrated and filtration to give a yellow solid (Compound 23) (1.4 g, in 69% yield).

Compound EM-19:

To a suspension of 4-bromo-2,3,5,6-tetra-(3′,6′-diphenylcarbazoyl)benzonitrile (Compound 23) (0.29 g, 0.2 mmol), 2-cyanopyridine-5-boronic acid pinacol ester (0.23 g, 1 mmol), Pd(PPh₃)₄ (0.06 g, 0.05 mmol) in toluene (30 ML), was added 10% K₂CO₃ aqueous solution (5 mL), then degassed for 40 min. The mixture was heated at 120° C. for 18 hours, worked up with dichloromethane/brine. The organic phase was dried over Na₂SO₄, loaded on silica gel and purified by flash column using eluents of dichloromethane/hexanes (20% to 50% to 70%). The desired fraction was collected, concentrated and reprecipitated in dichloromethane/methanol to give a yellow solid (EM-19) (0.10 g, in 34% yield). Confirmed by LCMS (APCI): calcd for C₁₀₉H₆₈N₇ (M+H): 1475. found: 1475.

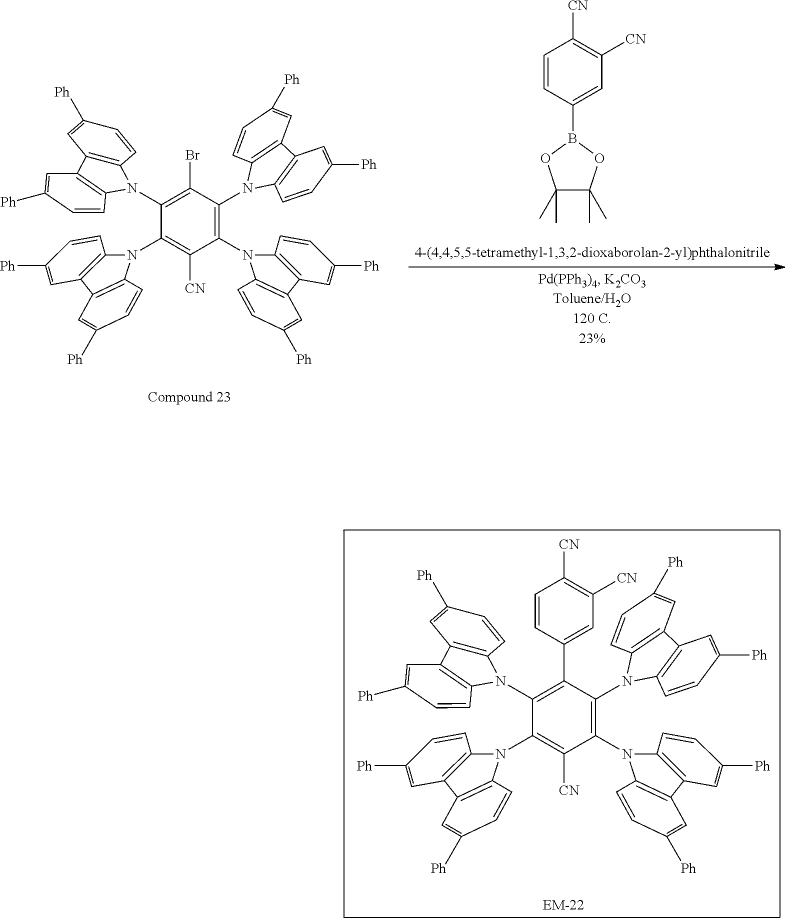 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(Br)c(-n2c3ccc(-c4ccccc4)cc3c3cc(-c4ccccc4)ccc32)c1-n1c2ccc(-c3ccccc3)cc2c2cc(-c3ccccc3)ccc21 ; CC1(C)OB(c2ccc(C#N)c(C#N)c2)OC1(C)C ; N#Cc1ccc(-c2c(-n3c4ccc(-c5ccccc5)cc4c4cc(-c5ccccc5)ccc43)c(-n3c4ccc(-c5ccccc5)cc4c4cc(-c5ccccc5)ccc43)c(C#N)c(-n3c4ccc(-c5ccccc5)cc4c4cc(-c5ccccc5)ccc43)c2-n2c3ccc(-c4ccccc4)cc3c3cc(-c4ccccc4)ccc32)cc1C#N]

Compound EM-22:

To a suspension of 4-bromo-2,3,5,6-tetra-(3′,6′-diphenylcarbazoyl)benzonitrile (Compound 23) (1.45 g, 1.0 mmol), 4-(4,4,5,5-tetramethyl-1,3,2-dioxaborolan-2-yl)phthalonitrile (1.01 g, 4 mmol), Pd(PPh₃)₄ (0.138 g, 0.12 mmol) in toluene (30 ML), was added 10% K₂CO₃ aqueous solution (5 mL), then degassed for 40 min. The mixture was heated at 120° C. for 18 hours, worked up with dichloromethane/brine. The organic phase was dried over Na₂SO₄, loaded on silica gel and purified by flash column using eluents of toluene/hexanes (20% to 50% to 70%). The desired fraction was collected, concentrated and reprecipitated in dichloromethane/hexanes to give a yellow solid (EM-22) (0.35 g, in 23% yield). Confirmed by LCMS (APCI): Calcd for C111H68N7 (M+H): 1498. Found: 1498.

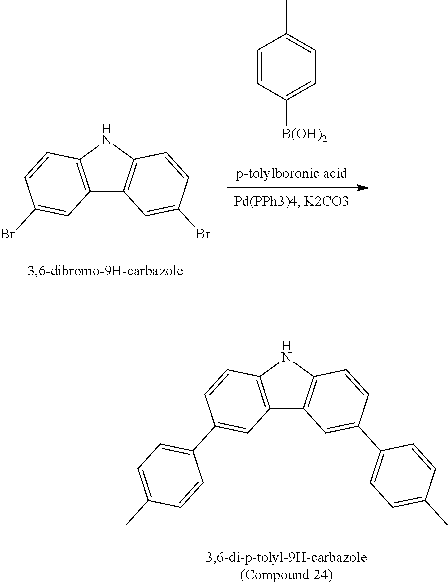

### 3,6-ditolyl-9H-carbazole (Compound 24)

A mixture of 3,6-dibromo-9H-carbazole (3.0 g, 9.2 mmol), toly boronic acid (3.4 g, 25 mmol), Pd(PPh₃)₄ (0.3 g, 0.26 mmol) and potassium carbonate (6.5 g, 47 mmol) in dioxane/water (75 mL/15 mL) was degassed and heated at about 100° C. for about 16 hours. Upon cooling to room temperature, the whole was worked up with ethyl acetate/brine, the organic was dried over Na₂SO₄, loaded on silica gel and purified by flash column using eluents of ethyl acetate/hexanes (10% to 30%). After removal of solvents, a white solid (Compound 24) was obtained (2.36 g, in 74% yield).

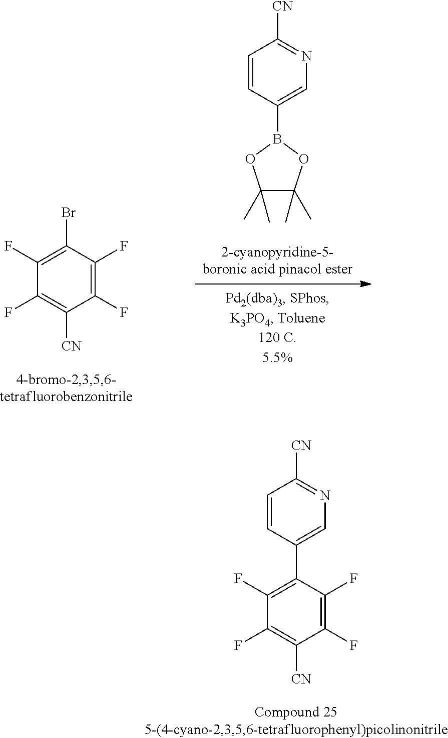

### Compound 25: 5-(4-cyano-2,3,5,6-tetrafluorophenyl)picolinonitrile

A mixture of 4-bromo-2,3,5,6-tetrafluorobenzonitrile (2.2 g, 5.53 mmol), 2-cyanopyridine-5-boronic acid pinacol ester (2.0 g, 5.53 mmol), Pd₂(dba)₃ (0.18 g, 0.2 mmol), 2-Dicyclohexylphosphino-2′,6′-dimethoxybiphenyl (0.16 g, 0.4 mmol) and K₃PO₄ (2.2 g, 10 mmol) in anhydrous toluene (100 mL) was degassed and heated at 115° C. for 16 hours. The resulting mixture was poured into ethyl acetate (100 mL), after filtered off precipitate, the solution was loaded on silica gel and purified by flash column using eluents of ethyl acetate/hexanes (10% to 30%). The desired fractions were collected and concentrated to give white solid (Compound 25) (0.18 g, in 6% yield).

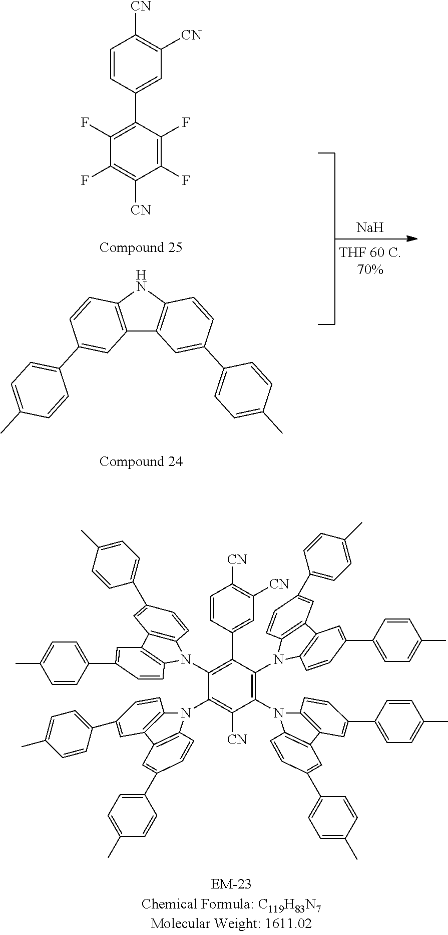

Compound EM-23:

To a solution of 3,6-ditolyl-9H-carbazole (Compound 24) (1.6 g, 4.5 mmol) and 2,3,5,6-tetrafluro-4-(3′,4′-dicyanophenyl)-benzonitrile (Compound 25) (0.28 g, 1 mmol) in anhydrous THF (25 mL) was added sodium hydride (60% in mineral oil, 0.2 g, 5 mmol) at about 0° C. and stirred for about 30 min. The mixture was heated at about 60° C. for about 24 hours. Upon cooling to room temperature, the whole was worked up with dichloromethane/brine, dried over Na₂SO₄, then purified by flash column using eluents of dicholoromethane/hexanes (20% to 60%). The yellow desired fractions were collected and concentrated to give a bright yellow solid (Host-22) (0.655 g, in 70% yield). Confirmed by LCMS (APCI): Calcd for C119H84N7 (M+H): 1612. Found: 1612.

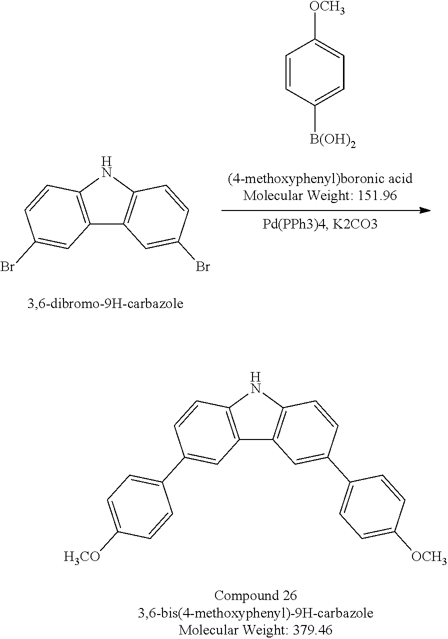 [SMILES: COc1ccc(B(O)O)cc1 ; Brc1ccc2[nH]c3ccc(Br)cc3c2c1 ; COc1ccc(-c2ccc3[nH]c4ccc(-c5ccc(OC)cc5)cc4c3c2)cc1]

### 3,6-bis(4-methoxyphenyl)-9H-carbazole (Compound 26)

A mixture of 3,6-dibromo-9H-carbazole (9.0 g, 32 mmol), (4-methoxyphenyl)boronic acid (9.7 g, 64 mmol), Pd(PPh₃)₄ (0.3 g, 0.26 mmol) and potassium carbonate (6.5 g, 47 mmol) in dioxane/water (75 mL/15 mL) was degassed and heated at about 100° C. for about 16 hours. Upon cooling to room temperature, the whole was worked up with ethyl acetate/brine, the organic was dried over Na₂SO₄, loaded on silica gel and purified by flash column using eluents of ethyl acetate/hexanes (10% to 30%). After removal of solvents, a white solid (Compound 26) was obtained (5.43 g, in 45% yield).

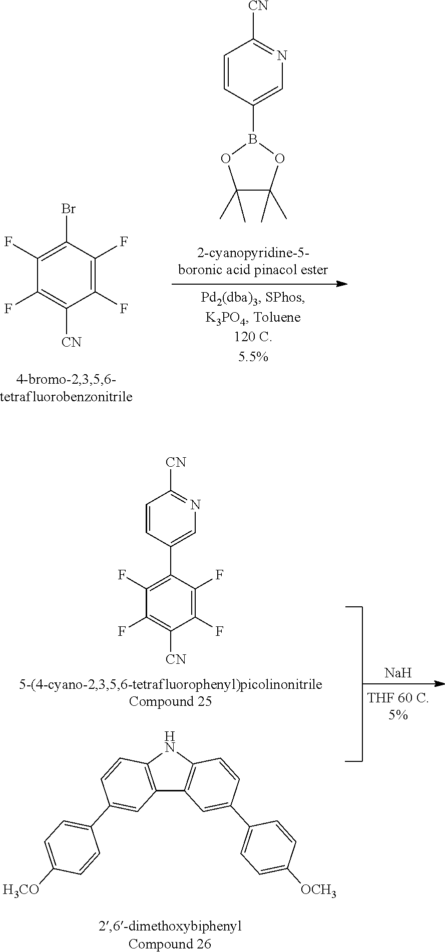

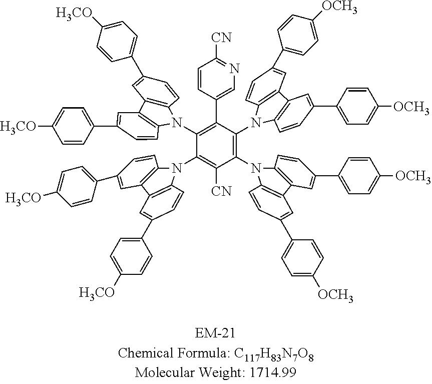 [SMILES: COc1ccc(-c2ccc3c(c2)c2cc(-c4ccc(OC)cc4)ccc2n3-c2c(C#N)c(-n3c4ccc(-c5ccc(OC)cc5)cc4c4cc(-c5ccc(OC)cc5)ccc43)c(-n3c4ccc(-c5ccc(OC)cc5)cc4c4cc(-c5ccc(OC)cc5)ccc43)c(-c3ccc(C#N)nc3)c2-n2c3ccc(-c4ccc(OC)cc4)cc3c3cc(-c4ccc(OC)cc4)ccc32)cc1]

### Compound 25: 5-(4-cyano-2,3,5,6-tetrafluorophenyl)picolinonitrile

A mixture of 4-bromo-2,3,5,6-tetrafluorobenzonitrile (2.2 g, 5.53 mmol), 2-cyanopyridine-5-boronic acid pinacol ester (2.0 g, 5.53 mmol), Pd₂(dba)₃ (0.18 g, 0.2 mmol), 2-Dicyclohexylphosphino-2′,6′-dimethoxybiphenyl (0.16 g, 0.4 mmol) and K₃PO₄ (2.2 g, 10 mmol) in anhydrous toluene (100 mL) was degassed and heated at 115° C. for 16 hours. The resulting mixture was poured into ethyl acetate (100 mL), after filtered off precipitate, the solution was loaded on silica gel and purified by flash column using eluents of ethyl acetate/hexanes (10% to 30%). The desired fractions were collected and concentrated to give white solid (Compound 25) (0.18 g, in 6% yield).

Compound EM-21:

To a solution of 5-(4-cyano-2,3,5,6-tetrafluorophenyl)picolinonitrile (Compound 25) (0.12 g, 0.43 mmol), 3,6-bis(4-methoxyphenyl)-9H-carbazole (Compound 26) (0.64 g, 1.73 mmol) in THF (10 mL), was added sodium hydride (60% in mineral oil, 0.10 g, 2.5 mmol) at about 0° C. After stirred at room temperature for about 20 min., the mixture was heated at about 60° C. for about 16 hours. The resulting mixture was worked up with dichloromethane/brine, the organic phase was dried and purified by flash column using eluents of dichloromethane/hexanes (20% to 50%). The orange fraction was collected and concentrated to give a orange solid (EM-21) (0.05 g, in 5% yield). Confirmed by LCMS (APCI): calcd for C117H84N708 (M+H): 1716. Found: 1716.

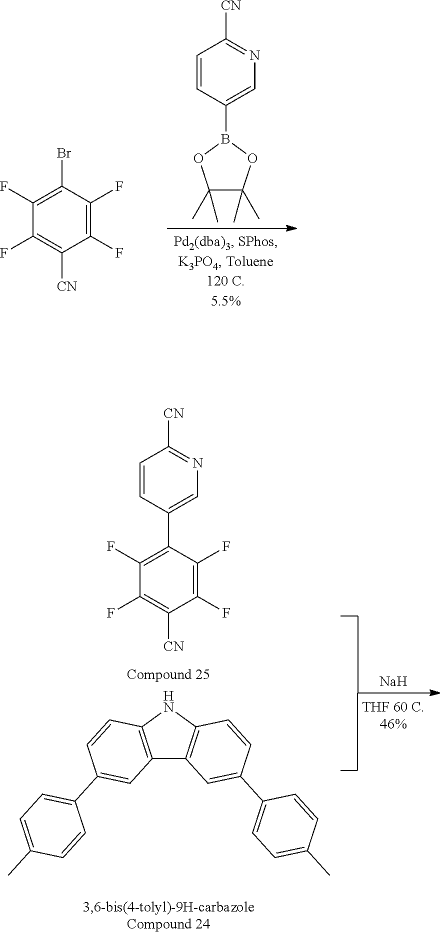

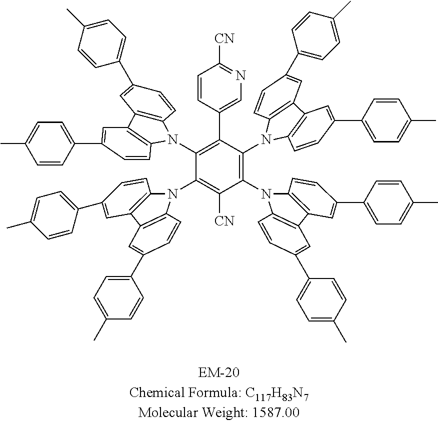

Compound EM_20:

To a solution of 5-(4-cyano-2,3,5,6-tetrafluorophenyl)picolinonitrile (Compound 25) (0.12 g, 0.43 mmol), 3,6-bis(4-tolyl)-9H-carbazole (Compound 24) (0.59 g, 1.73 mmol) in THF (10 mL), was added sodium hydride (60% in mineral oil, 0.10 g, 2.5 mmol) at about 0° C. After stirred at room temperature for about 20 min., the mixture was heated at about 60° C. for about 16 hours. The resulting mixture was worked up with dichloromethane/brine, the organic phase was dried and purified by flash column using eluents of dichloromethane/hexanes (20% to 50%). The orange fraction was collected and concentrated to give a orange solid (EM-20) (0.45 g, in 46% yield). Confirmed by LCMS (APCI): calcd for C117H84N7 (M+H): 1587. Found: 1587.

8.2. Physical Properties of the Materials

2 mg of EM-1 was dissolved in 1 mL of 2-methyltetrahydrofuran (2-MeTHF) and then the resulting solution was transferred into quartz tube. Then the quartz tube containing EM-1 was frozen (77K) by liquid nitrogen prior to measurement. Triplet (T₁) energy was measured by phosphorescent emission spectrum at 77K, using Fluoromax-3 spectrophotometer (Horiba Instruments, NJ, USA).

2 mg of EM-1 was dissolved in 1 mL of 2-MeTHF and then the resulting solution was transferred into quartz tube. Then the quartz tube containing EM-1 was frozen (77K) by liquid nitrogen prior to measurement. Singlet (S₁) energy was measured by fluorescent emission spectrum at 77K, using Fluoromax-3 spectrophotometer (Horiba Instruments, NJ, USA). EM-2, EM-3, EM-4, EM-5, EM-6 and EM-8 samples were tested in a similar manner, the results of which are provided below in Table 1.

TABLE 1
Physical data of the emissive materials

| | Com- | | λₑₘ | S₁-T₁ | φ_{PL} | φ_{PL} | | |
|---|---|---|---|---|---|---|---|---|
| Device | pound | Structure | (nm) | (eV) | (N₂₎ | (air) | (TADF) | EQE |
| 1A | EM-1 A | 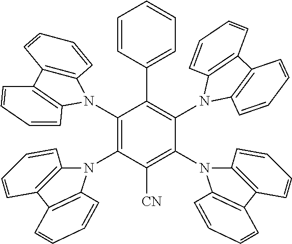 [SMILES: N#Cc1c(-n2c3ccccc3c3ccccc32)c(-n2c3ccccc3c3ccccc32)c(-c2ccccc2)c(-n2c3ccccc3c3ccccc32)c1-n1c2ccccc2c2ccccc21] | 469 | <0.01 | 37% | 10% | 27% | 11.4% |
| 1B | EM-1 B | 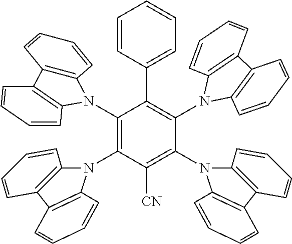 [SMILES: N#Cc1c(-n2c3ccccc3c3ccccc32)c(-n2c3ccccc3c3ccccc32)c(-c2ccccc2)c(-n2c3ccccc3c3ccccc32)c1-n1c2ccccc2c2ccccc21] | 469 | <0.01 | 37% | 10% | 27% | 7.2% |
| 1C | | | | | | | | |
| 1D | | | | | | | | |
| 2 | EM-2 | 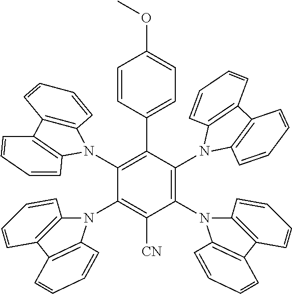 [SMILES: COc1ccc(-c2c(-n3c4ccccc4c4ccccc43)c(-n3c4ccccc4c4ccccc43)c(C#N)c(-n3c4ccccc4c4ccccc43)c2-n2c3ccccc3c3ccccc32)cc1] | 454 | — | 13.4% | 9.4% | 4% | 3.0% |
| 3 | EM-3 | 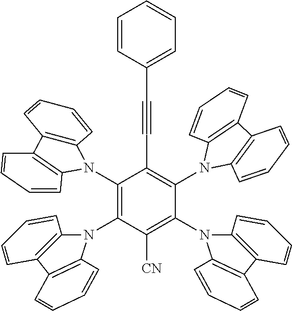 [SMILES: N#Cc1c(-n2c3ccccc3c3ccccc32)c(-n2c3ccccc3c3ccccc32)c(C#Cc2ccccc2)c(-n2c3ccccc3c3ccccc32)c1-n1c2ccccc2c2ccccc21] | 496 | — | 14.8% | 12.5% | 2.3% | 5.7% |
| 4 | EM-4 | 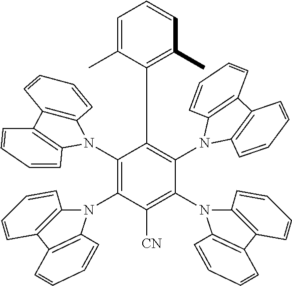 | 448 | <0.01 | 3% | 11% | 32% | — |
| 5 | EM-5 | 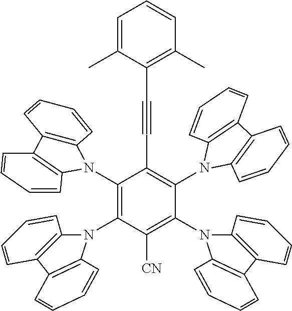 [SMILES: Cc1cccc(C)c1C#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21] | 490 | 0.25 | 31% | 14% | 17% | 4.0% |
| 6 | EM-6 | 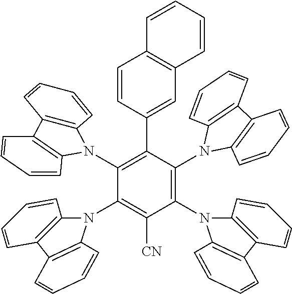 [SMILES: N#Cc1c(-n2c3ccccc3c3ccccc32)c(-n2c3ccccc3c3ccccc32)c(-c2ccc3ccccc3c2)c(-n2c3ccccc3c3ccccc32)c1-n1c2ccccc2c2ccccc21] | | | 13% | 9% | 4% | 2.3% |
| 7 | EM-7 | 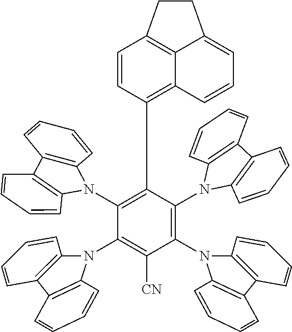 [SMILES: N#Cc1c(-n2c3ccccc3c3ccccc32)c(-n2c3ccccc3c3ccccc32)c(-c2ccc3c4c(cccc24)CC3)c(-n2c3ccccc3c3ccccc32)c1-n1c2ccccc2c2ccccc21] | | | | | | |
| 8 | EM-8 | 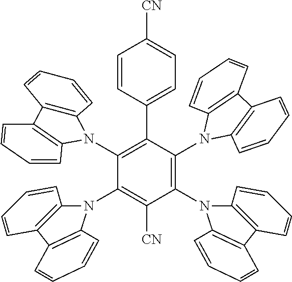 [SMILES: N#Cc1ccc(-c2c(-n3c4ccccc4c4ccccc43)c(-n3c4ccccc4c4ccccc43)c(C#N)c(-n3c4ccccc4c4ccccc43)c2-n2c3ccccc3c3ccccc32)cc1] | 495 | 0.0 | 100% | 15% | 85% | 15.4% |
| 9 | EM-9 | 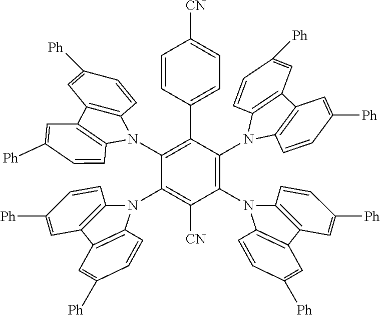 [SMILES: N#Cc1ccc(-c2c(-n3c4ccc(-c5ccccc5)cc4c4cc(-c5ccccc5)ccc43)c(-n3c4ccc(-c5ccccc5)cc4c4cc(-c5ccccc5)ccc43)c(C#N)c(-n3c4ccc(-c5ccccc5)cc4c4cc(-c5ccccc5)ccc43)c2-n2c3ccc(-c4ccccc4)cc3c3cc(-c4ccccc4)ccc32)cc1] | 536 | 0.0 | 99% | 37% | 62% | 21% |
| CD-1 | CE-1 | 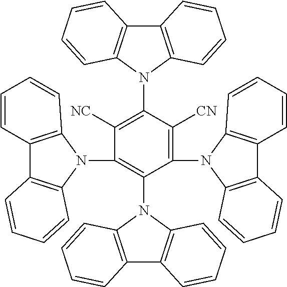 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21] | | | 94% | 26% | 68% | |
| CD-2 | CE-2 | 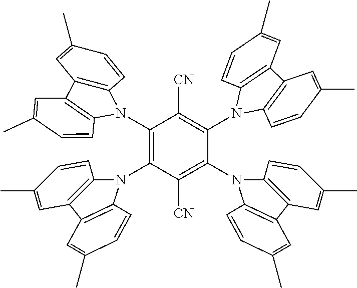 | | | 27% | 24% | 3% | |
| | EM-20 | 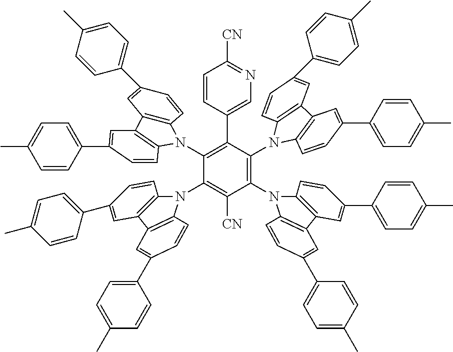 | | | | | | |
| | EM-21 | 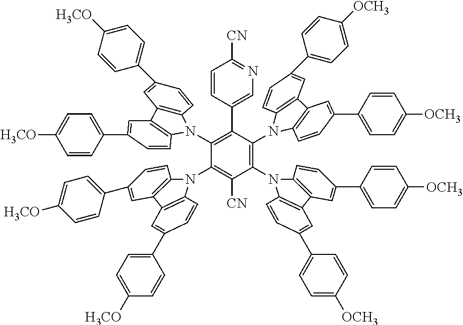 [SMILES: COc1ccc(-c2ccc3c(c2)c2cc(-c4ccc(OC)cc4)ccc2n3-c2c(C#N)c(-n3c4ccc(-c5ccc(OC)cc5)cc4c4cc(-c5ccc(OC)cc5)ccc43)c(-n3c4ccc(-c5ccc(OC)cc5)cc4c4cc(-c5ccc(OC)cc5)ccc43)c(-c3ccc(C#N)nc3)c2-n2c3ccc(-c4ccc(OC)cc4)cc3c3cc(-c4ccc(OC)cc4)ccc32)cc1] | 583 (570 nm in tol.) | −0.06 | 28.7% | 19.2% | 9.5% | |
| | EM-22 | 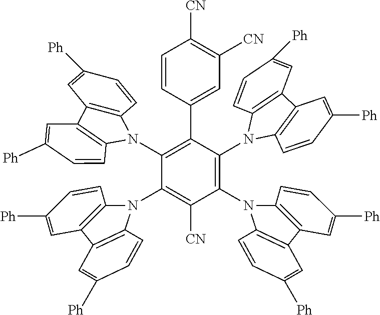 [SMILES: N#Cc1ccc(-c2c(-n3c4ccc(-c5ccccc5)cc4c4cc(-c5ccccc5)ccc43)c(-n3c4ccc(-c5ccccc5)cc4c4cc(-c5ccccc5)ccc43)c(C#N)c(-n3c4ccc(-c5ccccc5)cc4c4cc(-c5ccccc5)ccc43)c2-n2c3ccc(-c4ccccc4)cc3c3cc(-c4ccccc4)ccc32)cc1C#N] | 564 | −0.06 | 65% | 33.5% | 32.0% | |
| | EM-23 | 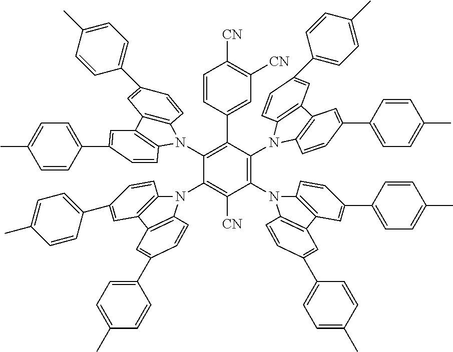 | | | | | | |

The data demonstrates that the compounds have a high quantum yield in air and a good TADF contribution.

8-3. Example of OLED Device Configuration and Performance

### Example 2.1

### Device-A

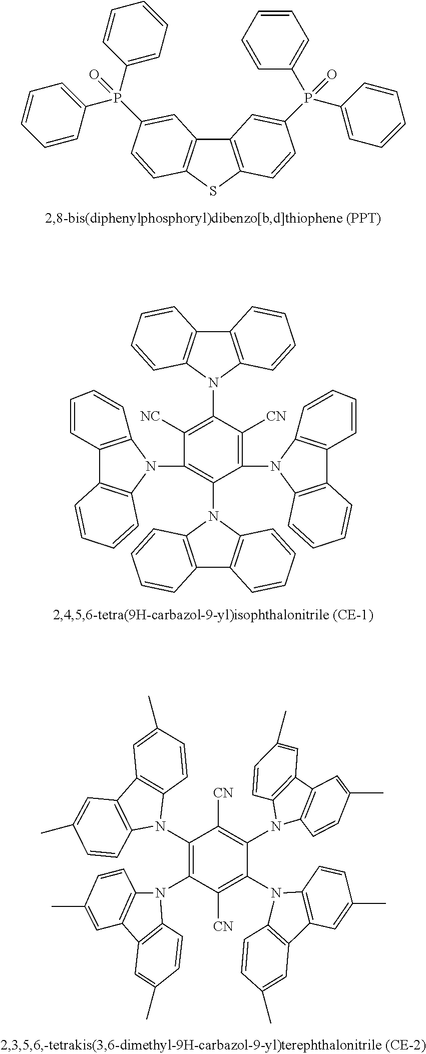

Fabrication of Light-Emitting Device:

A device was fabricated in the following manner. The ITO substrates having sheet resistance of about 14 ohm/sq were cleaned ultrasonically and sequentially in detergent, water, acetone and then IPA; and then dried in an oven at about 80° C. for about 30 min under ambient environment. Substrates were baked at about 200° C. for about 1 hour in an ambient environment, then under UV-ozone treatment for about 30 minutes. The substrate was then be transferred into a vacuum chamber, where 4,4′-bis[N-(1-napthyl)-N-phenylamino]biphenyl (NPB [hole transporting material]) was vacuum deposited at a rate of about 0.1 nm/s rate under a base pressure of about 2×10⁻⁷ torr. EM-1 (14 wt %) was co-deposited as an emissive layer with 1,3-N,N-dicarbazole-benzene (mCP) host material at about 0.01 nm/s and about 0.10 nm/s, respectively, to make the appropriate thickness ratio. 1,3,5-Tris(1-phenyl-1H-benzimidazol-)2-yl)benzene (TPBI) was then deposited at about 0.1 nm·s rate on the emissive layer. A layer of lithium fluoride (LiF) (electron injection material) was deposited at about 0.15 nm/s rate followed by deposition of the cathode as Aluminium (Al) at about 0.3 nm/s rate. The representative device structure was: ITO (about 150 nm thick)/NPB (about 35 nm thick)/mCP: EM-1 (about 15 nm thick)/TPBI (about 65 nm thick)/LiF (about 0.8 nm thick)/Al (about 70 nm thick). The device was then be encapsulated with a glass cap to cover the emissive area of the OLED device in order to protect from moisture, oxidation or mechanical damage.

Devices 1B, 1C and 1D were constructed in a similar manner to Device 1, except that Device 1B had 6 wt % EM-1 in mCP host, Device 1C had 10 wt % EM-1 in mCP host, Device 1C had 14 wt % EM-1 in mCP and Device 1D had 6 wt % EM-1 in PPT.

Device B was constructed in a similar manner to Device A, except that EM-2 was 6% in mCP host.

Devices C-I were constructed in a similar manner to Device B, except that 4,4′-N,N′-dicarbazole-biphenyl (CBP) was used as the host materials instead of mCP and EM-3, EM-4, EM-5, EM-6, EM-7, EM-8 and EM-9 were used instead of EM-2. Device I [EM-8] was constructed in a similar manner to Device 1 D, except that EM-8 (6 wt %) was used instead of EM-1 with PPT host material.

Comparative Devices CD-1 and CD-2 were constructed in a manner similar to Device C (6 wt % guest material in CBP host, except that Comparative Compound 1 (CE-1) or Comparative Compound 2 (CE-2) were used instead of EM-2.

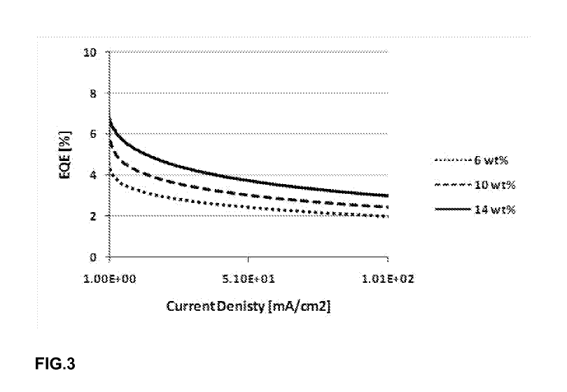

In addition, device performance of Device A was evaluated by measuring the current density and luminance as a function of the driving voltage, as shown in FIG. 2. The turn-on voltage for Device A was about 4.7 volts and the maximum luminance was about 8000 cd/m². FIG. 3 shows the EQE (external quantum efficiency) and luminous efficiency as a function of current density. The EQE of Device A was about 11.8%, and the luminous efficiency was about 26.4 cd/A. The power efficiency (PE) was 14.5 lm/w at 1000 cd/m².

TABLE 2
OLED monocolor device data

| | | Emitter | | | PE | LE | EQE |
|---|---|---|---|---|---|---|---|
| Device | Emitter | wt % | Host | Structure | [lm/W] | [cd/A] | [%] |
| Device 1 | EM-1 | 14% | CP | 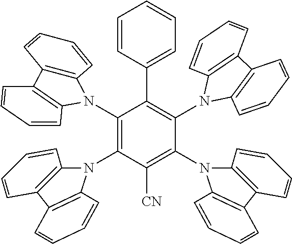 [SMILES: N#Cc1c(-n2c3ccccc3c3ccccc32)c(-n2c3ccccc3c3ccccc32)c(-c2ccccc2)c(-n2c3ccccc3c3ccccc32)c1-n1c2ccccc2c2ccccc21] | 4.1 | 10.5 | .2 |
| | EM-1 | 6% | CP | | 1.4 | 4.6 | .5 |
| | | 10% | CP | | 3.4 | 7.6 | .87 |
| | | 6% | PT | | 4.1 | 19.1 | 1.4 |
| | EM-2 | 6% | CP | | 0.54 | 2.1 | 3.0 |
| | EM-3 | 6% | BP | | 1.7 | 7.3 | .8 |
| | EM-4 | 6% | | | | | |
| | EM-5 | 6% | BP | | 1.1 | 3.7 | .0 |
| | EM-6 | 6% | BP | | 0.42 | 1.6 | 2.3 |
| | | 6% | | | | | |
| | EM-8 | 6% | PT | | 7.4 | 34 | 4.5 |
| | CE-1 | 6% | | | 29 | 36.5 | 18 |
| | CE-2 | 6% | BP | | 10 | 28 | 3 |

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained. At the very least, and not as an attempt to limit the application of the doctrine of equivalents to the scope of the claims, each numerical parameter should at least be construed in light of the number of reported significant digits and by applying ordinary rounding techniques.

The terms “a,” “an,” “the” and similar referents used in the context of describing the invention (especially in the context of the following claims) are to be construed to cover both the singular and the plural, unless otherwise indicated herein or clearly contradicted by context. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of any claim. No language in the specification should be construed as indicating any non-claimed element essential to the practice of the invention.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, the claims include all modifications and equivalents of the subject matter recited in the claims as permitted by applicable law. Moreover, any combination of the above-described elements in all possible variations thereof is contemplated unless otherwise indicated herein or otherwise clearly contradicted by context.

In closing, it is to be understood that the embodiments disclosed herein are illustrative of the principles of the claims. Other modifications that may be employed are within the scope of the claims. Thus, by way of example, but not of limitation, alternative embodiments may be utilized in accordance with the teachings herein. Accordingly, the claims are not limited to embodiments precisely as shown and described.

What is claimed is:

1. An emissive compound for use in emissive elements of organic light emitting devices, the compound being represented by Formula 1: 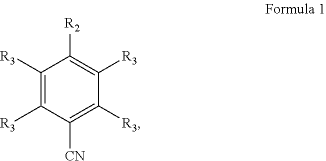
wherein R₂ is optionally substituted phenyl, an optionally substituted polycyclic aromatic, an optionally substituted C₁₋₄ alkynyl, or an optionally substituted heteroaryl group; wherein, and each R₃ is independently an electron donor heteroaryl group selected from an optionally substituted carbazolyl, an optionally substituted benzocarbazolyl, an optionally substituted phenoxazolyl, an optionally substituted phenothiazenyl and an optionally substituted phenazinyl.

2. An emissive compound for use in emissive elements of organic light emitting devices, the compound being represented by the following formula: 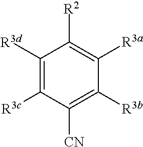
wherein R² is optionally substituted phenyl, an optionally substituted polycyclic aromatic, an optionally substituted C₁ alkynyl, or a heteroaryl group; and
wherein, R^{3a}, R^{3b}, R^{3c}, R^{3d} are independently optionally substituted carbazolyl, optionally substituted benzocarbazolyl, optionally substituted phenoxazolyl, optionally substituted phenothiazenyl, or optionally substituted phenazinyl.

3. The compound of claim 2, further represented by the following formula: 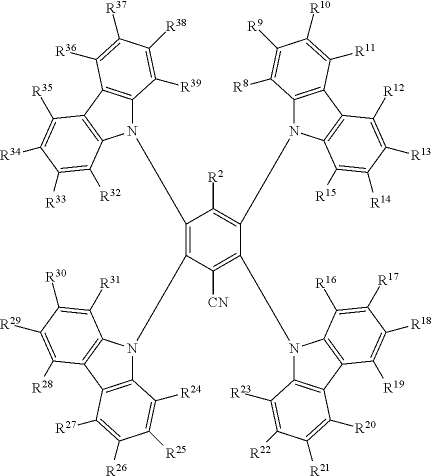
wherein R² is optionally substituted dihydroacenaphthyl, optionally substituted phenyl, or optionally substituted 2-phenylethynyl; and
wherein R⁸-R³⁹ are independently H, optionally substituted phenyl, optionally substituted 2-phenylethenyl, or optionally substituted carbazolyl, or wherein two adjacent groups of R⁸-R³⁹ together form an optionally substituted 1,3-butadien-1,4-yl.

4. The compound of claim 1 wherein R₂ is

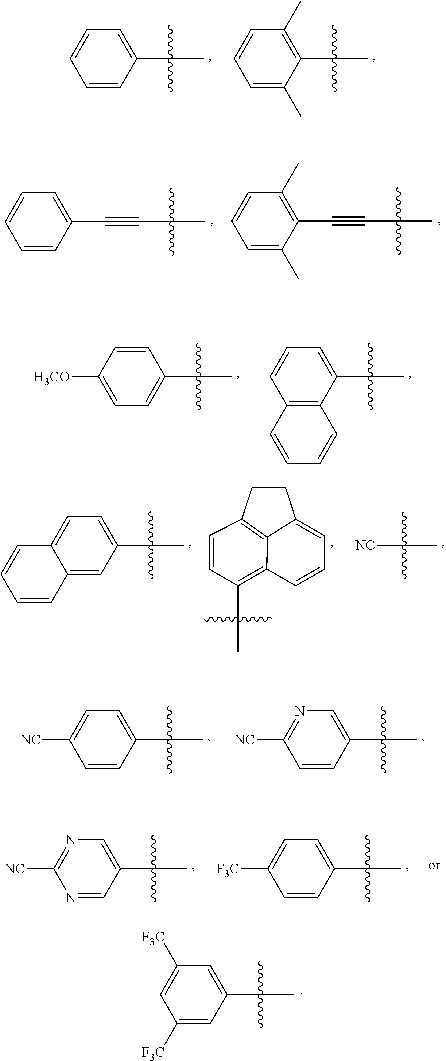

5. The compound of claim 1, wherein R₃ is

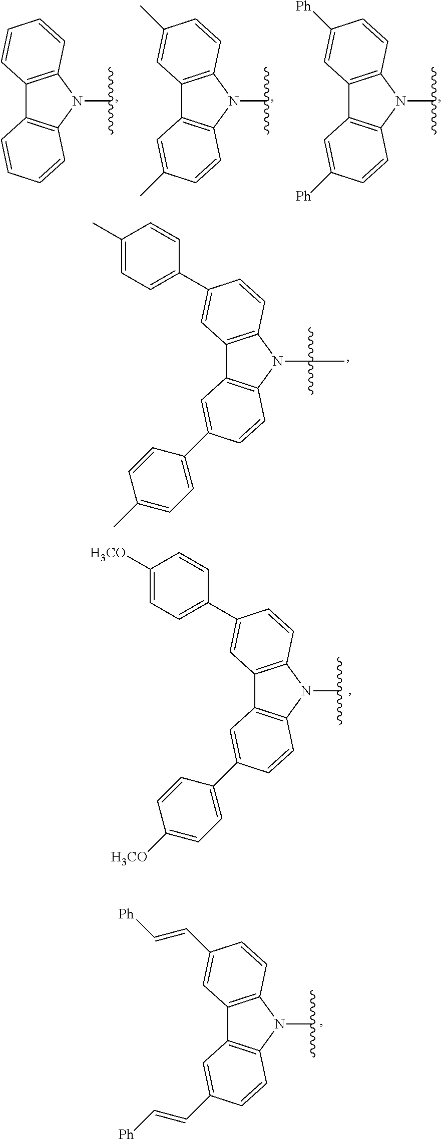

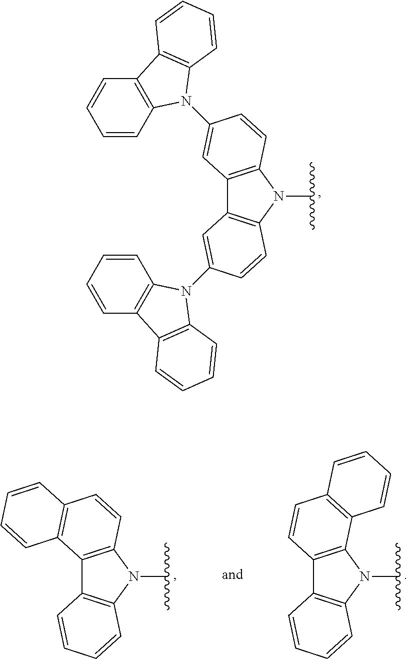 [SMILES: *n1c2ccc(-n3c4ccccc4c4ccccc43)cc2c2cc(-n3c4ccccc4c4ccccc43)ccc21 ; *n1c2ccccc2c2c3ccccc3ccc21 ; *n1c2ccccc2c2ccc3ccccc3c21]

6. The compound of claim 1 wherein the compound is:

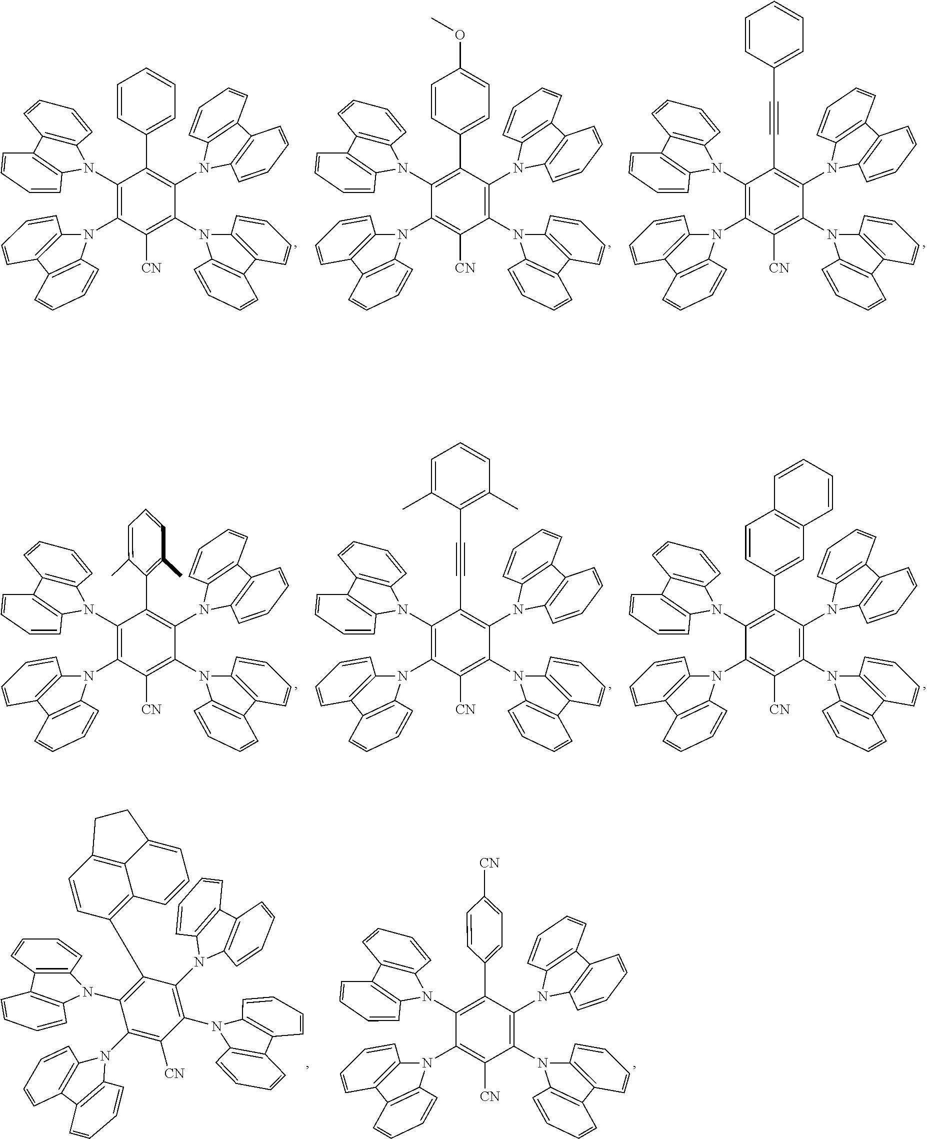

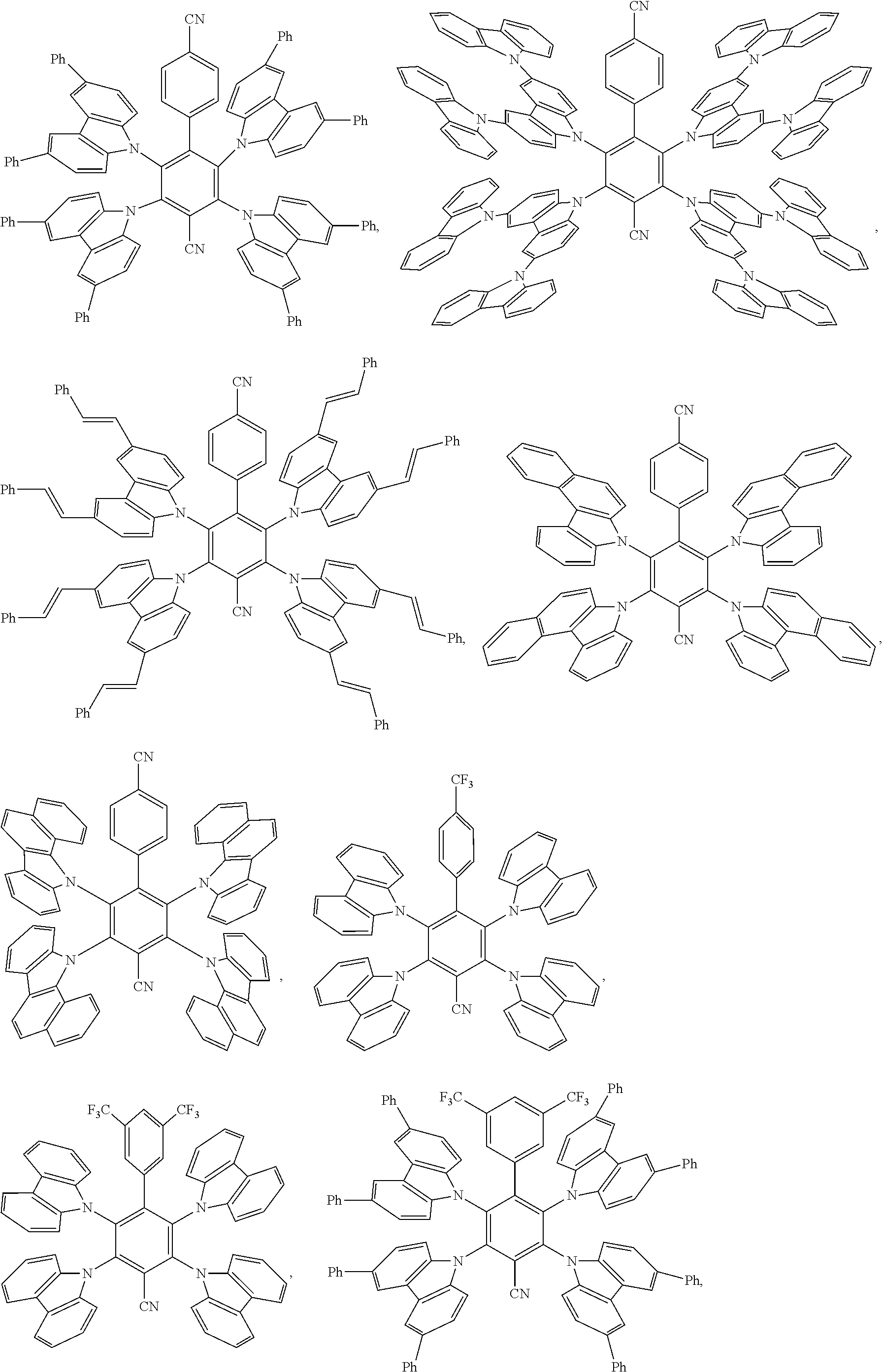

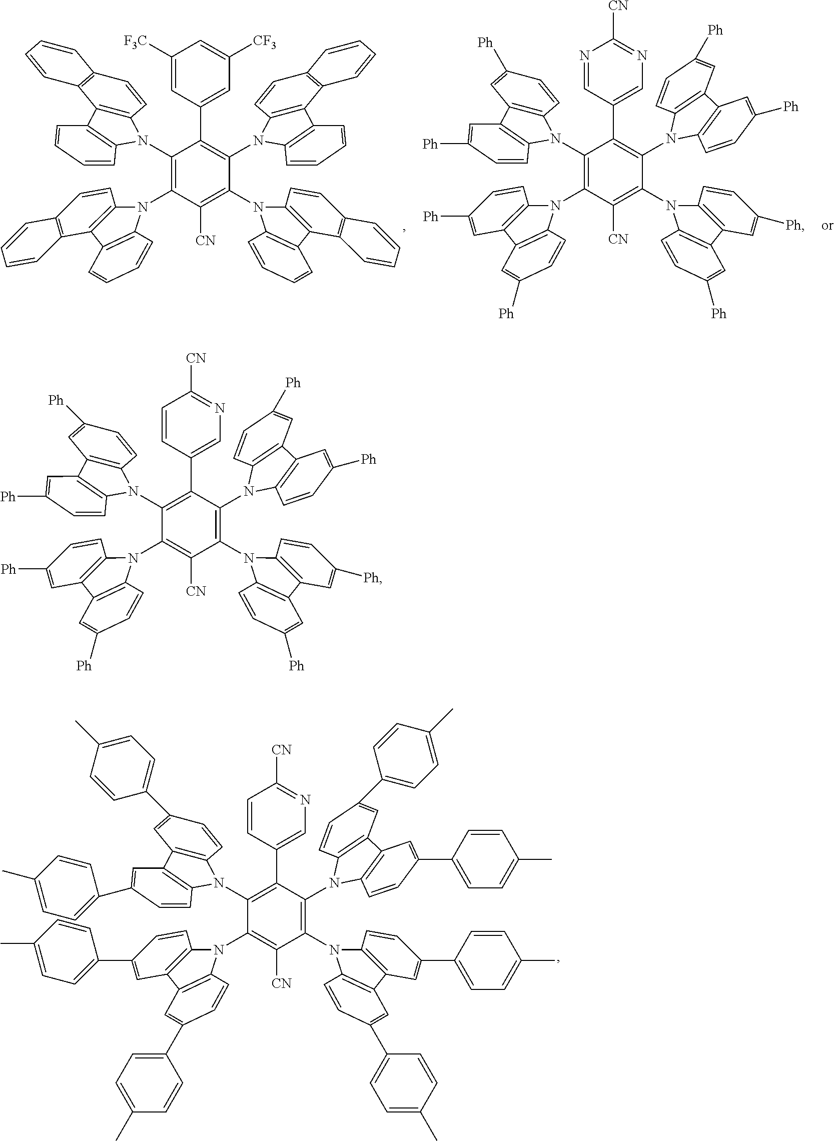

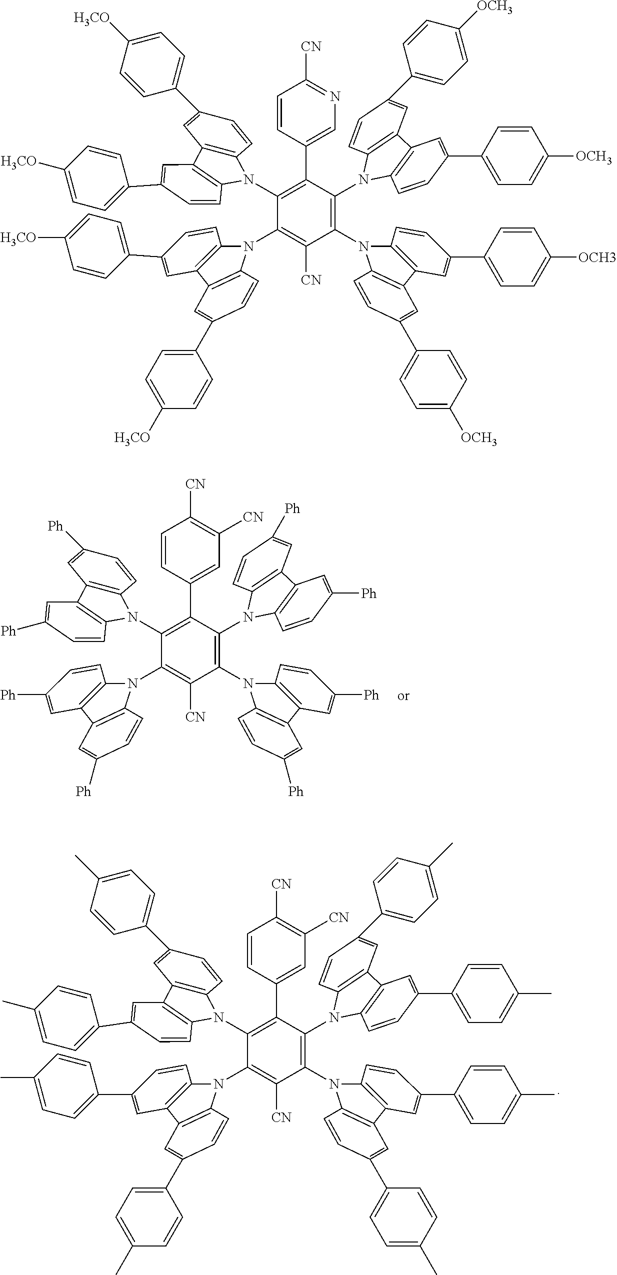

7. The compound of claim 2, wherein R^{3a} is optionally substituted carbazolyl.

8.-22. (canceled)

23. The compound of claim 2, wherein R^{3b} is optionally substituted carbazolyl.

24. The compound of claim 2, wherein R^{3c} is optionally substituted carbazolyl.

25. The compound of claim 2, wherein R^{3d} is optionally substituted carbazolyl.

26. The compound of claim 2, wherein R^{3a} is optionally substituted benzocarbazolyl.

27. The compound of claim 2, wherein R^{3b} is optionally substituted benzocarbazolyl.

28. The compound of claim 2, wherein R^{3c} is optionally substituted benzocarbazolyl.

29. The compound of claim 2, wherein R^{3d} is optionally substituted benzocarbazolyl.

30. The compound of claim 2, wherein R² is optionally substituted phenyl.

31. The compound of claim 3, wherein R² is optionally substituted 2-phenylethynyl.

32. The compound of claim 2, wherein R² is optionally substituted naphthyl.

33. The compound of claim 3, wherein R² is optionally substituted dihydroacenaphthyl.

34. The compound of claim 2, wherein R² is optionally substituted pyridinyl.

35. The compound of claim 2, wherein R² is optionally substituted pyrimidinyl.

36. An organic light-emitting diode device comprising:
a cathode;
an anode; and
a light-emitting layer disposed between and electrically connected to the anode and the cathode, wherein the light-emitting layer comprises an emissive compound according to claim 1.

37. The device of claim 36, further comprising a hole-transport layer between the anode and the light-emitting layer and an electron-transport layer between the cathode and the light-emitting layer.
